(19) United States
(12) Patent Application Publication
(10) Pub. No.: US 2025/0318282 A1
(43) Pub. Date: Oct. 9, 2025

(54) SOLAR DEVICES WITH BOROSILICATE GLASS AND METHODS OF THE SAME

(71) Applicant: CORNING INCORPORATED, CORNING, NY (US)

(72) Inventors: Thomas Michael Cleary, Elmira, NY (US); Lisa Lynn Griesbach Hawkins, Corning, NY (US); Timothy Michael Gross, Painted Post, NY (US); Jingshi Wu, Painted Post, NY (US)

(21) Appl. No.: 18/873,097

(22) PCT Filed: Jun. 15, 2023
(86) PCT No.: PCT/US2023/025459

§ 371 Date: Dec. 9, 2024

Related U.S. Application Data
(60) Provisional application No. 63/352,531, filed on Jun. 15, 2022.

(51) Int. Cl. H10F 19/80; H01L 23/15; H02S 40/34; H10F 19/40; H10F 77/30

(52) U.S. Cl. CPC H10F 19/807; H01L 23/15; H02S 40/34; H10F 19/40; H10F 19/804; H10F 77/315

(57) ABSTRACT

Various aspects of solar modules are set forth herein, at least one solar cell having a configured between a first substrate and a second substrate with an encapsulant configured between the first substrate and the second substate to retain the solar cell in place between the first substrate and the second substrate; wherein at least one of the first substrate and the second substrate is a borosilicate glass composition, comprising: at least 75 mol % SiO₂; at least 10 mol % B₂O₃; and Al₂O₃ in an amount such that sum of SiO₂, B₂O₃, and Al₂O₃ is at least 90 mol %.

### CROSS-REFERENCE TO RELATED APPLICATIONS

This application claims the benefit of priority under 35 U.S.C. § 119 of U.S. Provisional Application No. 63/352,531 filed Jun. 15, 2022, the content of which is incorporated herein by reference in its entirety.

### FIELD OF THE DISCLOSURE

The disclosure relates to glass compositions and glass articles made therefrom, and more particularly to borosilicate glass compositions capable of being fusion formed at relatively large thicknesses and glass articles made therefrom.

### BACKGROUND

Glass is used in windows due to its optical clarity and durability. Automotive and architectural windows may include a single glass ply or a laminate that includes two glass plies with an interlayer of a polymeric material disposed in between. For automotive applications in particular, there is a trend toward using laminates for improved fuel economy and/or impact performance. Certain laminate designs may utilize a thicker outer glass ply and a thin inner glass ply. For example, the thicker glass ply may be a soda-lime glass, which is susceptible to thermal shock and to cracking upon impact by, e.g., a rock or other debris thrown from a roadway. Accordingly, there is a need for improved glasses for use as a thicker outer glass ply in a laminate.

### SUMMARY

According to an aspect, embodiments of the present disclosure relate to a borosilicate glass composition. Unless otherwise specified, the glass compositions disclosed herein are described in mole percent (mol %) as analyzed on an oxide basis. In one or more embodiments, the borosilicate glass composition includes at least 74 mol % SiO₂, at least 10 mol % B₂O₃, and Al₂O₃ in an amount such that sum of SiO₂, B₂O₃, and Al₂O₃ is at least 90 mol %. In one or more embodiments, the borosilicate glass composition has a liquidus viscosity of greater than 500 kP. In one or more embodiments, the borosilicate glass composition has a temperature at which a viscosity of the borosilicate glass composition is 200 P of 1725° C. or less.

According to another aspect, embodiments of the present disclosure relate to a glass ply. The glass ply has a first major surface and a second major surface opposite to the first major surface. The glass ply is made of one or more embodiments of the borosilicate glass composition as described herein.

According to still another aspect, embodiments of the present disclosure relate to a laminate. The laminate includes a first glass ply according to one or more embodiments of the glass ply described herein. The laminate also includes a second glass ply and an interlayer bonding the first glass ply to the second glass ply.

According to yet another aspect, embodiments of the present disclosure relate to an automotive glazing. The automotive glazing is made from the laminate according to the previously described laminate.

According to a further aspect, embodiments of the present disclosure relate to a vehicle. The vehicle includes a body defining an interior of the vehicle and at least one opening and the automotive glazing as described disposed in the at least one opening. In the vehicle, the second glass ply is arranged facing the interior of the vehicle, and the first glass ply faces an exterior of the vehicle. In one or more embodiments, the first glass ply is arranged facing the interior of the vehicle and the second glass ply faces an exterior of the vehicle.

According to still a further aspect, embodiments of the present disclosure relate to a method of forming a glass ply. The glass ply has a first major surface and a second major surface. In the method, a trough in an isopipe is overflowed with at least two streams of a borosilicate glass composition having a liquidus viscosity of greater than 500 kP and a temperature at which the viscosity of the glass composition is 200 P of less than 1725° C. In one or more embodiments, the borosilicate glass composition includes at least 74 mol % SiO₂ and at least 10 mol % of B₂O₃. Further, in one or more embodiments, the composition includes a combined amount of SiO₂. B₂O₃, and Al₂O₃ is at least 90 mol %. In one or more embodiments of the method, the at least two streams of the borosilicate glass composition are fused at a root of the isopipe to form the glass ply having a thickness of at least 2 mm between the first major surface and the second major surface.

According to yet another aspect, embodiments of the present disclosure relate to a glass ply. The glass ply has a first major surface and a second major surface opposite to the first major surface. The glass ply is made of a borosilicate glass composition. When the glass ply is subjected to a quasi-static 2 kgf indentation load with a Vickers tip, the glass ply exhibits a ring crack and a plurality of radial cracks, and each radial crack of the plurality of radial cracks is bounded by the ring crack.

According to still yet another aspect, embodiments of the present disclosure relate to a glass laminate. The glass laminate includes a first glass ply, a second glass ply, and an interlayer. The first glass ply has a first major surface and a second major surface opposite to the first major surface. The first glass ply is made of a borosilicate glass composition. The second glass ply has a third major surface and a fourth major surface opposite to the third major surface. The interlayer bonds the second major surface of the first glass ply to the third major surface of the second glass ply. The borosilicate glass composition includes at least 74 mol % SiO₂, at least 10 mol % B₂O₃, and Al₂O₃ in an amount such that sum of SiO₂, B₂O₃, and Al₂O₃ is at least 90 mol %.

According to a still further embodiment, embodiments of the present disclosure relate to a system including a sensor and a glass laminate. The glass laminate includes a first glass ply having a first major surface and a second major surface opposite to the first major surface. The first glass ply is made of a borosilicate glass composition. The glass laminate includes a second glass ply having a third major surface and a fourth major surface opposite to the third major surface. An interlayer bonds the second major surface of the first glass ply to the third major surface of the second glass ply. The borosilicate glass composition includes at least 74 mol % SiO₂, at least 10 mol % B₂O₃, and Al₂O₃ in an amount such that sum of SiO₂, B₂O₃, and Al₂O₃ is at least 90 mol %. The sensor is configured to receive, transmit, or both receive and transmit signals through the glass laminate, and the signals have a peak wavelength in a range of 400 nm to 750 nm or a range of 1500 nm or greater.

According to another aspect, embodiments of the present disclosure relate to a glass laminate. The glass laminate includes a first glass ply having a first major surface and a second major surface opposite to the first major surface. The first glass ply is a fusion-formed borosilicate glass composition. The glass laminate also includes a second glass ply having a third major surface and a fourth major surface opposite to the third major surface. Further, the glass laminate includes an interlayer bonding the second major surface of the first glass ply to the third major surface of the second glass ply. Transmission of ultraviolet light having a wavelength in a range of 300-380 nm through the glass laminate is 75% or less. Transmission of light in the visible spectrum through the glass laminate is 73% or more, and total solar transmission through the glass laminate is 61% or less.

According to another aspect, embodiments of the present disclosure relate to a glass composition made up of SiO₂ in an amount in a range from about 72 mol % to about 80 mol %, Al₂O₃ in an amount in a range from about 2.5 mol % to about 5 mol %, and B₂O₃ in an amount in a range from about 11.5 mol % to about 14.5 mol %. The glass composition has a liquidus viscosity of greater than 500 kP, and the glass composition has a temperature at which a viscosity of the borosilicate glass composition is 200 P of 1725° C. or less.

According to another aspect, embodiments of the present disclosure relate to a glass composition made up of 74 mol % to 80 mol % of SiO₂, 2.5 mol % to 5 mol % of Al₂O₃, 11.5 mol % to 14.5 mol % B₂O₃, 4.5 mol % to 8 mol % Na₂O, 0.5 mol % to 3 mol % K₂O, 0.5 mol % to 2.5 mol % MgO, and 0 mol % to 4 mol % CaO.

Additional features and advantages will be set forth in the detailed description which follows, and in part will be readily apparent to those skilled in the art from that description or recognized by practicing the embodiments as described herein, including the detailed description which follows, the claims, as well as the appended drawings.

It is to be understood that both the foregoing general description and the following detailed description are merely exemplary, and are intended to provide an overview or framework to understanding the nature and character of the claims.

### BRIEF DESCRIPTIONS OF THE DRAWINGS

The accompanying drawings are included to provide a further understanding, and are incorporated in and constitute a part of this specification. The drawings illustrate one or more embodiment(s), and together with the description serve to explain principles and operation of the various embodiments. In the drawings:

FIG. 1 is an illustration of a vehicle including a glass article or laminate according to one or more embodiments;

FIG. 2 is a side view illustration of a glass article according to one or more embodiments:

FIG. 3 is a side view illustration of a laminate including a glass article according to one or more embodiments;

FIG. 4 is a side view illustration of a laminate including a glass article according to one or more embodiments;

FIGS. 5A-5C depict micrographs of cracks resulting from of an indentation test, as well as graphs related thereto, for the disclosed fusion formed borosilicate glass composition (FIG. 5A), a comparative soda-lime glass composition (FIG. 5B), and a comparative float formed borosilicate glass composition (FIG. 5C);

FIGS. 6A and 6B depicts results of a thermal shock test for the disclosed fusion formed borosilicate glass composition (FIG. 6A) and for a comparative soda-lime glass composition (FIG. 6B);

FIG. 7 depicts a fusion-forming apparatus for fusion forming a glass ply of borosilicate glass composition, according to an exemplary embodiment;

FIG. 8 depicts a graph of solar transmittance for various borosilicate glass compositions, according to exemplary embodiments;

FIG. 9 depicts a system including a sensor configured to send and receive signals through a glass laminate having at least one glass ply made of the borosilicate glass composition, according to an exemplary embodiment;

FIGS. 10 and 11 depict plots of visible, total solar, and ultraviolet light transmission as a function of iron content in glass, according to exemplary embodiments; and

FIGS. 12 and 13 depict plots of visible light transmission against total solar transmission for glass compositions, according to exemplary embodiments.

FIG. 14 is a digital image of a glass article in cross-section, according to exemplary embodiments.

FIG. 15 is a plot of transmission measurements for two example compositions, according to exemplary embodiments.

FIG. 16 is a plot of measured retained strength after indentation both prior to and after thermal shock of samples constructed used example compositions described herein, according to exemplary embodiments.

FIG. 17A is an image of a sample constructed in accordance with an example composition described herein having scratches from a Knoop scratching test, according to exemplary embodiments.

FIG. 17B is an image of a sample constructed in accordance with a counter example composition described herein having scratches from a Knoop scratching test, according to exemplary embodiments.

FIG. 17C is an image of a sample constructed in accordance with a counter example composition described herein having scratches from a Knoop scratching test, according to exemplary embodiments.

FIG. 18 provides a schematic cut-away side view of an embodiment of a solar panel 10 having one or more substrates from the borosilicate compositions set forth herein, in conjunction with various aspects of the present disclosure.

FIG. 19A-C provide various schematic embodiments of expanded cut away side views of aspects of incorporating the embodied borosilicate compositions of the present disclosure into variously configured layups within embodied solar modules (FIGS. 19A and 19B) and as a retrofit cover, configured to attach to a surface of a solar panel (FIG. 19C), in accordance with one or more embodiments of the present disclosure.

FIG. 20 provides the transmittance data for iron free-borosilicate glass and clear sodalime glass, plotted as the transmittance percent by wavelength, from 300 nm to 800 nm. Each glass sample was configured at the same thickness, in accordance with one or more aspects of the present disclosure.

FIG. 21 provides a series of SEM images at 20,000× magnification of the surfaces of two glass samples, (1) a sodalime glass (top row) compared to (2) the borosilicate glass composition embodiment detailed above (bottom row), over three conditions: initial state before weathering (initial state); after weathering, and after weathering and washing, in accordance with one or more aspects of the present disclosure.

FIG. 22 provides a comparative analysis which provides an example of how borosilicate glass compositions embodied herein behave to weathering and washing after a scratch test, in accordance with one or more aspects of the present disclosure.

FIG. 23 provides a comparative analysis of images from a microscope under 100× magnification, which depict spots and scratch damage on some samples resulting from a proxy analysis from the automotive field, in accordance with one or more aspects of the present disclosure.

FIG. 24 provides a comparative analysis, depicted as confocal microscopy images, of the samples described in FIG. 23, except that the confocal microscopy images were taken after abrasion (top row) then after weathering and wash process (bottom row), in accordance with one or more aspects of the present disclosure.

FIG. 25A through 25C provides three separate plots of % transmission diffusion over the visible spectrum (nm) and illustrative support for borosilicate glass maintaining transmission after linear abrasion (FIG. 25A), linear abrasion followed by weathering (FIG. 25B), and linear abrasion followed by weathering, then followed by washing (FIG. 25C), in accordance with one or more aspects of the present disclosure.

FIG. 26 A illustrates the crack behavior under subcritical stress, utilizing a Ring-on-Ring test with 3 kgf Vickers indented glass under subcritical crack growth stress for two sets of samples at different applied stresses (30 MPa and 35 MPa), in accordance with one or more aspects of the present disclosure. FIG. 26B depicts two representative images taken at an initial view of a sample (FIG. 26B top) and a representative view of an after run image (FIG. 26B below).

FIGS. 27 and 28 provide illustrative support that one or more borosilicate glass compositions of the present disclosure can be strengthened through at least one of thermal tempering (FIG. 27) or ion exchange (FIG. 28), in accordance with one or more aspects of the present disclosure, in accordance with one or more embodiments of the present disclosure.

### DETAILED DESCRIPTION

Reference will now be made in detail to various embodiments, examples of which are illustrated in the accompanying drawings. Embodiments of the disclosure relate to a borosilicate glass composition that is able to be fusion formed or is fusion-formed to a glass ply having a thicknesses of at least 2 mm, in particular, at least 3 mm, at least 3.3 mm, or at least 3.8 mm. In embodiments, the borosilicate glass composition includes at least 74 mol % SiO₂, at least 10 mol % B₂O₃, and at least some Al₂O₃, and in embodiments, the total amount of SiO₂. B₂O₃, and Al₂O₃ is at least 90 mol %. The borosilicate glass compositions described herein exhibit a liquidus viscosity of at least 500 kiloPoise (kP) and a temperature (T_{200P}) at which the viscosity is 200 Poise (P) of 1725° C. or less.

Further, embodiments of the borosilicate glass composition disclosed herein are particularly suitable for use in laminates for automotive glazing applications. In one or more embodiments, the borosilicate glass composition is used as an outer ply in such laminates. As compared to conventional automotive glazings including soda-lime glass plies, the glass plies made of the disclosed borosilicate glass composition densify during deformation, helping prevent formation (initiation) or spread (propagation) of radial or median cracks that tend to compromise the strength of the glass ply. Further, the borosilicate glass composition disclosed herein is more resistant to thermal shock than soda-lime glass, which also helps to prevent crack initiation and propagation. These performance advantages can be useful when the borosilicate glass composition is used as an inner glass ply or an outer glass ply of a glass laminate. In some instances, these performance advantages are particularly useful when the borosilicate glass composition is used as an outer glass ply in a laminate. These and other aspects and advantages of the disclosed borosilicate glass composition and articles formed therefrom will be described more fully below. The embodiments discussed herein are presented by way of illustration and not limitation.

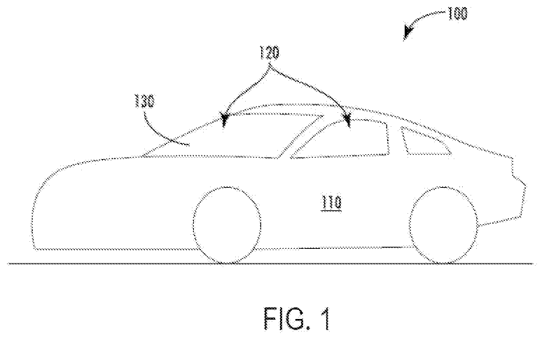

Embodiments to the borosilicate glass composition are described herein in relation to a vehicle 100 as shown in FIG. 1. The vehicle 100 includes a body 110 defining an interior and at least one opening 120 in communication with the interior. The vehicle 100 further includes an automotive glazing 130, i.e., window, disposed in the opening 120. The automotive glazing comprises at least one ply of the borosilicate glass composition described herein. The automotive glazing 130 may form at least one of the sidelights, windshield, rear window, windows, and sunroofs in the vehicle 100. In some embodiments, the automotive glazing 130 may form an interior partition (not shown) within the interior of the vehicle 100, or may be disposed on an exterior surface of the vehicle 100 and form, e.g., an engine block cover, headlight cover, taillight cover, door panel cover, or pillar cover. As used herein, vehicle includes automobiles (an example of which is shown in FIG. 1), rolling stock, locomotive, boats, ships, and airplanes, helicopters, drones, space craft, and the like. Further, while the present disclosure is framed in terms of a vehicle, the borosilicate glass composition may be used in other contexts, such as architectural glazing or bullet-resistant glazing applications.

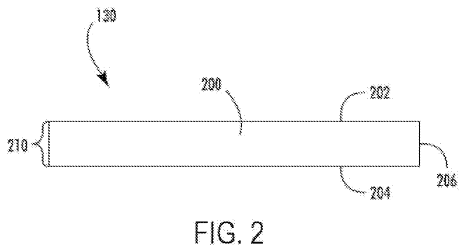

As shown in FIG. 2, in embodiments, the automotive glazing 130 includes at least one glass ply 200 comprising, consisting of or consisting essentially of the embodiments of the borosilicate glass composition described herein. In one or more embodiments, the automotive glazing 130 includes only a single glass ply 200 (i.e., the single glass ply is sometimes referred in the industry as a monolith). As can be seen in FIG. 2, the glass ply 200 has a first major surface 202 and a second major surface 204. The first major surface 202 is opposite to the second major surface 204. A minor surface 206 extends around the periphery of the glass ply 200 and connects the first major surface 202 and the second major surface 204.

A first thickness 210 is defined between the first major surface 202 and the second major surface 204. In embodiments, the first thickness 210 is at least 0.5 mm, at least 1 mm, at least 2 mm, at least 3 mm, at least 3.3 mm, or at least 3.8 mm. In one or more embodiments, the first thickness is in a range from about 0.1 mm to about 6 mm, 0.2 mm to about 6 mm, 0.3 mm to about 6 mm, 0.4 mm to about 6 mm, 0.5 mm to about 6 mm, 0.6 mm to about 6 mm, 0.7 mm to about 6 mm, 0.8 mm to about 6 mm, 0.9 mm to about 6 mm, 1 mm to about 6 mm, 1.1 mm to about 6 mm, 1.2 mm to about 6 mm, 1.3 mm to about 6 mm, 1.4 mm to about 6 mm, 1.5 mm to about 6 mm, 1.6 mm to about 6 mm, from about 1.8 mm to about 6 mm, from about 2 mm to about 6 mm, from about 2.2 mm to about 6 mm, from about 2.4 mm to about 6 mm, from about 2.6 mm to about 6 mm, from about 2.8 mm to about 6 mm, from about 3 mm to about 6 mm, from about 3.1 mm to about 6 mm, from about 3.2 mm to about 6 mm, from about 3.3 mm to about 6 mm, from about 3.4 mm to about 6 mm, from about 3.5 mm to about 6 mm, from about 3.6 mm to about 6 mm, from about 3.7 mm to about 6 mm, from about 3.8 mm to about 6 mm, from about 3.9 mm to about 6 mm, from about 4 mm to about 6 mm, from about 4.2 mm to about 6 mm, from about 4.4 mm to about 6 mm, from about 4.5 mm to about 6 mm, from about 4.6 mm to about 6 mm, from about 4.8 mm to about 6 mm, from about 5 mm to about 6 mm, from about 5.2 mm to about 6 mm, from about 5.4 mm to about 6 mm, from about 5.5 mm to about 6 mm, from about 5.6 mm to about 6 mm, from about 5.8 mm to about 6 mm, from about 1.6 mm to about 5.8 mm, from about 1.6 mm to about 5.6 mm, from about 1.6 mm to about 5.5 mm, from about 1.6 mm to about 5.4 mm, from about 1.6 mm to about 5.2 mm, from about 1.6 mm to about 5 mm, from about 1.6 mm to about 4.8 mm, from about 1.6 mm to about 4.6 mm, from about 1.6 mm to about 4.4 mm, from about 1.6 mm to about 4.2 mm, from about 1.6 mm to about 4 mm, from about 1.6 mm to about 3.9 mm, from about 1.6 mm to about 3.8 mm, from about 1.6 mm to about 3.7 mm, from about 1.6 mm to about 3.6 mm, from about 1.6 mm to about 3.5 mm, from about 1.6 mm to about 3.4 mm, from about 1.6 mm to about 3.3 mm, from about 1.6 mm to about 3.2 mm, from about 1.6 mm to about 3.1 mm, from about 1.6 mm to about 3 mm, from about 1.6 mm to about 2.8 mm, from about 1.6 mm to about 2.6 mm, from about 1.6 mm to about 2.4 mm, from about 1.6 mm to about 2.2 mm, from about 1.6 mm to about 2 mm, from about 1.6 mm to about 1.8 mm, from about 3 mm to about 5 mm, or from about 3 mm to about 4 mm. In other embodiments, the glass ply may be thinner than 2 mm or thicker than 6 mm.

In some embodiments, the glass ply may have curvature, such as rounded geometry or tubular, such as where the first major surface is an exterior and the second major surface is an interior surface of the tube. In some embodiments, a perimeter of the glass ply is generally rectilinear and in other embodiments the perimeter is complex. The first major surface may have apertures, slots, holes, bumps, dimples, or other geometry.

As will be discussed more fully below, in one or more embodiments, the glass ply 200 is a fusion-formed borosilicate glass composition having a liquidus viscosity of at least 500 kP and a T_{200P} of 1725° C. or less.

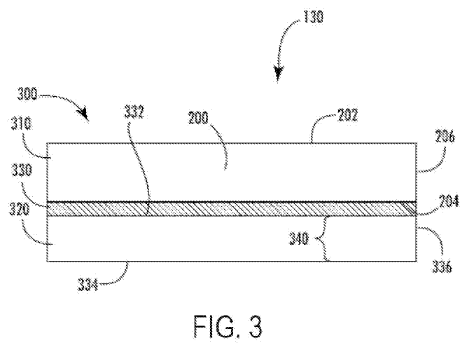

FIG. 3 depicts an embodiment of the automotive glazing 130 in which the automotive glazing 130 is a laminate structure 300 including the glass ply 200 of FIG. 2 as a first glass ply 310. As referenced above, the glass ply 200 can comprise, consist of or consist essentially of an embodiment of the borosilicate glass composition described herein. In the embodiment shown in FIG. 3, the first glass ply 310 is joined to a second glass ply 320 by an interlayer 330. In particular, the second glass ply 320 has a third major surface 332 and a fourth major surface 334. The third major surface 332 is opposite to the fourth major surface 334. A minor surface 336 extends around the periphery of the second glass ply 320 and connects the third major surface 332 and the fourth major surface 334.

A second thickness 340 is defined between the third major surface 332 and the fourth major surface 334. In embodiments, the second thickness 340 is less than the first thickness 210 of the first glass ply 310. In embodiments, the second glass thickness is 2 mm or less. In embodiments, the total glass thickness (i.e., the first thickness 210 plus the second thickness 340) is 8 mm or less, 7 mm or less, 6.5 mm or less, 6 mm or less, 5.5 mm or less, or 5 mm or less. In embodiments, the lower limit of the total glass thickness is about 2 mm.

In embodiments, the second glass ply 320 comprises a glass composition that is different from the borosilicate glass composition of the first glass ply 310. In embodiments, the second glass composition comprises a soda lime silicate composition, an aluminosilicate glass composition, an alkali aluminosilicate glass composition, an alkali containing borosilicate glass composition, an alkali aluminophosphosilicate glass composition, or an alkali aluminoborosilicate glass composition.

Further, in embodiments, the first glass ply 310 and/or the second glass ply 320 may be strengthened. For example, the first glass ply 310 and/or the second glass ply 320 may be thermally, chemically and/or mechanically strengthened. In particular, in embodiments, the first glass ply 310 and/or the second glass ply 320 is chemically strengthened through an ion-exchange treatment. In one or more embodiments, the first glass ply 310 and/or the second glass ply 320 is mechanically strengthened by utilizing a mismatch of the coefficient of thermal expansion between portions of the ply to create a compressive stress region and a central region exhibiting a tensile stress. In some embodiments, the first glass ply 310 and/or the second glass ply 320 may be strengthened thermally by heating the glass ply to a temperature above the glass transition point and then rapidly quenching. In some embodiments, various combinations of chemical, mechanical and thermal strengthening may be used to strengthen the second glass ply 320. In one or more embodiments, the second glass ply 320 is strengthened while the first glass ply 310 is unstrengthened a (but may optionally be annealed), and exhibits a surface compressive stress of less than about 3 MPa, or about 2.5 MPa or less, 2 MPa or less, 1.5 MPa or less, 1 MPa or less, or about 0.5 MPa or less.

In one or more embodiments, the interlayer 330 bonds the second major surface 204 of the first glass ply 310 to the third major surface 332 of the second glass ply 320. In embodiments, the interlayer 330 comprises a polymer, such as at least one of polyvinyl butyral (PVB), acoustic PVB (APVB), an ionomer, an ethylene-vinyl acetate (EVA) and a thermoplastic polyurethane (TPU), a polyester (PE), a polyethylene terephthalate (PET), or the like. The thickness of the interlayer may be in the range from about 0.5 mm to about 2.5 mm, in particular from about 0.7 mm to about 1.5 mm. In other embodiments the thickness may be less than 0.5 mm or more than 2.5 mm. Further, in embodiments, the interlayer 330 may comprise multiple polymeric layers or films providing various functionalities to the laminate structure 300. For example, the interlayer 330 may incorporate at least one of a display feature, solar insulation, sound dampening, an antenna, an anti-glare treatment, or an anti-reflective treatment, among others. In particular embodiments, the interlayer 330 is modified to provide ultraviolet (UV) absorption, infrared (IR) absorption, IR reflection, acoustic control/dampening, adhesion promotion, and tint. The interlayer 330 can be modified by a suitable additive such as a dye, a pigment, dopants, etc. to impart the desired property.

In one or more embodiments, the first glass ply 310 or second glass play 320 may be provided with a functional or decorative coating in addition to or in the alternative to the functional or decorative film of the interlayer 330. In embodiments, the coating is at least one of an infrared reflective (IRR) coating, frit, anti-reflective coating, or pigment coating. In an example embodiment of an IRR, the second major surface 204 of the first glass ply 310 or the third major surface 332 of the second glass ply 320 is coated with an infrared-reflective film and, optionally, one or more layers of a transparent dielectric film. In embodiments, the infrared-reflecting film comprises a conductive metal, such as silver, gold, or copper, that reduces the transmission of heat through the coated ply 310, 320. In embodiments, the optional dielectric film can be used to anti-reflect the infrared-reflecting film and to control other properties and characteristics of the coating, such as color and durability. In embodiments, the dielectric film comprises one or more oxides of zinc, tin, indium, bismuth, and titanium, among others. In an example embodiment, the IRR coating includes one or two silver layers each sandwiched between two layers of a transparent dielectric film. In embodiments, the IRR coating is applied using, e.g., physical or chemical vapor deposition or via lamination.

In embodiments, one or both of the first glass ply 310 and the second glass ply 320 includes frit. In embodiments, the frit is applied, e.g., to the second major surface 204 of the first glass ply 310, the third major surface 332 of the second glass ply 320, and/or the fourth major surface 334 of the second glass ply 320. In embodiments, the frit provides an enhanced bonding surface for adhesives such as the interlayer 330 or an adhesive joining the glazing 130 to a bonding surface defining an opening 120 in the vehicle body 110. Additionally, in embodiments, the frit provides a decorative border for the glazing 130. Further, in embodiments, the frit may be used in addition to the IRR coating described above. In embodiments, the frit is an enamel frit. In other embodiments, the frit is designed such that it is ion-exchangeable. That is, the frit can be applied to an ion-exchangeable glass prior to undergoing an ion-exchange treatment. Such frit is configured to allow the exchange of ions between the glass and the treatment bath. In embodiments, the frit is a Bi—Si—B alkali system, a Zn-based Bi-system, a Bi—Zn-system, a Bi-system, an Si—Zn—B—Ti system with no or low Bi, an Si—Bi—Zn—B-alkali system, and/or an Si—Bi—Ti—B—Zn-alkali system, among others. An example of an ion-exchangeable frit, including colorant, comprises 45.11 mol % B₂O₃, 20.61 mol % SiO₂, 13.56 mol % Cr₂O₃, 5.11 mol % CuO, 3.48 mol % MnO, 3.07 mol % ZnO, 2.35 mol % B₂O₃, 1.68 mol % TiO₂, 1.60 mol % Na₂O, 1.50 mol % Li₂O, 0.91 mol % K₂O, 0.51 mol % Al₂O₃, 0.15 mol % P₂O₅, 0.079 mol % SO₃, 0.076 mol % BaO, 0.062 mol % ZrO₂, 0.060 mol % Fe₂O₃, 0.044 mol % MoO₃, 0.048 mol % CaO, 0.018 mol % Nb₂O₅, 0.006 mol % Cl, and 0.012 mol % SrO. Other examples of ion-exchangeable frits are disclosed in U.S. Pat. No. 9,346,708B2 (application Ser. No. 13/464,493, filed May 4, 2012) and U.S. Publication No. 2016/0002104A1 (application Ser. No. 14/768,832, filed Aug. 19, 2015), both of which are incorporated herein by reference in their entireties.

In embodiments, the second glass ply 320 may be provided with a colorant coating comprised of an ink, such as an organic ink. In embodiments particularly suitable for such a colorant coating, the colorant coating is applied to the third major surface 332 of the second glass ply 320 or to the fourth major surface 334 of the second glass ply 320, and the second glass ply 320 is cold-formed against the first glass ply 310. Advantageously, such colorant coatings can be applied to the second glass ply 320 while the second glass ply 320 is in a planar configuration, and then the second glass ply 320 can be cold formed to a curved configuration without disrupting the colorant coating, e.g., organic ink coating. In an embodiment, the colorant coating comprises at least one pigment, at least one mineral filler, and a binder comprising an alkoxysilane functionalized isocyanurate or an alkoxysilane functionalized biuret. Examples of such colorant coatings are described in European Patent No. 2617690B1, incorporated herein by reference in its entirety. Other suitable colorant coatings and methods of applying the colorant coatings are described in U.S. Publication No. 2020/0171800A1 (application Ser. No. 16/613,010, filed on Nov. 12, 2019) and U.S. Pat. No. 9,724,727 (application Ser. No. 14/618,398, filed Feb. 10, 2015), both of which are incorporated herein by reference in their entireties.

In embodiments, the coating is an anti-reflective coating. In particular embodiments, the anti-reflective coating is applied to the fourth major surface 334 of the second glass ply 320. In embodiments, the anti-reflective coating comprises multiple layers of low and high index materials or low, medium, and high index materials. For example, in embodiments, the anti-reflective coating includes from two to twelve layers of alternating low and high index materials, such as silica (low index) and niobia (high index). In another example embodiment, the anti-reflective coating includes from three to twelve layers of repeating low, medium, and high index materials, such as silica (low index), alumina (medium index), and niboia (high index). In still other embodiments, the low index material in the stack may be an ultra low index material, such as magnesium fluoride or porous silica. In general, anti-reflective coatings having more layers in the stack will perform better at higher angles of incidence than anti-reflective coatings having less layers in the stack. For example, at an angle of incidence of, e.g., greater than 60°, an anti-reflective coating stack having four layers will perform better (less reflection) than an anti-reflective coating stack having two layers. Further, in embodiments, an anti-reflective coating stack having an ultra low index material will perform better (less reflection) than an anti-reflective coating stack having a low index material. Other anti-reflective coatings known in the art may also be suitable for application to the laminate 300.

In embodiments, the glass ply 200 or laminate 300 exhibits at least one curvature comprising a radius of curvature that is in the range of 300 mm to about 10 m along at least a first axis. In embodiments, the glass ply 200 or laminate 300 exhibits at least one curvature comprising a radius of curvature that is in the range of 300 mm to about 10 m along a second axis that is transverse, in particular perpendicular, to the first axis. In other embodiments the glass ply exhibits curvature but the curvature has a radius of curvature less than 300 μm or greater than 10 m. In some embodiments, the curvature is complex and changing.

In embodiments, the curvature(s) are introduced into the glass ply 200 or each glass ply 310, 320 of the glass laminate 300 through a thermal process. The thermal process may include a sagging process that uses gravity to shape the glass ply 200 or glass plies 310, 320 when heated. In the sagging step, a glass ply, such as glass ply 200, is placed on a mold having an open interior, heated in a furnace (e.g., a box furnace, or a lehr furnace), and allowed to gradually sag under the influence of gravity into the open interior of the mold. In one or more embodiments, the thermal process may include a pressing process that uses a mold to shape the glass ply 200 or glass plies 310, 320 when heated or while heating. In some embodiments, two glass plies, such as glass plies 310, 320, are shaped together in a “pair-shaping” process. In such a process, one glass ply is placed on top of another glass ply to form a stack (which may also include an intervening release layer), which is placed on the mold. In embodiments, to facilitate the pair-shaping process, the glass ply 310, 320 used as an inner and/or thinner glass ply has a pair-shaping temperature (temperature at 10¹¹ Poise) that is greater than the outer and/or thicker glass ply 310, 320.

In one or more embodiments, the mold may have an open interior for use in a sagging process. The stack and mold are both heated by placing them in the furnace, and the stack is gradually heated to the bend or sag temperature of the glass plies. During this process, the plies are shaped together to a curved shape. Advantageously, the viscosity curve for at least some of the presently disclosed borosilicate glass composition at a viscosity of 10¹¹ Poise is similar to conventional float-formed borosilicate glass compositions, allowing for existing equipment and techniques to be utilized for forming the glass ply 200 or plies 310, 320.

According to an exemplary embodiment, heating time and temperature are selected to obtain the desired degree of curvature and final shape. Subsequently, the glass ply or glass plies are removed from the furnace and cooled. For pair-shaped glass plies, the two glass plies are separated, re-assembled with an interlayer, such as interlayer 330, between the glass plies and heated, e.g., under vacuum to seal the glass plies and interlayer together into a laminate.

In one or more embodiments, only one glass ply is curved using heat (e.g., by a sag process or press process), and the other glass ply is curved using a cold-forming process by pressing the glass ply to be curved into conformity with the already curved glass ply at a temperature less than the softening temperature of the glass composition (in particular at a temperature of 200° C. or less, 100° C. or less, 50° C. or less, or at room temperature). Pressure to cold-form the glass ply against the other glass ply may be provided by, e.g., a vacuum, a mechanical press, or one or more clamps. The cold-formed glass ply may be held into conformity with the curved glass ply via the interlayer and/or mechanically clamped thereto or otherwise coupled.

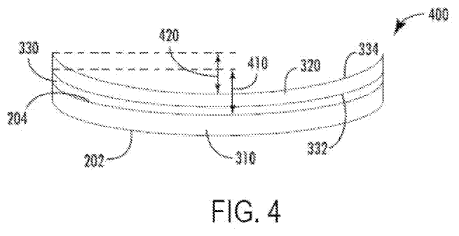

FIG. 4 depicts an exemplary embodiment of a curved glass laminate 400. As can be seen in FIG. 4, the second major surface 204 of the first glass ply 310 has a first curvature depth 410 defined as the maximum depth from planar (dashed line) of the second major surface 204. In embodiments in which the second glass ply 320 is curved, the fourth major surface 334 of the second glass ply 320 has a second curvature depth 420 defined as the maximum depth from planar (dashed line) of the fourth major surface 334.

In embodiments, one or both the first curvature depth 410 and the second curvature depth 420 is about 2 mm or greater. Curvature depth may be defined as maximum distance a surface is distanced orthogonally from a plane defined by points on a perimeter of that surface. For example, one or both the first curvature depth 410 and the second curvature depth 420 may be in a range from about 2 mm to about 30 mm. In embodiments, the first curvature depth 410 and the second curvature depth 420 are substantially equal to one another. In one or more embodiments, the first curvature depth 410 is within 10% of the second curvature depth 420, in particular within 5% of the second curvature depth 420. For illustration, the second curvature depth 420 is about 15 mm, and the first curvature depth 410 is in a range from about 13.5 mm to about 16.5 mm (or within 10% of the second sag depth 420).

In one or more embodiments, the first curved glass ply 310 and the second curved glass ply 330 comprise a shape deviation therebetween the first curved glass ply 310 and the second curved glass ply 320 of 5 mm or less as measured by an optical three-dimensional scanner such as the ATOS Triple Scan supplied by GOM GmbH, located in Braunschweig, Germany. In one or more embodiments, the shape deviation is measured between the second major surface 204 and the third major surface 332, or between the first major surface 202 and the fourth major surface 334. In one or more embodiments, the shape deviation between the first glass ply 310 and the second glass ply 320 is about ±4 mm or less, about ±3 mm or less, about ±2 mm or less, about ±1 mm or less, about ±0.8 mm or less, about ±0.6 mm or less, about ±0.5 mm or less, about ±0.4 mm or less, about ±0.3 mm or less, about ±0.2 mm or less, or about ±0.1 mm or less. As used herein, the shape deviation applies to stacked glass plies (i.e., with no interlayer) and refers to the maximum deviation from the desired curvature between coordinating positions on the respective second major surface 204 and third major surface 332 or the first major surface 202 and the fourth major surface 334.

In one or more embodiments, one of or both the first major surface 202 and the fourth major surface 334 exhibit minimal optical distortion. For example, one of or both the first major surface 202 and the fourth major surface 334 exhibit less than about 400 millidiopters, less than about 300 millidiopters, less than about 250 millidiopters, or less than about 200 millidiopters as measured by an optical distortion detector using transmission optics according to ASTM 1561. A suitable optical distortion detector is supplied by ISRA VISION AG, located in Darmstadt, Germany, under the tradename SCREENSCAN-Faultfinder. In one or more embodiments, one of or both the first major surface 202 and the fourth major surface 334 exhibit about 190 millidiopters or less, about 180 millidiopters or less, about 170 millidiopters or less, about 160 millidiopters or less, about 150 millidiopters or less, about 140 millidiopters or less, about 130 millidiopters or less, about 120 millidiopters or less, about 110 millidiopters or less, about 100 millidiopters or less, about 90 millidiopters or less, about 80 millidiopters or less, about 70 millidiopters or less, about 60 millidiopters or less, or about 50 millidiopters or less. As used herein, the optical distortion refers to the maximum optical distortion measured on the respective surfaces.

It is believed that the reduction in optical distortion for the glass ply 200 or plies 310, 320 is related to both the borosilicate glass composition disclosed herein and the fusion forming process made possible by the disclosed borosilicate glass composition. As related to the forming process, conventional float glass techniques for forming borosilicate glass compositions involve floating molten glass on liquid tin, and the glass naturally has a thickness of 6 mm or more when floating on tin. To produce lower thicknesses, the glass is stretched or drawn while floating, which produces variations in the thickness across the surface of the glass known as drawlines and which produces internal stresses. The drawlines and internal stresses can both contribute to optical distortion. By fusion forming the borosilicate glass composition according to the present disclosure, such drawlines and internal stresses are substantially avoided. Further, the outer surfaces of the glass ply 200 or plies 310, 320 are not in contact with any structures during fusion forming, which also reduces optical distortion. With respect to the composition, the borosilicate glass disclosed herein allows for fusion forming of the glass ply 200 or plies 310, 320 by providing a liquidus viscosity of at least 500 kP and a T_{200P} of 1725° C. or less. Moreover, the borosilicate glass composition according to the present disclosure is also believed to reduce refractive index variation across the surface of the glass ply 200 or plies 310, 320 as compared to conventionally used soda-lime silicate glass compositions. Variation in refractive index is also known to cause optical distortion, and thus, reduction in refractive index variation is expected to decrease optical distortion.

In one or more embodiments, the first major surface or the second major surface of the first curved glass ply exhibits low membrane tensile stress. Membrane tensile stress can occur during cooling of curved plies and laminates. As the glass cools, the major surfaces and edge surfaces (orthogonal to the major surfaces) can develop surface compression, which is counterbalanced by a central region exhibiting a tensile stress. Such stresses can, in certain circumstances, be problematic around the periphery where edge cooling effects set up stresses and bending tools create thermal gradients that generate stresses. The low CTE associated with embodiments of the presently disclosed borosilicate glass composition minimizes adverse residual stresses that may arise during the annealing process of hot forming. Such stresses are proportional to the CTE, and thus, by decreasing the CTE of the borosilicate glass composition, the residual stresses are also decreased.

Bending or shaping can introduce additional surface tension near the edge and causes the central tensile region to approach the glass surface. Accordingly, membrane tensile stress is the tensile stress measured near the edge (e.g., about 10-25 mm from the edge surface). In one or more embodiments, the membrane tensile stress at the first major surface or the second major surface of the first curved glass ply is less than about 7 megaPascals (MPa) as measured by an edge stress meter according to ASTM C1279. An example of such a surface stress meter is an Edge Stress Meter or VRP (both commercially available from Strainoptic Technologies). In one or more embodiments, the membrane tensile stress at the first major surface or the second major surface of the first curved glass ply is about 6 MPa or less, about 5 MPa or less, about 4 MPa or less, or about 3 MPa or less. In one or more embodiments, the lower limit of membrane tensile stress is about 0.01 MPa or about 0.1 MPa. In other embodiments, membrane tensile stress may be negligible (e.g., about 0). As recited herein, stress is designated as either compressive or tensile, with the magnitude of such stress provided as an absolute value.

In one or more embodiments, the laminate 300, 400 may have a thickness of 10 mm or less, 9 mm or less, 8 mm or less, 7 mm or less, or 6 mm or less where the thickness comprises the sum of thicknesses of the first glass ply 310, the second glass ply 320, and the interlayer 330. In various embodiments, the laminate 300, 400 may have a thickness in the range of about 1.8 mm to about 10 mm, or in the range of about 1.8 mm to about 9 mm, or in the range of about 1.8 mm to about 8 mm, or in the range of about 1.8 mm to about 7 mm, or in the range of about 1.8 mm to about 6 mm, or in the range of about 1.8 mm to about 5 mm, or 2.1 mm to about 10 mm, or in the range of about 2.1 mm to about 9 mm, or in the range of about 2.1 mm to about 8 mm, or in the range of about 2.1 mm to about 7 mm, or in the range of about 2.1 mm to about 6 mm, or in the range of about 2.1 mm to about 5 mm, or in the range of about 2.4 mm to about 10 mm, or in the range of about 2.4 mm to about 9 mm, or in the range of about 2.4 mm to about 8 mm, or in the range of about 2.4 mm to about 7 mm, or in the range of about 2.4 mm to about 6 mm, or in the range of about 2.4 mm to about 5 mm, or in the range of about 3.4 mm to about 10 mm, or in the range of about 3.4 mm to about 9 mm, or in the range of about 3.4 mm to about 8 mm, or in the range of about 3.4 mm to about 7 mm, or in the range of about 3.4 mm to about 6 mm, or in the range of about 3.4 mm to about 5 mm. In other embodiments, the laminate thickness may be less than 1.8 mm or greater than 10 mm.

In one or more embodiments the second curved glass ply (or the second glass ply used to form the second curved glass ply) is relatively thin in comparison to the first curved glass ply (or the first glass ply used to form the first curved glass ply). In other words, the first curved glass ply (or the first glass ply used to form the first curved glass ply) has a thickness greater than the second curved glass ply (or the second glass ply used to form the second curved glass ply). In one or more embodiments, the first thickness (or the thickness of the first glass ply used to form the first curved glass ply) is more than two times the second thickness. In one or more embodiments, the first thickness (or the thickness of the first glass ply used to form the first curved glass ply) is in the range from about 1.5 times to about 10 times the second thickness (e.g., from about 1.75 times to about 10 times, from about 2 times to about 10 times, from about 2.25 times to about 10 times, from about 2.5 times to about 10 times, from about 2.75 times to about 10 times, from about 3 times to about 10 times, from about 3.25 times to about 10 times, from about 3.5 times to about 10 times, from about 3.75 times to about 10 times, from about 4 times to about 10 times, from about 1.5 times to about 9 times, from about 1.5 times to about 8 times, from about 1.5 times to about 7.5 times, from about 1.5 times to about 7 times, from about 1.5 times to about 6.5 times, from about 1.5 times to about 6 times, from about 1.5 times to about 5.5 times, from about 1.5 times to about 5 times, from about 1.5 times to about 4.5 times, from about 1.5 times to about 4 times, from about 1.5 times to about 3.5 times, from about 2 times to about 7 times, from about 2.5 times to about 6 times, from about 3 times to about 6 times). In other embodiments, the plies may be otherwise sized, such as the second ply being thicker or the same thickness as the first.

In one or more embodiments, the second thickness (or the thickness of the second glass ply used to form the second curved glass ply) is less than 2.0 mm (e.g., 1.95 mm or less, 1.9 mm or less, 1.85 mm or less, 1.8 mm or less, 1.75 mm or less, 1.7 mm or less, 1.65 mm or less, 1.6 mm or less, 1.55 mm or less, 1.5 mm or less, 1.45 mm or less, 1.4 mm or less, 1.35 mm or less, 1.3 mm or less, 1.25 mm or less, 1.2 mm or less, 1.15 mm or less, 1.1 mm or less, 1.05 mm or less, 1 mm or less, 0.95 mm or less, 0.9 mm or less, 0.85 mm or less, 0.8 mm or less, 0.75 mm or less, 0.7 mm or less, 0.65 mm or less, 0.6 mm or less, 0.55 mm or less, 0.5 mm or less, 0.45 mm or less, 0.4 mm or less, 0.35 mm or less, 0.3 mm or less, 0.25 mm or less, 0.2 mm or less, 0.15 mm or less, or about 0.1 mm or less). The lower limit of thickness may be 0.1 mm, 0.2 mm or 0.3 mm. In some embodiments, the second thickness (or the thickness of the second glass ply used to form the second curved glass ply) is in the range from about 0.1 mm to less than about 2.0 mm, from about 0.1 mm to about 1.9 mm, from about 0.1 mm to about 1.8 mm, from about 0.1 mm to about 1.7 mm, from about 0.1 mm to about 1.6 mm, from about 0.1 mm to about 1.5 mm, from about 0.1 mm to about 1.4 mm, from about 0.1 mm to about 1.3 mm, from about 0.1 mm to about 1.2 mm, from about 0.1 mm to about 1.1 mm, from about 0.1 mm to about 1 mm, from about 0.1 mm to about 0.9 mm, from about 0.1 mm to about 0.8 mm, from about 0.1 mm to about 0.7 mm, from about 0.2 mm to less than about 2.0 mm, from about 0.3 mm to less than about 2.0 mm, from about 0.4 mm to less than about 2.0 mm, from about 0.5 mm to less than about 2.0 mm, from about 0.6 mm to less than about 2.0 mm, from about 0.7 mm to less than about 2.0 mm, from about 0.8 mm to less than about 2.0 mm, from about 0.9 mm to less than about 2.0 mm, or from about 1.0 mm to about 2.0 mm. In other embodiments, the second ply can be thicker than 2.0 mm or thinner than 0.1 mm, such as less than 700 μm, 500 μm, 300 μm, 200 μm, 100 μm, 80 μm, 40 μm, and/or at least 10 μm.

In some embodiments, the first thickness (or the thickness of the first glass ply used to form the first curved glass ply) is about 2.0 mm or greater. In such embodiments, first thickness (or the thickness of the first glass ply used to form the first curved glass ply) and the second thickness (or the thickness of the second glass ply used to form the second curved glass ply) differ from one another. For example, the first thickness (or the thickness of the first glass ply used to form the first curved glass ply) is about 2.0 mm or grater, about 2.1 mm or greater, about 2.2 mm or greater, about 2.3 mm or greater, about 2.4 mm or greater, about 2.5 mm or greater, about 2.6 mm or greater, about 2.7 mm or greater, about 2.8 mm or greater, about 2.9 mm or greater, about 3.0 mm or greater, about 3.1 mm or greater, about 3.2 mm or greater, about 3.3 mm or greater, 3.4 mm or greater, 3.5 mm or greater, 3.6 mm or greater, 3.7 mm or greater, 3.8 mm or greater, 3.9 mm or greater, 4 mm or greater, 4.2 mm or greater, 4.4 mm or greater, 4.6 mm or greater, 4.8 mm or greater, 5 mm or greater, 5.2 mm or greater, 5.4 mm or greater, 5.6 mm or greater, 5.8 mm or greater, or 6 mm or greater. In some embodiments the first thickness (or the thickness of the first glass ply used to form the first curved glass ply) is in a range from about 2.0 mm to about 6 mm, from about 2.1 mm to about 6 mm, from about 2.2 mm to about 6 mm, from about 2.3 mm to about 6 mm, from about 2.4 mm to about 6 mm, from about 2.5 mm to about 6 mm, from about 2.6 mm to about 6 mm, from about 2.8 mm to about 6 mm, from about 3 mm to about 6 mm, from about 3.2 mm to about 6 mm, from about 3.4 mm to about 6 mm, from about 3.6 mm to about 6 mm, from about 3.8 mm to about 6 mm, from about 4 mm to about 6 mm, from about 2.0 mm to about 5.8 mm, from about 2.0 mm to about 5.6 mm, from about 2.0 mm to about 5.5 mm, from about 2.0 mm to about 5.4 mm, from about 2.0 mm to about 5.2 mm, from about 2.0 mm to about 5 mm, from about 2.0 mm to about 4.8 mm, from about 2.0 mm to about 4.6 mm, from about 2.0 mm to about 4.4 mm, from about 2.0 mm to about 4.2 mm, from about 2.0 mm to about 4 mm, from about 2.0 mm to about 3.8 mm, from about 2.0 mm to about 3.6 mm, from about 2.0 mm to about 3.4 mm, from about 2.0 mm to about 3.2 mm, or from about 2.0 mm to about 3 mm. In other embodiments the first ply can be thicker than 10.0 mm or thinner than 2.0 mm, such as less than 1.5 mm, 1.0 mm, 700 μm, 500 μm, 300 μm, 200 μm, 100 μm, 80 μm, 40 μm, and/or at least 10 μm.

In one or more specific examples, the first thickness (or the thickness of the first glass ply used to form the first curved glass ply) is from about 2.0 mm to about 3.5 mm, and the second thickness (or the thickness of the second glass ply used to form the second curved glass ply) is in a range from about 0.1 mm to less than about 2.0 mm. In embodiments, the ratio of first thickness to total glass thickness is at least 0.7, or at least 0.75, or at least 0.8, or at least 0.85, or at least 0.9.

In one or more embodiments, the laminate 300, 400 is substantially free of visual distortion as measured by ASTM C1652/C1652M. In specific embodiments, the laminate, the first curved glass ply and/or the second curved glass ply are substantially free of wrinkles or distortions that can be visually detected by the naked eye, according to ASTM C1652/C1652M.

In one or more embodiments, the first major surface 202 or the second major surface 204 comprises a surface compressive stress of less than 3 MPa as measured by a surface stress meter, such as the surface stress meter commercially available under the tradename FSM-6000, from Orihara Industrial Co., Ltd. (Japan) (“FSM”). In some embodiments, the first curved glass ply is unstrengthened as will be described herein (but may optionally be annealed), and exhibits a surface compressive stress of less than about 3 MPa, or about 2.5 MPa or less, 2 MPa or less, 1.5 MPa or less, 1 MPa or less, or about 0.5 MPa or less. In some embodiments, such surface compressive stress ranges are present on both the first major surface and the second major surface.

In one or more embodiments, the first and second glass plies used to form the first curved glass ply and second curved ply are substantially planar prior to being pair shaped to form a first curved glass ply and second curved glass ply. In some instances, one or both of the first glass ply and the second glass ply used to form the first curved glass ply and second curved ply may have a 3D or 2.5D shape that does not exhibit the curvature depth desired and will eventually be formed during the pair shaping process and present in the resulting laminate. Additionally or alternatively, the thickness of the one or both of the first curved glass ply (or the first glass ply used to form the first curved glass ply) and the second curved glass ply (or the second glass ply used to form the second curved glass ply) may be constant along one or more dimension or may vary along one or more of its dimensions for aesthetic and/or functional reasons. For example, the edges of one or both of the first curved glass ply (or the first glass ply used to form the first curved glass ply) and the second curved glass ply (or the second glass ply used to form the second curved glass ply) may be thicker as compared to more central regions of the glass ply.

The length (e.g., longest centerline of surface (e.g., first major surface)), width (e.g., longest dimension of the surface orthogonal to the length), and thickness (e.g., dimension of the ply orthogonal to the length and the width) dimensions of the first curved glass ply (or the first glass ply used to form the first curved glass ply) and the second curved glass ply (or the second glass ply used to form the second curved glass ply) may also vary according to the article application or use. In one or more embodiments, the first curved glass ply (or the first glass ply used to form the first curved glass ply) includes a first length and a first width (the first thickness is orthogonal both the first length and the first width), and the second curved glass ply (or the second glass ply used to form the second curved glass ply) includes a second length and a second width orthogonal the second length (the second thickness is orthogonal both the second length and the second width). In one or more embodiments, either one of or both the first length and the first width is about 0.25 meters (m) or greater. For example, the first length and/or the second length may be in a range from about 1 m to about 3 m, from about 1.2 m to about 3 m, from about 1.4 m to about 3 m, from about 1.5 m to about 3 m, from about 1.6 m to about 3 m, from about 1.8 m to about 3 m, from about 2 m to about 3 m, from about 1 m to about 2.8 m, from about 1 m to about 2.8 m, from about 1 m to about 2.8 m, from about 1 m to about 2.8 m, from about 1 m to about 2.6 m, from about 1 m to about 2.5 m, from about 1 m to about 2.4 m, from about 1 m to about 2.2 m, from about 1 m to about 2 m, from about 1 m to about 1.8 m, from about 1 m to about 1.6 m, from about 1 m to about 1.5 m, from about 1.2 m to about 1.8 m or from about 1.4 m to about 1.6 m. In some embodiments, a surface dimension from perimeter to perimeter through a centroid of the respective surface (e.g., first surface, second surface, monolith major surface, ply surface) is at least 1 mm, at least 1 cm, at least 10 cm, at least 1 m, and/or no more than 10 m, whereby a contained fracture may not result in failure of the respective ply. In other embodiments, the ply may be otherwise sized.

For example, the first width and/or the second width may be in a range from about 0.5 m to about 2 m, from about 0.6 m to about 2 m, from about 0.8 m to about 2 m, from about 1 m to about 2 m, from about 1.2 m to about 2 m, from about 1.4 m to about 2 m, from about 1.5 m to about 2 m, from about 0.5 m to about 1.8 m, from about 0.5 m to about 1.6 m, from about 0.5 m to about 1.5 m, from about 0.5 m to about 1.4 m, from about 0.5 m to about 1.2 m, from about 0.5 m to about 1 m, from about 0.5 m to about 0.8 m, from about 0.75 m to about 1.5 m, from about 0.75 m to about 1.25 m, or from about 0.8 m to about 1.2 m. In other embodiments, the ply may be otherwise sized.

In one or more embodiments, the second length is within 5% of the first length (e.g., about 5% or less, about 4% or less, about 3% or less, or about 2% or less). For example if the first length is 1.5 m, the second length may be in a range from about 1.425 m to about 1.575 m and still be within 5% of the first length. In one or more embodiments, the second width is within 5% of the first width (e.g., about 5% or less, about 4% or less, about 3% or less, or about 2% or less). For example if the first width is 1 m, the second width may be in a range from about 1.05 m to about 0.95 m and still be within 5% of the first width.

Having described the glass ply, laminate structure thereof, and uses therefor, the borosilicate glass composition is now described in more detail. In embodiments, the borosilicate glass composition comprises at least 74 mol % SiO₂, at least 10 mol % B₂O₃, and at least some Al₂O₃. In particular embodiments, the borosilicate glass composition includes at least 0.03 mol % of an iron oxide (e.g., Fe₂O₃ or FeO). In more particular embodiments, SiO₂, Al₂O₃, and B₂O₃ make up at least 90 mol % of the borosilicate glass composition. Further, the borosilicate glass composition has a liquidus viscosity of at least 500 kiloPoise (kP) and a temperature (T_{200P}) at which the viscosity is 200 Poise (P) of 1725° C. or less.

In embodiments, the borosilicate glass composition includes SiO₂ in an amount in the range of at least about 72 mol %, more particularly about 72 mol % to about 80 mol %, in particular 74 mol % to 80 mol %. For example, the borosilicate glass composition includes SiO₂ in an amount in the range from about 72 mol % to about 85 mol %, from about 73 mol % to about 85 mol %, from about 74 mol % to about 85 mol %, from about 75 mol % to about 85 mol %, from about 76 mol % to about 85 mol %, from about 77 mol % to about 85 mol %, from about 78 mol % to about 85 mol %, from about 79 mol % to about 85 mol %, from about 80 mol % to about 85 mol %, from about 81 mol % to about 85 mol %, from about 82 mol % to about 85 mol %, from about 83 mol % to about 85 mol %, from about 84 mol % to about 85 mol %, from about 74 mol % to about 84 mol %, from about 74 mol % to about 84 mol %, from about 74 mol % to about 83 mol %, from about 74 mol % to about 82 mol %, from about 74 mol % to about 81 mol %, from about 74 mol % to about 80 mol %, from about 74 mol % to about 79 mol %, from about 74 mol % to about 78 mol %, from about 74 mol % to about 77 mol %, from about 74 mol % to about 76 mol %, and all ranges and sub-ranges therebetween. In other embodiments, the glass may have less than 74 mol % SiO₂.

In embodiments, the borosilicate glass composition comprises B₂O₃ in an amount in the range from about 10 mol % to about 16 mol %, in particular about 11.5 mol % to about 14.5 mol %. In various embodiments, the borosilicate glass composition comprises B₂O₃ in an amount in the range from about 10 mol % to about 16 mol %, from about 11 mol % to about 16 mol %, from about 12 mol % to about 16 mol %, from about 13 mol % to about 16 mol %, from about 14 mol % to about 16 mol %, from about 15 mol % to about 16 mol %, from about 11 mol % to about 15 mol %, from about 11 mol % to about 14 mol %, from about 11 mol % to about 13 mol %, from about 11 mol % to about 12 mol %, from about 12 mol % to about 13 mol %, from about 12 mol % to about 14 mol %, from about 14 mol % to about 15 mol %, or any range or sub-ranges therebetween. In other embodiments, the glass may have less than 10 mol % B₂O₃ or more than 16 mol % B₂O₃.

In embodiments, the borosilicate glass composition includes Al₂O₃ in an amount in the range from about 2 mol % to about 6 mol %, in particular about 2.5 mol % to about 5 mol %. In various embodiments, the borosilicate glass composition includes Al₂O₃ in an amount in the range from about 2 mol % to about 6 mol %, from about 3 mol % to about 6 mol %, from about 4 mol % to about 6 mol %, from about 5 mol % to about 6 mol %, from about 3 mol % to about 5 mol %, from about 3 mol % to about 4 mol %, from about 4 mol % to about 5 mol %, or any range or sub-ranges therebetween. Advantageously, the Al₂O₃ present in these amounts helps prevent phase separation of the borosilicate glass composition. In other embodiments, the glass may have less than 2 mol % Al₂O₃ or more than 6 mol % Al₂O₃.

In embodiments, the borosilicate glass composition comprises Na₂O in an amount in the range from about 3 mol % to about 8 mol %, in particular from about 4.5 mol % to about 8 mol %. In various embodiments, the borosilicate glass composition comprises Na₂O in an amount in the range from about 3 mol % to about 8 mol %, from about 4 mol % to about 8 mol %, from about 5 mol % to about 8 mol %, from about 6 mol % to about 8 mol %, from about 7 mol % to about 8 mol %, from about 3 mol % to about 7 mol %, from about 4 mol % to about 7 mol %, from about 5 mol % to about 7 mol %, from about 6 mol % to about 7 mol %, from about 4 mol % to about 6 mol %, from about 5 mol % to about 6 mol %, or any ranges and sub-ranges therebetween. In other embodiments, the glass may have less than 3 mol % Na₂O or more than 8 mol % Na₂O.

In embodiments, the borosilicate glass composition comprises K₂O in an amount in the range from about 0.5 mol % to about 5 mol %, in particular from about 0.5 mol % to about 3 mol %. In various embodiments, the borosilicate glass composition comprises K₂O in an amount in the range from about 0.5 mol % to about 5 mol %, from about 0.6 mol % to about 5 mol %, from about 0.7 mol % to about 5 mol %, from about 0.8 mol % to about 5 mol %, from about 0.9 mol % to about 5 mol %, from about 1 mol % to about 5 mol %, from about 2 mol % to about 5 mol %, from about 3 mol % to about 5 mol %, from about 4 mol % to about 5 mol %, from about 2 mol % to about 4 mol %, in the range of 3 mol % to 4 mol %, or any ranges and sub-ranges therebetween. In other embodiments, the glass may have less than 0.8 mol % K₂O or more than 5 mol % K₂O.

The presence of Na₂O and K₂O has an effect on the liquidus viscosity. Thus, in embodiments, at least one of Na₂O or K₂O is present in an amount of at least 4 mol %. In embodiments, the combined amount of Na₂O and K₂O is present in an amount of at least 5.5 mol % when other alkaline earth oxides (e.g., CaO or MgO) are present in an amount of at least 1.5 mol %. In other embodiments, the combined amount of Na₂O and K₂O is present in an amount of at least 8 mol % without regard to alkaline earth oxides. In certain instances, it is believed that K₂O and Na₂O tend to decrease the liquidus temperature, thereby increasing the liquid viscosity. Further, in combination with B₂O₃ and Al₂O₃, K₂O and Na₂O tend to increase the liquidus viscosity.

In embodiments, the ratio of K₂O to Na₂O is from about 0.1 to about 0.75. In embodiments, the ratio of K₂O to Na₂O is about 0.15 to about 0.75, about 0.20 to about 0.75, about 0.25 to about 0.75, about 0.30 to about 0.75, about 0.35 to about 0.75, about 0.40 to abut 0.75, about 0.45 to about 0.75, about 0.50 to about 0.75, about 0.55 to about 0.75, about 0.60 to about 0.75, about 0.65 to about 0.75, about 0.70 to about 0.75, about 0.1 to about 0.70, abut 0.1 to about 0.65, about 0.1 to about 0.60, about 0.1 to about 0.55, about 0.1 to about 0.50, about 0.1 to about 0.45, about 0.1 to about 0.40, about 0.1 to about 0.35, about 0.1 to about 0.30, about 0.1 to about 0.25, about 0.1 to about 0.20, or about 0.1 to about 0.15.

In embodiments, the borosilicate glass composition comprises P₂O₅ in an amount in the range from 0 mol % to about 4 mol %, from about 1 mol % to about 4 mol %, from about 2 mol % to about 4 mol %, from about 3 mol % to about 4 mol %, from about 1 mol % to about 3 mol %, from about 2 mol % to about 3 mol %, from about 1 mol % to about 2 mol %, or any ranges and sub-ranges therebetween. P₂O₅ tends to lower the density of the borosilicate glass composition, which may result in increased densification during deformation as discussed below. Further, it is contemplated that P₂O₅ may increase the liquidus viscosity.

In embodiments, the borosilicate glass composition comprises CaO in an amount in the range from 0 mol % to about 5 mol %, from 0 mol % to about 4 mol %, from 0 mol % to about 3 mol %, from 0 mol % to about 2 mol %, from 0 mol % to about 1 mol %, from about 1 mol % to about 5 mol %, from about 2 mol % to about 5 mol %, from about 3 mol % to about 5 mol %, from about 4 mol % to about 5 mol %, from about 2 mol % to about 4 mol %, from about 2 mol % to about 3 mol %, from about 3 mol % to about 4 mol %, and all ranges and sub-ranges therebetween.

In embodiments, the borosilicate glass composition comprises MgO in an amount in the range from 0 mol % to about 5 mol %, in particular 0.5 mol % to 2.5 mol %. In various embodiments, the borosilicate glass composition comprises MgO in an amount in the range from 0 mol % to about 5 mol %, from 0 mol % to about 4 mol %, from 0 mol % to about 3 mol %, from 0 mol % to about 2 mol %, from 0 mol % to about 1 mol %, from about 1 mol % to about 5 mol %, from about 2 mol % to about 5 mol %, from about 3 mol % to about 5 mol %, from about 4 mol % to about 5 mol %, from about 2 mol % to about 4 mol %, from about 2 mol % to about 3 mol %, from about 3 mol % to about 4 mol %, and all ranges and sub-ranges therebetween.

In embodiments, the total amount of CaO and MgO is at most 5 mol %. In embodiments, the total amount of CaO and MgO is at least 1.5 mol % where the combined amount of K₂O and Na₂O are less than 7 mol %. Alkaline earth oxides, such as CaO and MgO, tend to reduce liquidus temperature and increase liquidus viscosity.

In embodiments, the borosilicate glass composition comprises SnO₂ in an amount up to about 0.25 mol %. In embodiments, the borosilicate glass composition comprises SnO₂ in an amount in the range from 0 mol % to about 0.25 mol %, from about 0.05 mol % to about 0.25 mol %, from about 0.10 mol % to about 0.25 mol %, from about 0.15 mol % to about 0.25 mol %, from about 0.20 mol % to about 0.25 mol %, from about 0.05 mol % to about 0.20 mol %, from about 0.05 mol % to about 0.15 mol %, from about 0.05 mol % to about 0.10 mol %, from about 0.10 mol % to about 0.15 mol %, from about 0.10 mol % to about 0.20 mol %, from about 0.15 mol % to about 0.20 mol %, or all ranges and sub-ranges therebetween. In some embodiments, SnO₂ may be substituted with another fining agent, such as a multivalent or other oxygen absorbing agent including antimony, arsenic, iron, cerium, and the like.

In embodiments, the borosilicate glass composition includes one or more iron compounds, e.g., in the form of iron (III) oxide (Fe₂O₃) or iron (II) oxide (FeO; provided, e.g., from an iron oxalate (C₂FeO₄) source), in particular in order to absorb infrared radiation from sunlight. In embodiments, the borosilicate glass composition comprises the iron compound in an amount up to about 0.50 mol %, in particular in a range from about 0.20 to about 0.40 mol %. In embodiments, the borosilicate glass composition comprises the iron compound in an amount in the range from about 0.03 mol % to about 0.50 mol %, from about 0.10 mol % to about 0.50 mol %, from about 0.15 mol % to about 0.50 mol %, from about 0.20 mol % to about 0.50 mol %, from about 0.25 mol % to about 0.50 mol %, from about 0.30 mol % to about 0.50 mol %, from about 0.35 mol % to about 0.50 mol %, from about 0.40 mol % to about 0.50 mol %, from about 0.45 mol % to about 0.50 mol %, or any ranges or sub-ranges therebetween. In other embodiments, other modifiers, such as TiO₂ can be used in addition to or in place of the iron compound to reduce transmission of UV radiation. In embodiments, TiO₂ can be provided in an amount of about 0.04 mol % to about 0.12 mol %.

In embodiments, the glass composition (or the glass article formed therefrom) exhibits a liquidus viscosity of at least 500 kiloPoise (kP) and up to 50.000 kP. Advantageously, glass compositions having a liquidus viscosity greater than 1000 kP are less susceptible to baggy warp during fusion draw. As used herein, the term “liquidus viscosity” refers to the viscosity of a molten glass at the liquidus temperature, wherein the term “liquidus temperature” refers to the temperature at which crystals first appear as a molten glass cools down from the melting temperature (or the temperature at which the very last crystals melt away as temperature is increased from room temperature).

The borosilicate glass compositions described herein having a liquidus viscosity of at least 500 kP are fusion formable at thicknesses of at least 2 mm, at least 3 mm, at least 3.3 mm, or at least 3.8 mm. In some embodiments, the fusion formed glass ply is substantially free of draw lines that are present in typical float formed glass articles. The liquidus viscosity is determined by the following method. First the liquidus temperature of the glass is measured in accordance with ASTM C829-81 (2015), titled “Standard Practice for Measurement of Liquidus Temperature of Glass by the Gradient Furnace Method.” Next the viscosity of the glass at the liquidus temperature is measured in accordance with ASTM C965-96 (2012), titled “Standard Practice for Measuring Viscosity of Glass Above the Softening Point.”

In embodiments, the borosilicate glass composition exhibits a strain point temperature in a range from about 480° C. to about 560° C., about 490° C. to about 560° C., about 500° C. to about 560° C., about 510° C. to about 560° C., about 520° C. to about 560° C., about 530° C. to about 560° C., about 540° C. to about 560° C., about 550° C. to about 560° C., about 480° C. to about 550° C., about 480° C. to about 540° C., about 480° C. to about 530° C., about 480° C. to about 520° C., about 480° C. to about 510° C., about 480° C. to about 500° C., or any ranges or sub-ranges therebetween. In embodiments, the strain point temperature is determined using the beam bending viscosity method of ASTM C598-93(2013). In embodiments, the strain point is defined as the temperature at which viscosity is 10^{14.68} poise.

In embodiments, the borosilicate glass composition exhibits an annealing point temperature in a range from about 520° C. to about 590° C., about 530° C. to about 590° C., about 540° C. to about 590° C., about 550° C. to about 590° C., about 560° C. to about 590° C., about 570° C. to about 590° C., about 580° C. to about 590° C., about 520° C. to about 580° C., about 520° C. to about 570° C., about 520° C. to about 560° C., about 520° C. to about 550° C., about 520° C. to about 540° C., about 520° C. to about 530° C., or any ranges or sub-ranges therebetween. The annealing point is determined using the beam bending viscosity method of ASTM C598-93(2013). In embodiments, the annealing point is defined as the temperature at which viscosity is 10^{13,18} poise.

In embodiments, the glass composition exhibits a temperature at a viscosity of about 200 P (T_{200P}) that is at most 1725° C., as measured by Fulcher fit to high temperature viscosity (HTV) data (i.e., all the temperature measurements from 100 kP to 100 Poise). For example, the glass composition may exhibit a T_{200P} in a range from about 1500° C. to about 1725° C., about 1525° C. to about 1725° C., about 1550° C. to about 1725° C., about 1575° C. to about 1725° C., about 1600° C. to about 1725° C., about 1625° C. to about 1725° C., about 1650° C. to about 1725° C., about 1675° C. to about 1725° C., about 1700° C. to about 1725° C., about 1500° C. to about 1700° C., about 1500° C. to about 1675° C., about 1500° C. to about 1650° C., about 1500° C. to about 1625° C., about 1500° C. to about 1600° C., about 1500° C. to about 1575° C., about 1500° C. to about 1550° C., about 1500° C. to about 1525° C., or any ranges or sub-ranges therebetween.

In one or more embodiments, the glass composition or the glass article formed therefrom exhibit a density at 20° C. that is less than 2.4 g/cm³. In embodiments, the density at 20° C. is 2.39 g/cm³ or less, 2.38 g/cm³ or less, 2.37 g/cm³ or less, 2.36 g/cm³ or less, 2.35 g/cm³ or less, 2.34 g/cm³ or less, 2.33 g/cm³ or less, 2.32 g/cm³ or less, 2.31 g/cm³ or less, 2.30 g/cm³ or less, 2.29 g/cm³ or less, 2.28 g/cm³ or less, 2.27 g/cm³ or less, 2.26 g/cm³ or less, 2.25 g/cm³ or less, 2.24 g/cm³ or less, 2.23 g/cm³ or less, 2.22 g/cm³ or less, 2.21 g/cm³ or less, or 2.20 g/cm³ or less. In embodiments, the density is determined using the buoyancy method of ASTM C693-93(2013). Advantageously, a density below 2.4 g/cm³ is less than the density of soda-lime glass, which is conventionally used in automotive glazing laminates.

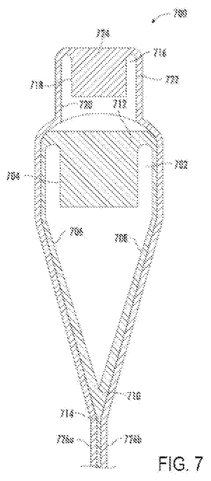

As mentioned, borosilicate glass composition according to the present disclosure is able to be fusion formed. The resulting glass ply can be described as being fusion-formed. FIG. 7 depicts an exemplary embodiment of an apparatus 700 for fusion forming a glass ply from a borosilicate glass composition. The fusion-forming apparatus 700 includes an isopipe 702 defined by a trough 704, a first forming surface 706, and a second forming surface 708. The first forming surface 706 and the second forming surface 708 angle inwardly beneath the trough 704 and meet at a root 710 of the isopipe 702. The presently disclosed borosilicate glass composition 712 is provided to the trough 704 in a molten state, and the borosilicate glass composition 712 overflows the trough 704, forming two streams and running down the forming surfaces 706, 708. The streams of molten glass meet at the root 710 to form the glass ply 714, which cools and is cut from the flowing stream.

In embodiments, the fusion-forming apparatus 700 includes a second isopipe 716 having a second trough 718, a third forming surface 720, and a fourth forming surface 722. A glass composition 724, having the same or different composition as the borosilicate glass composition 712, is provided to the second trough 718 in a molten state and overflows the second trough 718. The molten glass composition 724 flows down the third and fourth forming surfaces 720, 722 where it is directed outwardly around the borosilicate glass composition 712. In this way, the glass composition 724 flows down the first and second forming surfaces 706, 708 outside of the streams of the borosilicate glass composition 712. At the root 710 of the isopipe 702, the combination of the streams of the borosilicate glass composition 712 and the streams of the glass composition 724 create a glass ply 714 having cladding layers 726a, 726b. Such cladding layers may mechanically strengthen the glass based on residual stresses developed based on different coefficients of thermal expansions between the compositions 712, 724, or the cladding layers may be chemically strengthenable, such as through ion-exchange treatment. The cladding layers 726a, 726b may also provide other features, such as specific optical properties to the glass ply 714 formed in this manner.

The fusion forming method offers the advantage that, because the two glass steams flowing over the channel fuse together, neither of the outside surfaces of the resulting glass article comes in contact with any part of the apparatus. Thus, the surface properties of the fusion drawn glass article are not affected by such contact. In embodiments, the fusion-formed borosilicate glass composition of the present disclosure exhibits optical distortions of no greater than 75 millidiopters as measured by an optical distortion detector using transmission optics according to ASTM 1561. Conventional borosilicate glass compositions, which have a liquidus viscosity less than 500 kP and a T_{200P} temperature of greater than 1725° C., were not able to be fusion formed at thicknesses of 2 mm or greater using a fusion draw process, and instead, such conventional borosilicate glass compositions of that thickness were typically formed using a float process.

### EXAMPLES

Various embodiments of the fusion formable borosilicate glass composition are provided in the tables below.

TABLE 1
COMPOSITIONS AND PROPERTIES OF EXAMPLES 1-6

| | 1 | 2 | 3 | 4 | 5 | 6 |
|---|---|---|---|---|---|---|
| SiO₂ | 75.35 | 76.72 | 76.14 | 75.18 | 77.19 | 76.36 |
| Al₂O₃ | 3.54 | 3.54 | 3.54 | 4.07 | 4.04 | 4.07 |
| B₂O₃ | 12.21 | 10.75 | 11.31 | 12.01 | 9.84 | 10.86 |
| Na₂O | 4.60 | 4.67 | 4.68 | 4.61 | 4.70 | 4.57 |
| K₂O | 2.13 | 2.18 | 2.18 | 2.93 | 3.05 | 2.94 |
| MgO | 0.99 | 0.99 | 0.99 | 0.02 | 0.02 | 0.02 |
| CaO | 1.03 | 1.02 | 1.02 | 1.05 | 1.03 | 1.03 |
| SnO₂ | 0.14 | 0.13 | 0.13 | 0.13 | 0.13 | 0.14 |
| Density | 2.307 | 2.308 | 2.308 | 2.316 | 2.335 | 2.324 |
| (g/cm³) | | | | | | |
| Strain | 512.6 | 518.6 | 516.7 | 515.2 | 528.0 | 520.7 |
| Point (° C.) | | | | | | |
| LTCTE | 5.1 | 5.24 | 5.1 | 5.58 | 5.55 | 5.56 |
| (ppm/° C.) | | | | | | |
| HTCTE | 25.44 | 25.26 | 24.79 | 24.52 | 24.6 | 24.58 |
| (ppm/° C.) | | | | | | |
| Young's | 66.6 | 67.7 | 67.1 | 66.7 | 69.2 | 67.7 |
| Modulus | | | | | | |
| (GPa) | | | | | | |
| Poisson's | 0.198 | 0.194 | 0.196 | 0.200 | 0.194 | 0.197 |
| Ratio | | | | | | |
| Fulchers A | −1.531 | −1.342 | −1.536 | −1.163 | −1.159 | −1.152 |
| Fulchers B | 5661.3 | 5468.2 | 5817.5 | 4739.4 | 4858.6 | 4848.7 |
| Fulchers T₀ | 140.9 | 182.3 | 142.8 | 227.7 | 232.4 | 224.8 |
| 200P Temp | 1618 | 1683 | 1659 | 1596 | 1637 | 1629 |
| (° C.) | | | | | | |
| 35 kP Temp | 1073 | 1111 | 1100 | 1058 | 1084 | 1076 |
| (° C.) | | | | | | |
| 200 kP Temp | 970 | 1005 | 994 | 961 | 985 | 976 |
| (° C.) | | | | | | |
| Liquidus | 947 | 672 | 1578 | 3779 | 2892 | 4013 |
| Viscosity | | | | | | |
| (kP) | | | | | | |
| Phase | Cristobalite | Cristobalite | Cristobalite | Cristobalite | Cristobalite | Cristobalite |

Examples 1-6 are exemplary glass compositions according to one or more embodiments of this disclosure. As can be seen from Table 1, the liquidus viscosity of these glass compositions is well above the 500 kP necessary for fusion forming the glass composition. Further, T_{200P} for these glasses is well below 1725° C. Also, advantageously, these glasses have a density below 2.4 g/cm³. Conventional laminates utilize a thick outer glass ply of soda-lime glass, which has a density above 2.4 g/cm³. Thus, not only are the mechanical properties enhanced as will be discussed below, but the disclosed fusion formable borosilicate glass composition offers weight savings (and thus enhanced fuel efficiency) based on its density of less than 2.4 g/cm³, in particular 2.35 g/cm³ or less. The thermal properties of a resulting glass ply are also enhanced by the low temperature coefficient of thermal expansion (LTCTE), which is obtained by measuring expansion of the glass between the temperatures of 0° C. and 300° C. In embodiments, the LTCTE is 5.6 ppm/° C. or less, in particular, 5.3 ppm/° C. or less, and particularly 5.1 ppm/C or less. Besides the properties just discussed, Table 1 also includes information related to strain point temperature, annealing point temperature, high temperature CTE (HTCTE), Young's modulus, and Poisson's ratio.

Table 2, below provides additional exemplary compositions according to the present disclosure.

TABLE 2
COMPOSITIONS AND PROPERTIES OF EXAMPLES
7-9 AND COMPARATIVE EXAMPLES 10 AND 11

| | 7 | 8 | 9 | CE10 | CE11 |
|---|---|---|---|---|---|
| SiO₂ | 76.75 | 75.93 | 76.38 | 76.10 | 76.25 |
| Al₂O₃ | 3.57 | 3.53 | 3.56 | 3.53 | 3.52 |
| B₂O₃ | 11.18 | 11.61 | 12.26 | 8.47 | 11.49 |
| Na₂O | 6.35 | 4.59 | 4.87 | 6.50 | 8.73 |
| K₂O | 2.04 | 2.13 | 1.01 | 2.15 | 0.00 |
| MgO | 0.00 | 0.03 | 1.81 | 0.06 | 0.00 |
| CaO | 0.01 | 2.05 | 0 | 3.08 | 0.01 |
| SnO₂ | 0.11 | 0.11 | 0.11 | 0.11 | 0.00 |
| Density | 2.328 | 2.32 | 2.273 | 2.385 | 2.332 |
| (g/cm³) | | | | | |
| Strain Point | 518.6 | 525.8 | 506.2 | 543 | 526.6 |
| (° C.) | | | | | |
| Anneal Point | 564 | 571.4 | 552.9 | 585.4 | 569.7 |
| (° C.) | | | | | |
| LTCTE | 5.6 | 5.15 | 4.58 | 6.09 | — |
| (ppm/° C.) | | | | | |
| Young's | 68.7 | 68.3 | 63.1 | 74.1 | — |
| Modulus | | | | | |
| (GPa) | | | | | |
| Poisson's | 0.192 | 0.192 | 0.196 | 0.194 | — |
| Ratio | | | | | |
| Fulchers A | −1.121 | −0.974 | −1.682 | −1.272 | −1.023 |
| Fulchers B | 4505.1 | 4545.6 | 6535.2 | 4696.1 | 4178.6 |
| Fulchers T₀ | 255.8 | 251.8 | 69 | 240.1 | 279.4 |
| 200 P Temp | 1572 | 1640 | 1710 | 1555 | 1536 |
| (° C.) | | | | | |
| 35 kP Temp | 1051 | 1076 | 1119 | 1048 | 1030 |
| (° C.) | | | | | |
| 200 kP | 957 | 976 | 1005 | 955 | 940 |
| Temp (° C.) | | | | | |
| Liquidus | 582 | 855 | 1365 | 308 | 180 |
| Viscosity | | | | | |
| (kP) | | | | | |
| Phase | Cristobalite | Cristobalite | Cristobalite | Cristobalite | Cristobalite |

Again, from Table 2, it can be seen that Examples 7-9 of the disclosed fusion formable borosilicate glass compositions exhibit the properties necessary for fusion forming at thicknesses greater than 2 mm. Further, the properties of the borosilicate glass composition are advantaged over the same properties of soda-lime glass, such as density and LTCTE. However, as can be seen from Comparative Examples 10 and 11, compositions outside of those disclosed herein with respect to fusion formability do not have the properties necessary for fusion forming at relatively large thicknesses. Comparative Example 10 has a low B₂O₃ content of 8.47 mol % such that the total amount of SiO₂, B₂O₃, and Al₂O₃ is below 90 mol %, and Comparative Example 11 contains none of K₂O or MgO and almost none of CaO, which tend to increase the liquidus viscosity as discussed above. However, as discussed later, some embodiments may be useful as windshields or other articles, such as due to fracture behavior, regardless of whether the respective composition is fusion formable.

Table 3, below, provides further exemplary compositions for the borosilicate glass composition according to the present disclosure.

TABLE 3
COMPOSITIONS OF EXAMPLES 12-14 AND 18 AND COMPARATIVE EXAMPLES 15-17

| | 12 | 13 | 14 | CE15 | CE16 | CE17 | 18 |
|---|---|---|---|---|---|---|---|
| SiO₂ | 76.34 | 76.06 | 76.15 | 76.19 | 76.23 | 76.09 | 74.89 |
| Al₂O₃ | 3.56 | 3.54 | 3.54 | 3.55 | 3.55 | 3.54 | 3.50 |
| B₂O₃ | 11.80 | 12.43 | 12.89 | 13.35 | 13.73 | 14.28 | 13.60 |
| Na₂O | 4.29 | 4.15 | 3.85 | 3.55 | 3.33 | 3.12 | 5.22 |
| K₂O | 1.96 | 1.95 | 1.80 | 1.65 | 1.58 | 1.51 | 0.92 |
| MgO | 0.95 | 0.86 | 0.82 | 0.77 | 0.71 | 0.66 | 1.76 |
| CaO | 0.99 | 0.90 | 0.86 | 0.82 | 0.76 | 0.70 | — |
| SnO₂ | 0.10 | 0.10 | 0.10 | 0.10 | 0.10 | 0.10 | 0.11 |
| Density | 2.298 | 2.285 | 2.271 | 2.259 | 2.246 | 2.234 | 2.273 |
| (g/cm³) | | | | | | | |
| Strain | 512.7 | 511.1 | 506.6 | 499.8 | 499 | 492 | 504 |
| Point | | | | | | | |
| (° C.) | | | | | | | |
| Anncal | 558.7 | 558.2 | 554.9 | 549.7 | 549.2 | 543.5 | 546 |
| Point | | | | | | | |
| (° C.) | | | | | | | |
| LTCTE | 4.8 | 4.6 | 4.5 | 4.4 | 4.3 | 4.1 | 4.6 |
| (ppm/° C.) | | | | | | | |
| Young's | 65.9 | 64.6 | 63.0 | 61.4 | 60.2 | 58.8 | — |
| Modulus | | | | | | | |
| (GPa) | | | | | | | |
| Poisson's | 0.196 | 0.2 | 0.2 | 0.201 | 0.202 | 0.203 | — |
| Ratio | | | | | | | |
| Fulchers A | −1.504 | −1.647 | −1.835 | −1.719 | −2.093 | −1.727 | −1.697 |
| Fulchers B | 5948 | 6341.6 | 7018.7 | 6898.6 | 7963.1 | 7172.3 | 6442.7 |
| Fulchers T₀ | 111.3 | 89.1 | 21.2 | 33 | −55.1 | 13.3 | 73.7 |
| T_{200P} | 1676 | 1695 | 1718 | 1749 | 1757 | 1794 | 1685 |
| (° C.) | | | | | | | |
| T_{35 kP} | 1097 | 1113 | 1121 | 1134 | 1145 | 1157 | 1106 |
| (° C.) | | | | | | | |
| T_{200 kP} | 987 | 1002 | 1005 | 1016 | 1022 | 1034 | 994 |
| (° C.) | | | | | | | |
| Liquidus | 1021 | 1197 | 1752 | | | | 4569 |
| Viscosity | | | | | | | |
| (kP) | | | | | | | |
| Phase | Cristobalite | Cristobalite | Cristobalite | | | | Cristobalite |

The borosilicate glass compositions Examples 12-14 and 18 in Table 3 possess the requisite liquid viscosity and T_{200P} temperature for fusion forming and also the advantaged properties of density and LTCTE for using the disclosed borosilicate glass composition as an outer ply in automotive glazing laminates. Moreover, as can be seen, these examples demonstrate that the increasing amount of B₂O₃ has the effect of decreasing density. Each of Examples 12-17 has a density of less than 2.3 g/cm³, and certain examples, have a density of 2.250 g/cm³ or less. Comparative Examples 15-17 exhibit a T_{200P} temperature that is above 1725° C. In comparison to Examples 12-14 and 18, Comparative Examples 15-17 have too little alkali oxides and too little alkali and alkali earth oxides (also called alkaline earth metal oxides), such as for some of the fusion formability attributes disclosed herein, but may have sufficient alkali and alkaline earth metal oxides for other embodiments, such as windshields and other articles with loop cracks that contain lateral and radial cracks from a Vickers indenter, as discussed below. In particular, each of Examples 12-14 and 15 include at least 5.5 mol % of Na₂O+K₂O and a total of at least 7.0 mol % of Na₂O+K₂O+MgO+CaO. From the examples in Tables 1-3, it is believed that embodiments of the present disclosure will exhibit the requisite T_{200P} and liquidus viscosity for fusion forming where a total amount of Na₂O+K₂O+MgO+CaO is at least 7.0 mol %, especially where there is at least 5.5 mol % of Na₂O+K₂O and at least 1.5 mol % of MgO+CaO. It is further believed that embodiments of the present disclosure will exhibit the requisite T_{200P} and liquidus viscosity for fusion forming where Na₂O+K₂O is at least 8 mol % without regard to the amount of MgO and CaO.

Table 4 provides additional exemplary compositions of the disclosed borosilicate glass composition with the further addition of an iron compound (e.g., as iron (II) oxide or iron (III) oxide) to absorb sunlight, in particular infrared (IR) radiation, which causes the temperature of the vehicle interior to rise. Thus, by providing IR absorption, an automotive glazing comprising a laminate with an outer ply of the disclosed borosilicate glass composition is able to provide additional fuel efficiency and comfort by reducing the heat that builds up in the vehicle and the burden on the air cooling system. Table 4 provides example borosilicate glass compositions of Table 4 having amounts of iron (Fe₂O₃) increasing from 0 mol % to 0.44 mol % and one composition (Example 25) containing primarily iron (II) oxide (FeO) as the primary iron compound. In Example 25, the iron (II) oxide is provided by using iron oxalate (C₂FeO₄) as a batch material source. The carbon of the iron oxalate leaves as carbon dioxide (CO₂), leaving primarily iron (II) oxide and some iron (III) oxide in the glass.

TABLE 4
COMPOSITIONS AND OPTICAL PROPERTIES OF EXAMPLES 19-25

| | 3 | 19 | 20 | 21 | 22 | 23 | 24 | 25 |
|---|---|---|---|---|---|---|---|---|
| SiO₂ | 76.14 | 76.00 | 76.16 | 76.06 | 76.04 | 76.22 | 75.93 | 75.68 |
| Al₂O₃ | 3.54 | 3.53 | 3.54 | 3.53 | 3.54 | 3.55 | 3.52 | 3.51 |
| B₂O₃ | 11.31 | 11.58 | 11.41 | 11.26 | 11.34 | 11.25 | 11.29 | 12.55 |
| Na₂O | 4.68 | 4.58 | 4.52 | 4.65 | 4.57 | 4.45 | 4.57 | 4.2 |
| K₂O | 2.18 | 2.11 | 2.12 | 2.18 | 2.11 | 2.07 | 2.14 | 2.05 |
| MgO | 0.99 | 0.98 | 0.97 | 0.97 | 0.98 | 0.98 | 0.98 | 0.85 |
| CaO | 1.02 | 1.01 | 1.03 | 1.03 | 1.03 | 1.02 | 1.03 | 0.9 |
| Fe₂O₃/FeO | — | 0.07 | 0.15 | 0.22 | 0.28 | 0.37 | 0.44 | 0.16 |
| SnO₂ | 0.13 | 0.11 | 0.11 | 0.11 | 0.11 | 0.10 | 0.10 | 0.1 |
| Refractive | 1.4855 | 1.4855 | 1.4855 | 1.4855 | 1.4855 | 1.4855 | — | 1.484 |
| Index at 633 | | | | | | | | |
| nm | | | | | | | | |

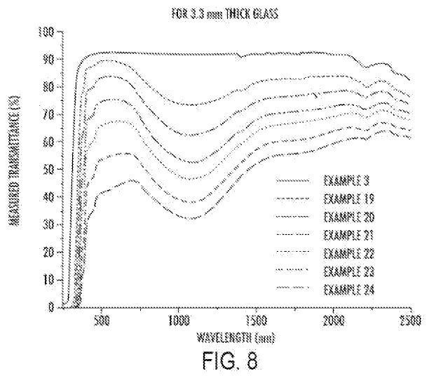

Tables 5 and 6, below, provide transmission data for the borosilicate glass compositions of Table 4 for glass plies having a thickness of 3.3 mm and 2.1 mm, respectively. In embodiments, for a given composition of borosilicate glass composition, the addition of an iron compound serves to lower the visible light (i.e., about 400 nm to about 750 nm), total solar transmission, and UV transmission. All transmission values were measured at normal incidence. Example 3 has a visible light transmission (T_{VIS}) of 92.4% and a total solar transmission (TTS) of 92.0% as measured according to ISO 13837A (A/2°). By adding increments of Fe₂O. T_{VIS} and TTS are reduced incrementally. As shown in Table 4, the addition of 0.07 mol % (or 0.19 wt %) Fe₂O₃ drops T_{VIS} by about 3% and TTS by about 6%. The addition of 0.37 mol % (or 0.92 wt %) of Fe₂O₃ drops T_{VIS} by about 44% and TTS by about 33%. According to ISO 13837, the minimum requirement for T_{VIS} is 73% for glazing of road vehicles. FIG. 8 provides a graph of transmittance for Examples 3, 19-24. As can be seen, the addition of Fe₂O₃ lowers overall measured transmittance and creates a significant dip in measured transmittance between about 750 nm and 1500 nm, corresponding to the near infrared spectrum. In embodiments, an automotive glazing comprising a laminate 300, 400 including at least one glass ply of the presently disclosed fusion formable borosilicate glass composition has a TTS of 61% or less and/or a T_{VIS} of at least 73% as measured according to ISO 13837A (A/2°). In such embodiments, the inventors believe from prior experience preparing such glazings and laminates that the interlayer and other glass ply will have minimal effect on T_{VIS} (e.g., up to about 0.5% diminishment) and would further reduce TTS by, e.g., 3-5%. This is especially so where the presently disclosed fusion formable borosilicate glass ply is used as a thicker out ply of the laminate glazing.

TABLE 5
TRANSMISSION PROPERTIES BASED ON
IRON CONTENT FOR 3.3. MM GLASS

| Glass | | Fe | UV cutoff | T_{UV} | | |
|---|---|---|---|---|---|---|
| Compo- | Fe | level | wavelength | (300-380 nm) | T_{VIS} | TTS |
| sition | Source | (wt %) | (nm) | (%) | (%) | (%) |
| 3 | Oxide | 0 | <300 | 85.7 | 92.4 | 92.0 |
| 19 | Oxide | 0.19 | 320 | 59.2 | 89.3 | 85.7 |
| 20 | Oxide | 0.37 | 335 | 39.1 | 83.6 | 80.1 |
| 21 | Oxide | 0.55 | 345 | 26.7 | 75.7 | 74.2 |
| 22 | Oxide | 0.70 | 350 | 17.6 | 67.6 | 69.4 |
| 23 | Oxide | 0.92 | 365 | 6.1 | 48.8 | 59.2 |
| 24 | Oxide | 1.1 | — | — | 44.2 | 56.3 |
| 25 | Oxalate | 0.40 | 330 | 42.2 | 79.6 | 73.8 |

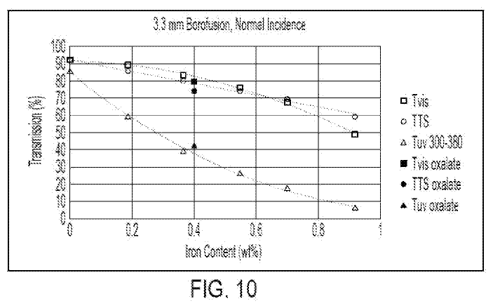

As can also be seen in Table 5, increasing the iron content increases the UV cutoff wavelength (i.e., the wavelength where UV transmission goes below 10%) and decreases total UV transmission in the range of 300-380 nm in addition to decreasing T_{VIS} and TTS. In Example 3, the glass composition contains no iron content. The UV cutoff wavelength is below 300 nm, and the UV transmission is 85.7%. As the iron content increases from 0 wt % (or 0 mol %) to 0.92 wt % (or 0.37 mol %), the UV cutoff wavelength increases to 365 nm and the T_{UV} decreases to 6.1%. In addition to the T_{VIS} and TTS requirements referenced above, embodiments of a laminate 300, 400 including at least one glass ply the presently disclosed fusion formable borosilicate glass composition have a T_{UV} that is less than 75%. Advantageously, decreasing UV transmission in a laminate can help to reduce yellowing of the polymer interlayer. FIG. 10 depicts plots of the T_{VIS}, T_{UV}, and TTS for Examples 3, 19-23, and 25 as a function of iron content for a single glass ply based on the data contained in Table 5.

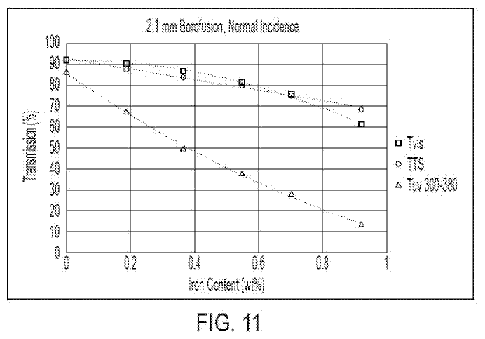

Table 6 provides transmission data for glass plies of the same compositions contained in Table 5 (with the exception of Example 24, which was not included). However, the thickness of the glass plies was decreased from 3.3 mm to 2.1 mm. As can be seen in Table 6, the decrease in ply thickness causes a slight decrease in the UV cutoff wavelength, and the T_{UV}, T_{VIS}, and TTS are each increased from the thicker 3.3 mm plies of Table 5. However, Table 6 still demonstrates that the T_{UV}, T_{VIS}, and TTS still decrease progressively with increasing iron content. FIG. 11 depicts plots of the T_{VIS}, T_{UV}, and TTS as a function of iron content for a single glass ply based on the data contained in Table 6. From Tables 5 and 6, it can also be seen that the iron (II) oxide from the iron oxalate provided to the batch provides a similar or better level of UV and solar radiance absorption than the iron (III) oxide when considered on a weight percentage basis.

TABLE 6
TRANSMISSION PROPERTIES BASED ON
IRON CONTENT FOR 2.1 MM GLASS

| Glass | | Fe | UV cutoff | T_{UV} | | |
|---|---|---|---|---|---|---|
| Compo- | Fe | level | wavelength | (300-380 nm) | T_{VIS} | TTS |
| sition | source | (wt %) | (nm) | (%) | (%) | (%) |
| 3 | Oxide | 0 | <300 | 86.7 | 92.4 | 92.2 |
| 19 | Oxide | 0.19 | 315 | 67.5 | 90.5 | 88.0 |
| 20 | Oxide | 0.37 | 330 | 49.7 | 86.7 | 84.2 |
| 21 | Oxide | 0.55 | 335 | 37.8 | 81.5 | 80.0 |
| 22 | Oxide | 0.70 | 340 | 28.1 | 75.8 | 76.4 |
| 23 | Oxide | 0.92 | 355 | 13.5 | 61.5 | 68.4 |
| 25 | Oxalate | 0.40 | 320 | 53.5 | 84.1 | 79.6 |

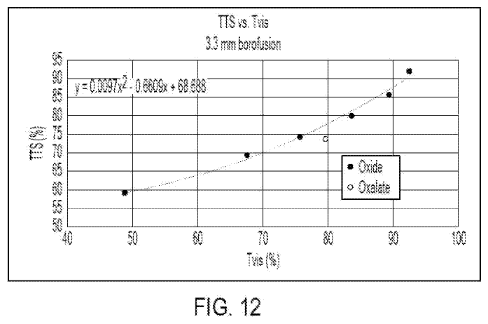

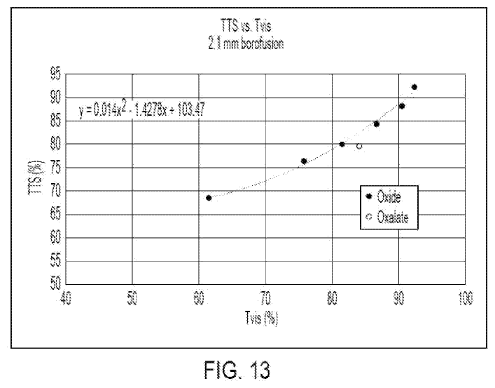

FIGS. 12 and 13 depict graphs plotting TTS against T_{VIS} for the glass compositions contained in Tables 5 and 6. As can be seen in FIGS. 12 and 13, the iron content increases as the plot points go from the upper right to the lower left, defining a quadratic relationship. In FIG. 12, the relationship between T_{VIS} and TTS is given by the equation TTS=0.0097(T_{VIS})²−0.6609(T_{VIS})÷68.688. In FIG. 13, the relationship between T_{VIS} and TTS is given by the equation TTS=0.014(T_{VIS})²−1.4278(T_{VIS})+103.47. It is believed that using iron oxalate as a source material for the iron compound of the borosilicate glass may shift the curves to the right, increasing the T_{VIS} for the same level of TTS.

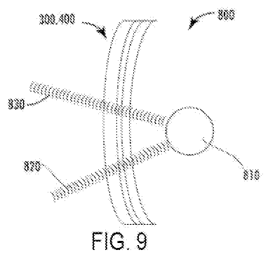

In embodiments, the laminates 300, 400 described herein may be used in a system 800 that also includes a sensor 810 as shown in FIG. 9. In particular, the previous discussion demonstrates that the laminates 300, 400 transmit electromagnetic radiation in the visible spectrum, and as shown in FIG. 8, the laminates also substantially transmit electromagnetic radiation at wavelengths greater than 1500 nm (e.g., short-wave infrared). Signals carried on electromagnetic radiation in these ranges can be transmitted through the laminates 300, 400. FIG. 9 depicts the sensor 810 receiving incoming signals 820 and sending outgoing signals 830 through the laminates 300, 400. For example, in one or more embodiments, the laminate 300, 400 is included as glazing 130 in a vehicle 100 as depicted in FIG. 1. In such an embodiment, the sensor 810 is arranged on the interior of the vehicle 100. In this way, signals 820, 830 are able to be sent from and received by the vehicle 100. In one or more embodiments, the signals 820, 830 have a peak wavelength in the visible light (about 400 nm to about 750 nm) or short-wave infrared spectrums (1500 nm or greater). In embodiments, such signals facilitate autonomous or semi-autonomous driving of the vehicle, open road tolling, telecommunication, traffic monitoring and control, and vehicle-to-vehicle communication, amongst other possibilities. An example of a sensor 810 that can be utilized in the system 800 is LIDAR utilizing one or both of visible light or short-wave infrared radiation. In embodiments of the laminate 300, 400 that include an IRR coating, the IRR coating may be ablated from the ply on which it is applied in the region where the sensor 810 is configured to receive and send signals through the laminate 300, 400.

As mentioned above, the presently disclosed borosilicate glass composition has surprisingly improved deformation properties as compared to conventional soda-lime glass compositions and even to conventional borosilicate glass compositions. In particular, the inventors found that glass plies formed from borosilicate glass compositions disclosed herein surprisingly and unexpectedly densify upon deformation, which can limit the spread of radial cracks produced by, e.g., rocks and other flying debris from the roadway.

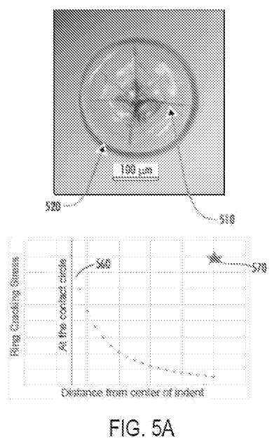

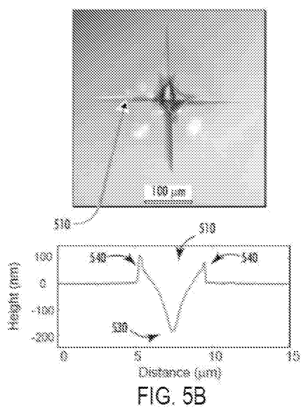

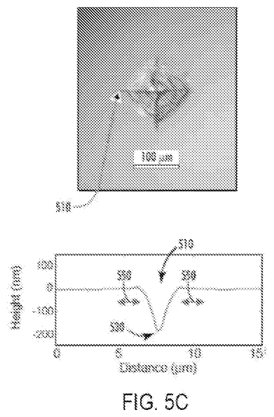

FIGS. 5A-5C depict crack formation produced by quasi static indents made using a 2 kilogram force (kgf) with a Vickers indentation tip for glass plies made from the presently disclosed borosilicate glass composition (FIG. 5A), a conventional soda lime silicate glass composition (FIG. 5B), and a conventional borosilicate glass composition (FIG. 5C). It is believed that the quasi-static indentation test using a Victers tip provides a good indication of windshield performance when an outer surface of the windshield is struck by flying debris, such as a rock.

In the test, a more conventional borosilicate glass composition with respect to formability included 83.60 mol % SiO₂, 1.20 mol % Al₂O₃, 11.60 mol % B₂O₃, 3.00 mol % Na₂O, and 0.70 mol % K₂O. This conventional borosilicate glass composition had a density of 2.23 g/cm³, a strain point of 518° C., an anneal point of 560° C., an LTCTE of 3.25 μm/° C., a Young's modulus of 64 GPa, and a Poisson's ratio of 0.2. Thus, as compared to embodiments of the presently disclosed borosilicate glass composition, the conventional borosilicate glass composition includes less Al₂O₃, less total alkali content, especially K₂O, and less total alkaline earth content. Such conventional borosilicate glass compositions may be ployed in contexts where low coefficient of thermal expansion (e.g., 3.3 ppm/° C. or less) is desired. Alkali and Alkaline earth oxides tend to increase the coefficient of thermal expansion. Here, the slight increase in coefficient of thermal expansion to about 5-6 ppm/° C. is balanced against the ability to fusion form the presently disclosed borosilicate glass composition by increasing the liquidus viscosity and decreasing the T_{200P} temperature. Further, as will be discussed below, the disclosed borosilicate glass composition had surprising and unexpected effects on the facture properties of glass plies made from the borosilicate glass composition.

As can be seen in FIGS. 5A-5C, each glass composition exhibits radial cracks 510 extending outwardly from the point where the Vickers indentation tip was pressed into the respective plies. However, as shown in FIG. 5A, the glass ply of the presently disclosed borosilicate glass composition exhibits a ring crack 520 formation that bounds the radial cracks 510 and preventing their further growth. In particular, the radial cracks 510 will not continue to extend radially because the radial cracks 510 are likely (e.g., more likely than not, statistically more likely, at least 51% likely, such as at least 60% likely, at least 80% likely out of sample size of 100) to be stopped and not traverse (e.g., are interrupted by) the ring crack 520. Advantageously, by limiting the spread of the radial cracks 510, the effect on the overall strength of the glass ply (which would be to decrease the strength) is reduced.

The graphs in FIGS. 5B and 5C demonstrate the topography of a line section of the cracks shown in the micrographs of FIGS. 5B and 5C. As can be seen in FIG. 5B, the radial crack 510 has a valley 530 at the center of the graph where the depth below the surface is the deepest. For the soda lime silicate glass of FIG. 5B, the structure of the glass provides relatively reduced free volume, and the broken glass networks shear under sharp contact, which causes the surface to pile-up to peaks 540. Hence, as shown in the micrograph of FIG. 5B, the surface around the radial cracks 510 is mounded.

For the conventional borosilicate glass composition of FIG. 5C, there is relatively higher free volume than the soda lime silicate glass and highly connected networks in the glass structure, which preferentially densifies under sharp contacts. The radial crack 510 still includes a central valley 530 at the center of the graph, but there are no substantial peaks at the edges of the radial crack 510 as the densification of the structure (as denoted by arrows 550) conserves volume, resulting in high ring stress that produces the cluster of ring cracks shown in the micrograph of FIG. 5C.

Returning to FIG. 5A, a contrast can be seen between the conventional borosilicate glass composition of FIG. 5C and the presently disclosed borosilicate glass composition. In the graph of FIG. 5A, the ring cracking stress is shown as a function of distance from the contact circle of the indenter. For the conventional borosilicate glass composition (denoted by curve 560), the ring stress decreases as the distance from the contact circle increases, which places the maximum ring cracking stress at the periphery of the contact circle. However, for the presently disclosed borosilicate glass composition, stress field analysis of the cracks of FIGS. 5A and 5C demonstrates that the maximum ring cracking stress (denoted by star 570) is surprising and unexpectedly spaced a distance away from the periphery of the contact circle. By forming a ring at a distance removed from the crack boundary, strength limiting median and radial cracks 510 are contained within the ring crack 520 for the presently disclosed borosilicate glass composition.

While the Vickers indentation test considers a quasi-static load (i.e., where the load is applied slowly such that the inertial effects of loading are negligible), it was also found using a Vickers dart drop test that the fusion-formed borosilicate glass composition performed as well as conventional float-formed borosilicate glass and better than soda-lime silicate glass when exposed to a dynamic load. In the Vickers dart drop test, a dart having a Vickers indentation tip (136°) and a weight of 8.6 g was dropped from increasing heights (50 mm increments) until a visible crack (i.e., crack having a length of at least 10 mm) was formed in the glass ply. The soda-lime silicate glass had an average height of visible crack formation of less than 600 mm. The presently disclosed borosilicate glass had an average height before visible crack formation of over 600 mm, in particular over 650 mm, which is about the same as would be expected from conventional borosilicate glass compositions. It is believed that the dart-drop test provides an indication of the contact rate and force needed for radial crack formation to exceed the ability of the glass to densify for the formation of ring cracks in the presently disclosed borosilicate glass composition.

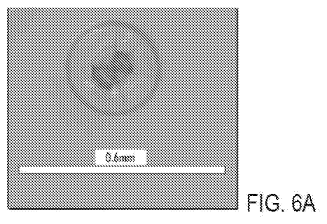

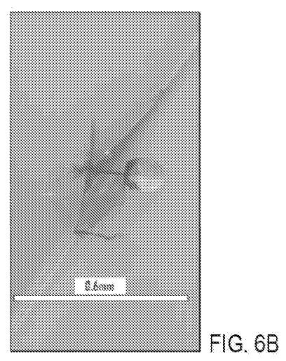

As was also mentioned above, glass plies formed from the presently disclosed borosilicate glass composition are more resistant to thermal shock than soda lime silicate glasses. The effect of a thermal shock load is shown in FIGS. 6A and 6B. In particular, specimens of the presently disclosed fusion formed glass composition (FIG. 6A) and soda lime glass (FIG. 6B) were indented with a Vickers indenter at 2 kgf as discussed above in relation to FIGS. 5A and 5B. The specimens were then heated up to 150° C., and a droplet of water (at 25° C.±5° C.) was dropped onto the indent site while the specimens were still hot.

As can be seen in FIG. 6B, the soda-lime silicate glass cracks readily propagate during this thermal shock event. By comparison, the cracks in the fusion formed borosilicate glass composition remain confined within the ring crack boundary as shown in FIG. 6A. One reason for the resistance to thermal shock is the ring crack boundary that prevents radial crack extension. Another reason for the resistance to thermal shock is that the LTCTE for the fusion formed borosilicate glass composition is considerably lower than soda-lime silicate (5.6 ppm/° C. or less for the fusion formable borosilicate glass composition vs. 8.0 ppm/° C. for the soda-lime silicate).

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is in no way intended that any particular order be inferred. In addition, as used herein, the article “a” is intended to include one or more than one component or element, and is not intended to be construed as meaning only one.

It will be apparent to those skilled in the art that various modifications and variations can be made without departing from the spirit or scope of the disclosed embodiments. Since modifications, combinations, sub-combinations and variations of the disclosed embodiments incorporating the spirit and substance of the embodiments may occur to persons skilled in the art, the disclosed embodiments should be construed to include everything within the scope of the appended claims and their equivalents.

According to an exemplary embodiment and in furtherance the above disclosed information, a vehicle windshield or other article may include a first ply (e.g., outer ply, glass sheet; see, e.g., ply first glass 310 of FIG. 3) comprising a first major surface (e.g., outside surface, front-facing surface) and a second major surface opposite to the first major surface, a second ply (e.g., outer ply, glass sheet; see, e.g., second glass ply 320) comprising a third major surface and a fourth major surface opposite to the third major surface, and an interlayer (see, e.g., interlayer 330) coupling the second major surface of the first ply to the third major surface of the second ply. In contemplated embodiments, any of the first, second, third, and/or fourth surfaces may be coated, such as with a functional layer, such as ultra-violet light reflective layer, hydrophobic layer, adhesive promoting layer, etc., as disclosed above.

In some embodiments, the second ply is a tempered soda lime glass. In other embodiments, the second ply is an ion-exchanged aluminoborosilicate glass. In still other embodiments, the second ply is a glass-ceramic. In some embodiments, the interlayer includes a polymer, such as polyvinyl butyral.

Referring to Tables 1-3, the low-temperature coefficient of thermal expansion of compositions disclosed herein may range from more than 4.4 ppm/° C. to less than 6.09 ppm/° C., such as from 4.5 ppm/° C. to 6 ppm/° C., to 5.8 ppm/° C., and/or 5.6 ppm/° C. As indicated, LTCTE is obtained by measuring expansion of the glass between the temperatures of 0° C. and 300° C., such as by thermomechanical analysis described in ASTM Test Method E831 (Ref 4). In other contemplated embodiments, glasses with unique fracture behavior disclosed herein may not have viscosity for fusion forming, the glasses may have lower, or higher LTCTEs. In some embodiments, LTCTE of compositions disclosed herein is less than 8.7 ppm/° C., which may be associated with soda lime glass, and/or greater than 3.25 ppm/° C., which may be associated with lower-CTE borosilicates. Accordingly, glasses disclosed herein may be less thermal shock resistant than some lower-CTE borosilicates, which may be counter-intuitive. However, Applicants have found a higher CTE (e.g., greater than 3.25 ppm/° C.) will result in higher surface compression after thermal reforming. Disadvantages associated with lower thermal shock resistance may be offset by the unique fracture mechanics of glasses disclosed herein, further discussed below. A result is that glasses disclosed herein are more thermal resistant than soda lime by having a lower LTCTE than 8.7 ppm/° C., and may also have improved for blunt impact performance over other borosilicates.

In some embodiments, the first ply has a thickness of at least 200 μm and no more than 1 cm, and/or thicknesses disclosed above, such as 0.1 mm to about 6 mm. In other contemplated embodiments, a first ply, single-ply, monolithic sheet, substrate, or other article of borosilicate glass as disclosed herein may have such thicknesses as disclosed above or other thicknesses, such as less than 200 μm and/or at least 20 μm, or at least 1 cm and/or less than 1 m, where thickness may be constant or generally constant over the article (e.g., glass sheet, ply), such as within 100 μm of an average thickness of the respective article, such as within 10 μm of an average thickness, or the thickness may vary over the article, such as with a glass container having a thicker lip or base.

According to an exemplary embodiment, the interlayer cushions the first ply with respect to the second ply, thereby mitigating communicating of cracks therebetween. In contemplated embodiments, the interlayer has a modulus of rigidity that is less than that of glass of the first and/or second ply, such as less than 0.7 thereof, such as less than 0.5 thereof.

According to an exemplary embodiment, the interlayer adheres to the first ply, thereby controlling loss of fragments from fracture of the first ply. In some embodiments, the interlayer is directly contacting the first ply. As discussed above, in some embodiments the interlayer adheres to the first ply, the second ply, and/or both, and couples the first and second plies. According to an exemplary embodiment, the second ply reinforces the first ply, stiffening the first ply to bending forces applied thereto. However, in other contemplated embodiments, the first ply may be independent of a second ply or interlayer, and may instead be a monolith, for example.

According to an exemplary embodiment, the first ply has curvature such that the second major surface is concavely curved, and the second ply has curvature such that the third major surface is convexly curved and fits together with the second major surface, as disclosed above such that the first major surface of first ply is configured as an outward-facing surface of glazing, such as laminate glazing, such as a windshield and configured to be outboard when installed on a vehicle.

According to an exemplary embodiment, the first ply includes a borosilicate glass composition, such as those disclosed herein. In terms of constituent oxides, the borosilicate glass composition of the first glass ply includes (i) SiO₂, B₂O₃, and/or Al₂O₃; and (ii) one or more alkali metal oxides (also called alkaline oxides; e.g., Li₂O, Na₂O, K₂O, Rb₂O, Cs₂O) and/or one or more divalent cation oxides (zinc oxide and/or alkaline earth metal oxides, also called alkaline earth oxides, such as MgO, CaO, SrO, BaO).

According to some embodiments, such as those exhibiting self-terminating crack loop behavior as disclosed herein, concentrations in mole percent on an oxide basis of SiO₂, B₂O₃, the one or more alkali metal oxides, and, when included in the composition, Al₂O₃ and the one or more divalent cation oxides, satisfy some (e.g., one or a combination of more than one) or all the relationships: (relationship 1) SiO₂≥72 mol %, such as SiO₂≥72.0, such as SiO₂≥73.0, such as SiO₂≥74.0, and/or SiO₂≤92, such as SiO₂≤90; (relationship 2) B₂O₃≥10 mol %, such as B₂O₃≥10.0, such as B₂O₃≥10.5, and/or B₂O₃≥20, such as B₂O₃≤18, (relationship 3) (R₂O+R′O)≥Al₂O₃, such as (R₂O+R′O)≥(Al2O₃+1), such as (R₂O+R′O)≥(Al₂O₃+2), and/or (relationship 4) 0.80≤(1−[(2R₂O+2R′O)/(SiO₂+2Al₂O₃+2B₂O₃)])≤0.93, where RO is the sum of the concentrations of the one or more alkali metal oxides and, when included in the borosilicate glass composition, R′O is the sum of the concentrations of the one or more divalent cation oxides. R₂O may be the sum of Li₂O, Na₂O, K₂O, Rb₂O, Cs₂O for example, and R′O may be the sum of MgO, CaO, SrO, BaO, ZnO for example.

Inventive glasses disclosed herein may include additional constituents. In some embodiments, the borosilicate glass composition may further include P₂O₅. Notably, if P₂O₅ is added to the glass, it should be treated as non-rotatable network former (u or v) when considering the relationship (4) such as R₂O or R′O, where the relationships (3) and (4) may be modified as (R₂O+R′O+P₂O₅)≥Al₂O₃, and 0.80≤(1−[(2R₂O+2R′O+2P₂O₅)/(SiO₂+2Al₂O₃+2B₂O₃)])≤0.93. Other minor chemical components, such as fining agent SnO₂, Sb₂O₃, NaCl, are generally negligible with respect to rotatability and fracture behavior. Other minor chemical components, such as color agent such as with which concentration smaller than 0.5 mol %, are negligible.

Applicants believe relationships (3) and (4) may relate to fracture behavior of borosilicate glass compositions disclosed herein and characterize aspects of “rotatability” of the respective compositions. For compositions of the form xSiO₂·yAl₂O₃·zB₂O₃·uR₂O·vRO, where x, y, z, u, v can represent mol % or molar fraction of each type of oxide. If (u+v)≥y, Applicants believe the fracture behavior is related to a rotatability parameter of (1−[(2R₂O+2R′O)/(SiO₂+2Al₂O₃+2B₂O₃)]). In instances when the value of the rotatability parameter is between 0.80 and 0.93, Applicant have found that Vickers indenter tests produce radial and lateral cracks that are contained within a small (<1 mm in diameter) crack loop. A result is that sheets of glasses within this range may not crack to failure during Vickers indenter tests, but instead only form small round cracks that contain other cracks and prevent them from spreading.

Similarly, Applicants believe density may relate to fracture behavior of the borosilicate glass compositions disclosed herein. According to an exemplary embodiment, density of the glass is greater than 2.230 g/cm and/or is less than 2.397 g/cm³, and this cracking behavior has been observed in this range.

Vickers indenter tests may be used to characterize fracture behavior of glass, as discussed in Gross et al., Crack-resistant glass with high shear band density, Journal of Non-Crystalline Solids, 494 (2018) 13-20; and Gross, Deformation and cracking behavior of glasses indented with diamond tips of various sharpness, Journal of Non-Crystalline Solids, 358 (2012) 3435-3452, both of which are incorporated by reference herein. In some embodiments, when glass having the borosilicate glass composition of the first glass ply is formed as at least ten polished, flat samples (e.g., 100 samples) of 1 mm thickness with a major surface of at least 2.2 cm² area (e.g., 2 cm by 2 cm square), and tested using square-based, 136° four-sided, pyramidal Vickers indenter directed orthogonally into a center of the major surface at 25° C. in 50% relative humidity and the indenter is quasi-statically displaced at rate of 60 μm per second up to maximum 3 kg-force with indentation load held for 10 seconds (unless failure by fracture of the sample occurs first), more often than not (at least 51 times out of 100; at least 6 times out of 10) all cracks extending through the sample radially and/or laterally from beneath the indenter tip (i.e. the location where the indenter tip contacted the glass) are interrupted by a self-terminating crack loop (e.g., ring crack), whereby fracture of the samples from the Vickers indenter is limited to cracking within the loop. Essentially the indenter crushes and cracks the glass beneath the indenter. However, the crack loop forms and stops spread of cracking originating from the indenter contact beyond the crack loop. By contrast, lateral or radial cracks may otherwise form prior to and/or pass through such crack loops in other glasses (e.g., anomalous cracking) or crack loops may not form (e.g., normal cracking), and in either case the lateral or radial cracks would not be contained by the crack loop, and may propagate through the full glass article causing overall fracture through the article and failure thereof.

The following Table 100 summarizes the value of rotatability parameter of (1−[(2R₂O+2R′O)/(SiO₂+2Al₂O₃+2B₂O₃)]), density, and Vickers indention fracture behavior for various borosilicate glass compositions tested.

TABLE 100
(broken into three parts to fit the page)

| | | CE-101 | CE-102 | DSG | DSX | DQQ | DQR | DQS | DQT |
|---|---|---|---|---|---|---|---|---|---|
| SiO₂ | mol % | 77.18 | 78.97 | 76.42 | 76.38 | 75.35 | 76.72 | 76.14 | 75.18 |
| Al₂O₃ | mol % | 1.98 | 2.04 | 2.04 | 3.56 | 3.54 | 3.54 | 3.54 | 4.07 |
| B₂O₃ | mol % | 4.66 | 8.67 | 14.71 | 12.26 | 12.21 | 10.75 | 11.31 | 12.01 |
| Na₂O | mol % | 16.14 | 10.28 | 6.8 | 4.87 | 4.6 | 4.67 | 4.68 | 4.61 |
| K₂O | mol % | | | | 1.01 | 2.13 | 2.18 | 2.18 | 2.93 |
| MgO | mol % | | | | 1.81 | 0.99 | 0.99 | 0.99 | 0.02 |
| CaO | mol % | | | | 0 | 1.03 | 1.02 | 1.02 | 1.05 |
| SnO₂ | mol % | | | | 0.11 | 0.14 | 0.13 | 0.13 | 0.13 |
| density | g/cm³ | 2.428 | 2.397 | 2.275 | 2.273 | 2.307 | 2.308 | 2.308 | 2.316 |

| | | | | | | | | |
|---|---|---|---|---|---|---|---|---|
| Rotatability value | 0.64 | 0.8 | 0.88 | 0.86 | 0.84 | 0.83 | 0.83 | 0.84 |
| Fracture behavior | normal | normal | contained | contained | contained | contained | contained | contained |

| | | DQU | DQV | DSP | DSQ | DSR | DSS | DST | DSU |
|---|---|---|---|---|---|---|---|---|---|
| SiO₂ | mol % | 77.19 | 76.36 | 76.34 | 76.06 | 76.15 | 76.19 | 76.23 | 76.09 |
| Al₂O₃ | mol % | 4.04 | 4.07 | 3.56 | 3.54 | 3.54 | 3.55 | 3.55 | 3.54 |
| B₂O₃ | mol % | 9.84 | 10.86 | 11.8 | 12.43 | 12.89 | 13.35 | 13.73 | 14.28 |
| Na₂O | mol % | 4.7 | 4.57 | 4.29 | 4.15 | 3.85 | 3.55 | 3.33 | 3.12 |
| K₂O | mol % | 3.05 | 2.94 | 1.96 | 1.95 | 1.8 | 1.65 | 1.58 | 1.51 |
| MgO | mol % | 0.02 | 0.02 | 0.95 | 0.86 | 0.82 | 0.77 | 0.71 | 0.66 |
| CaO | mol % | 1.03 | 1.03 | 0.99 | 0.9 | 0.86 | 0.82 | 0.76 | 0.7 |
| SnO₂ | mol % | 0.13 | 0.14 | 0.1 | 0.1 | 0.1 | 0.1 | 0.1 | 0.1 |
| density | g/cm³ | 2.335 | 2.324 | 2.298 | 2.285 | 2.271 | 2.259 | 2.246 | 2.234 |
| Rotatability value | | 0.83 | 0.84 | 0.85 | 0.85 | 0.87 | 0.88 | 0.88 | 0.89 |
| Fracture behavior | | contained | contained | contained | contained | contained | contained | contained | contained |
| | | DSV | DSW | DSX | DSY | DSZ | DUE | CE-103 | CE-104 |
| SiO₂ | mol % | 75.91 | 76.14 | 76.35 | 76.04 | 76.03 | 74.89 | 75.54 | 83.6 |
| Al₂O₃ | mol % | 3.53 | 3.54 | 3.56 | 3.54 | 3.54 | 3.5 | 2.01 | 1.2 |
| B₂O₃ | mol % | 12.63 | 12.31 | 12.26 | 12.4 | 12.37 | 13.6 | 19.76 | 11.6 |
| Na₂O | mol % | 4.98 | 6.09 | 4.87 | 4.97 | 6.13 | 5.22 | 2.66 | 3 |
| K₂O | mol % | 1.05 | 0 | 1.01 | 1.05 | 0 | 0.92 | | 0.7 |
| MgO | mol % | 0.86 | 0.87 | 1.81 | 0.03 | 1.78 | 1.76 | | |
| CaO | mol % | 0.9 | 0.91 | 0.02 | 1.83 | 0.02 | | | |
| SnO₂ | mol % | 0.11 | 0.11 | 0.11 | 0.11 | 0.1 | 0.11 | | |
| density | g/cm³ | 2.286 | 2.284 | 2.273 | 2.295 | 2.273 | 2.273 | 2.147 | 2.23 |

| | | | | | | | | |
|---|---|---|---|---|---|---|---|---|
| Rotatability value | 0.86 | 0.85 | 0.86 | 0.85 | 0.85 | 0.86 | 0.96 | 0.93 |
| Fracture behavior | contained | contained | contained | contained | contained | contained | anomalous | anomalous |

In Table 100, for some compositions the fracture behavior is identified as “contained” as opposed to “anomalous” or “normal” facture behavior. Radial and lateral cracks that were contained in a crack loop (e.g., circular ring crack) did not extend beyond the crack loop, even hours after indention testing (e.g., 12 hours, 24 hours, 72 hours after). As such samples with the contained cracks only cracked locally, within the crack loop, and did not fail beyond the crack loop. As summarized in Table 100, Applicant observed polished, flat samples of 1 mm to 3.3 mm thickness tested using square-based, 136° four-sided, pyramidal Vickers indenter quasi-statically displaced at rate of 60 μm per second until fracture or up to maximum 3 kg-force with indentation load held for 10 seconds. Furthermore, as evidence that the radial and lateral cracks were contained, when rapidly cooled by placement of corresponding samples into cold water, cracks did not propagate beyond the crack loop and the observed samples did not fail outside the crack loop. Radial and lateral cracks that were contained in a crack loop, with the samples rapidly cooled, did not extend beyond the crack loop, even hours after indention testing (e.g., 2 hours, 12 hours, 24 hours, 72 hours after).

For the composition labelled DUE in Table 100, crack loops were observed to be shaped as circular rings or ring cracks (see generally FIGS. 5A & 6A). When loaded to 2 kg-force, the radii of the rings ranged from 101 to 136 micrometers. When loaded to 3 kg-force, the radii of the rings ranged from 119 to 229 micrometers.

Also, for the composition labelled DUE in Table 100, 19 different indent tests were performed for samples with a thickness of 1 mm, and the result was 19 of the 19 tests had circular ring cracks that contained the radial and lateral cracks from the indenter. Applicants expect similar results with more testing, such as at least 90 out of 100 samples, such as at least 95, such as at least 98.

Applicants observed that for some samples, cracks may be delayed but show up within approximately 2 hours of indentation testing. But, radial and lateral cracks of the DUE samples were contained in a crack loop and did not extend beyond the crack loop, even hours after indention testing (e.g., 2 hours, 12 hours, 24 hours, 72 hours after).

For the composition labelled DQS in Table 100, ten different indent tests were performed for samples with a thickness of 1 mm, and the results were 10 out of 10 samples produced crack loops in the form of circular ring cracks that contained the radial and lateral cracks from the indenter. The radial and lateral cracks did not extend beyond the crack loop, even hours after indention testing (e.g., 2 hours, 12 hours, 24 hours, 72 hours after). Applicants expect similar results with more testing, such as at least 90 out of 100 samples, such as at least 95, such as at least 98.

The same DQS composition was tested in samples with a thickness of 3.3 mm, and 16 of 20 different tests resulted in circular ring cracks that contained the radial and lateral cracks from the indenter. Applicants expect similar results with more testing, such as at least 50 out of 100 samples, such as at least 60, such as at least 75. Without being bound to any theory, Applicants believe that the decreased percentage of occurrence with 3.3 mm samples may have been due to inhomogeneity of the samples, rather than thickness.

For samples of DSX composition in Table 100, 21 different indent tests were performed for samples with a thickness of 1 mm, and the results were 19 with circular ring cracks that contained the radial and lateral cracks from the indenter. Applicants expect similar results with more testing, such as at least 70 out of 100 samples, such as at least 80, such as at least 90. Those radial and lateral cracks did not extend beyond the crack loop, even hours after indention testing (e.g., 2 hours, 12 hours, 24 hours, 72 hours after).

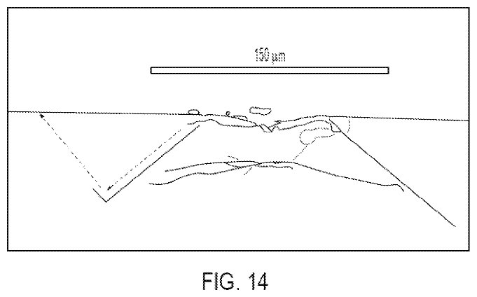

As shown in FIG. 14, Applicants were able to observe a cross-section of a sample of borosilicate glass, as disclosed herein, and view cracking of the sample via fractography. The image shows cracking of a normal cone beneath the indent location that appears to then change direction and head back to the same surface, presumably to form the crack loop. Further, the crack cone keeps extending through the sample to the opposing surface. Applicants believe this to be newly discovered fracture behavior for the presently disclosed glasses and structures.

In contemplated embodiments, a glass article (e.g. sheet, ply, film, cover, tube, container) of borosilicate glass, as disclosed herein, includes one or more crack loops, as disclosed above, such as having a generally round perimeter, such as a circular perimeter. The crack loops may be particularly small, such as having a cross-sectional dimension in a direction along a surface of the glass article that is less than 10 mm, such as less than 2 mm, such as less than 1 mm, such as less than 0.7 mm (as shown in FIG. 6A for example), and/or at least 10 μm, such as at least 50 μm, such as at least 100 μm, such as at least 200 μm.

Thickness of the article, uniformity of the dimensions of the article, rate of loading, composition and microstructure of the borosilicate glass, support underlying the article, geometry of the indenter, or other parameters may influence fracture behavior. For example, Applicants demonstrated different size crack loops with the DUE composition resulting from different loading, as discussed above.

If the cone extends to the opposing surface and the crack loop intersects the cone, as shown in FIG. 14, then the ring crack in combination with the cone may form a crack-enclosed section of the article that passes fully through the article. At least portions of the crack-enclosed section may have a round periphery, such as at surfaces of the article. The crack enclosed section may generally have a cone shape, an hourglass shape, or another shape. Due to unique fracture behavior of borosilicate glasses disclosed herein, purposeful mechanical fracturing of the glass articles may be used to form holes or other precise geometries, such as surface dimples where a cone does not extend fully through the article. Etchants, lasers, plasma, heat, etc., may be used to further process the articles, such as to arrest cracks, dull sharp edges associated with the cracking.

In contemplated embodiments, an article may have at least one crack loop and/or associated structure (e.g., hole) as disclosed above, or the article may have more than one of the crack loops, such as at least 10, at least 100, at least 1000 crack loops, which may connect with cones to pass fully through such articles to form holes, when (fractured) glass interior to the crack loop is removed, such as mechanically or by chemical etchants. Such articles may be useful as a sieve, a mesh, a panel, a substrate or component in a battery or electronic device for example. Lines of small crack loops in series (e.g., perforation line) may aid in controlled separation of sheets or shapes through guided fracture between the loops. Holes formed in the article may allow for breathability of the article, and/or for liquids, adhesives, polymers in fluid-state, conductive metals, etc. to pass through the article. The loops cracks may be arranged in a pattern or in patterns on the article. In some contemplated embodiments, such as with articles (e.g., sheets) having more than one crack loop, the crack loops may vary in size, such as where one crack loop has a diameter that is at least 20% greater than another crack loop in the same article.

Controlled cracking of an article, such as a sheet of borosilicate glass as disclosed herein, may differ from use of lasers to crack a glass sheet to form a via or other hole or feature because the crack loops disclosed herein may be a single continuous crack ring, as opposed to numerous smaller cracks extending in various directions. The crack loop may be unlikely to propagate beyond the loop, as demonstrated by the testing disclosed herein. In some embodiments, articles that include one or more crack loops or associated structures may not require or may require fewer etchants or other means to dull edges or microcracking.

With that said, some inventive glasses disclosed herein may have conventional fracture behavior, such as glasses that are borosilicate glasses that are able to be fusion formed but have normal or anomalous cracking in Vickers indention testing as disclosed herein. And vice versa, some inventive glasses disclosed herein may have unique crack loop fracture behavior, such as glasses that are borosilicate glasses but may be more difficult to fusion form. Still other embodiments may have the unique fracture behavior and fusion formability, thereby providing glasses that are particularly advantageous for outer plies in laminate windshields or in other articles disclosed herein.

Each of U.S. Application Nos. 63/023,518 filed May 12, 2020, Ser. No. 17/327,870 filed May 24, 2021, 63/088,525 filed Oct. 7, 2020, Ser. No. 17/068,272 filed Oct. 12, 2020, 63/136,381 filed Jan. 12, 2021, 63/151,210 filed Feb. 19, 2021, 63/177,536 filed Apr. 21, 2021, 63/209,489 filed May 11, 2021 is incorporated by reference herein in its entirety. U.S. Application No. 63/059,105 filed Jul. 30, 2020 is incorporated by reference herein in its entirety. U.S. Application No. 63/050,181 filed Jul. 10, 2020 is incorporated by reference herein in its entirety.

According to exemplary embodiments and in furtherance of the above disclosed information, further examples are herein described. The further examples are summarized in the Table 200 below.

TABLE 200

| Example | 26 | 27 | 28 | 29 |
|---|---|---|---|---|
| SiO₂ | 75.93 | 75.71 | 76.06 | 75.70 |
| Al₂O₃ | 3.46 | 3.56 | 3.54 | 3.49 |
| B₂O₃ | 12.65 | 12.64 | 12.34 | 12.68 |
| Na₂O | 5.20 | 5.24 | 6.07 | 5.23 |
| K₂O | 0.92 | 0.94 | 0 | 0.93 |
| MgO | 1.74 | 1.77 | .03 | 1.77 |
| CaO | 0 | 0 | 1.82 | 0.02 |
| SnO₂ | 0.06 | .06 | 0.11 | 0.06 |
| Fe₂O₃ | 0.04 | 0 | 0 | 0.12 |
| Density (g/cm³) | 2.266 | 2.26 | 2.296 | — |
| Strain Point (° C.) | 494 | — | — | — |
| Anneal Point | 540 | — | — | — |
| (° C.) | | | | |
| LTCTE | 4.5 | — | — | |
| (ppm/° C.) | | | | |
| Young's | 62.7 | — | — | |
| Modulus (GPa) | | | | |
| Poisson's Ratio | 0.196 | — | — | |
| Fulchers A | −1.891 | — | — | |
| Fulchers B | 7026.7 | — | — | |
| Fulchers T₀ | 25.3 | — | — | |
| 200 P Temp (° C.) | 1702 | — | — | |
| 35 kP Temp (° C.) | 1117 | — | — | |
| 200 kP Temp | 1002 | — | — | |
| (° C.) | | | | |
| Liquidus | 1388 | — | — | |
| Viscosity (kP) | | | | |
| Phase | Cristobalite | — | — | |

As shown in the Table 200, the composition of Example 26 includes greater than or equal to 12 mol % B₂O₃, Al₂O₃ in an amount that is greater than or equal to 3 mol % and less than or equal to 5 mol %, Na₂O in an amount that is greater than or equal to 4 mol % and less than or equal to 6 mol %, and meets the relationships (1), (2), (3), and (4) described herein. Accordingly, glasses constructed in accordance with Example 26 exhibit the favorable fracture behavior described herein and may also be fusion formed to produce glass articles suitable for the uses described herein.

In embodiments, the glass compositions described herein include amounts of Al₂O₃ and Na₂O that satisfy the relationship Na₂O>Al₂O₃+1, (e.g., Na₂O>Al₂O₃+1.25, Na₂O>Al₂O₃+1.5, Na₂O>Al₂O₃+1.75, Na₂O>Al₂O₃+2.0). In embodiments, the Al₂O₃ content of the glass compositions described herein is greater than or equal to 2.0 mol % and less than or equal to 5.0 mol % (e.g., greater than or equal to 2.5 mol % and less than or equal to 5.0 mol %, greater than or equal to 3.0 mol % or les than or equal to 5 mol %). When combined with compositions having greater than or equal to 12.0 mol % B₂O₃ (e.g., greater than or equal to 13.0 mol % B₂O₃, greater than or equal to 14.0 mol % B₂O₃, greater than or equal to 15.0 mol % B₂O₃ and less than or equal to 16 mol % B₂O₃), such Al₂O₃ content is sufficient to prevent phase separation of the borosilicate glass, yet low enough such that SiO₂ and B₂O₃ are the primary network formers in the glass. With the Al₂O₃ content at such levels, Na₂O content in excess of Al₂O₃ assists in dissolution of the silica during melting of the glass. In embodiments, the Na₂O content in the glass composition described herein is less than or equal to 6.25 mol % (e.g., less than or equal to 6.20 mol %, less than or equal to 6.15 mol %, less than or equal to 6.10 mol %, less than or equal to 6.05 mol %, less than or equal to 6.0 mol %,), as Na₂O in excess of this amount may lead to an undesirably high CTE of the glass. In such embodiments, the Na₂O content is at least 4.0 mol %. In embodiments, when the Na₂O content satisfies these criteria, K₂O, if included, is included in an amount that is less than Na₂O, such as in an amount that is greater than or equal to 0.8 mol % and less than or equal to 5 mol %, but less than the amount of Na₂O, as K₂O tends to increase CTE to a greater extent than Na₂O per unit of composition. For example, in embodiments, the glass compositions described herein include a ratio of K₂O to Na₂O that is from about 0.1 to about 0.75. Glass compositions meeting the aforementioned constraints may be suitable for fusion-forming and exhibit the unique fracture behavior described herein, while still having favorably low CTEs.

In embodiments, the glass compositions of the present disclosure comprise greater than or equal to 12.0 mol % B₂O₃, greater than or equal to 2.0 mol % and less than or equal to 5.0 mol % Al₂O₃ or greater than or equal to 3.0 mol % and less than or equal to 5.0 mol % Al₂O₃, greater than or equal to 4.0 mol % and less than or equal to 6.25 mol % Na₂O, and greater than or equal to 0.8 mol % and less than or equal to 5.0 mol % K₂O, wherein Na₂O is greater than or equal to Al₂O₃+1.0 and a ratio of the K₂O content to the Na₂O content is greater than or equal to 0.1 and less than or equal to 0.75. Such a set of compositional ranges facilitates generating glasses described herein having liquidus viscosities of greater than or equal to 500 kP and meeting the CTE requirements described herein (e.g., a LTCTE of 5.1 ppm/° C. or less).

Samples having the composition of Example 26 provided in the Table 300 were tested for various characteristics. In a first set of tests, the samples were subjected various chemical treatments to determine the chemical durability of the samples. Two glass samples (2″ by 2″) having different compositions were subjected to the same chemical treatments to serve as a basis of comparison. Comparative Example 26A was a borosilicate glass including 83.60 mol % SiO₂, 1.20 mol % Al₂O₃, 11.60 mol % B₂O₃, 3.00 mol % Na₂O, and 0.70 mol % K₂O. Comparative Example 26B was an untinted soda lime glass. Each of the samples were immersed in a 5% w/w HCl solution for a period of 24 hours at an elevated temperature of 95° C. Samples of the same composition were also immersed in a 5% w/w NaOH solution for a period of 6 hours at an elevated temperature of 95° C. After immersion, the samples were cleaned and subsequently dried. Optical transmission of each sample at 450 nm was measured. Haze was also measured. The results are shown in Table 300 below.

As used herein, the terms “transmission haze” and “haze” refer to the percentage of transmitted light scattered outside an angular cone of about ±2.5° in accordance with ASTM procedure D1003, entitled “Standard Test Method for Haze and Luminous Transmittance of Transparent Plastics,” the contents of which is incorporated by reference herein in its entirety. Unless otherwise noted, all haze measurements reported in the disclosure were obtained on a Haze-Guard transmittance meter (Paul N. Gardner Company). For an optically smooth surface, transmission haze is generally close to zero.

TABLE 300

| | | Weight | | % | |
|---|---|---|---|---|---|
| | | Change | Standard | Transmission | % |
| Test | Sample | Mean | Deviation | at 450 nm | Haze |
| Media | Description | mg/cm² | mg/cm² | Average | Average |
| 5% w/w | Example 26 | 0.010 | 0.00 | 93.85 | 0.00 |
| HCl | Comparative | 0.010 | 0.00 | 92.69 | 0.00 |
| 95° C. | Example 26A | | | | |
| 24 hours | Comparative | 0.011 | 0.00 | 91.90 | 0.00 |
| | Example 26B | | | | |
| 5% w/w | Example 26 | 3.09 | 0.03 | 91.99 | 0.00 |
| NaOH | Comparative | 2.82 | 0.00 | 92.57 | 0.00 |
| 95° C. | Example 26A | | | | |
| 6 hours | Comparative | 0.79 | 0.01 | 91.60 | 0.22 |
| | Example 26B | | | | |

As shown in the Table 300, the samples according to Example 26 described herein had relatively low weight loss (of about 0.010 mg/cm²) as a result of the acidic chemical treatment in the HCl solution and showed favorable optical qualities, with superior transmission to both comparative examples. The basic chemical treatment in the NaOH solution resulted in relatively high weight loss in both the samples according to Example 26 and Comparative Example 26A. While the samples in accordance with Comparative Example 26B (the soda lime glass) experienced lower weight loss in the basic solution, such treatments resulted in increased haze, representing inferior optical appearance. These results indicate that the compositions described herein may possess the chemical durability for use in applications such as glass containers of various liquids (e.g., pharmaceutical containers such as vials, syringes, ampoules, and cartridges).

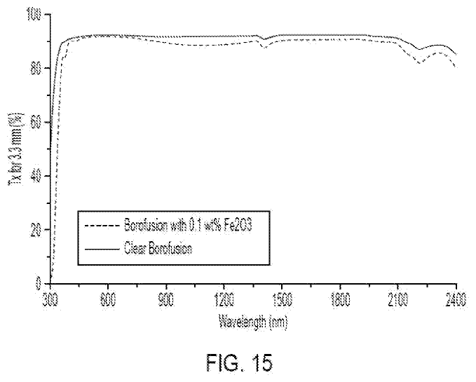

As shown in the Table 200, Example 26 comprised 0.1 wt % Fe₂O₃. The transmission spectrum of a 3.3 mm thick sample was measured for comparison with the results contained in Table 5 herein. FIG. 15 provides a graph of the transmittance measured in accordance with ISO 13837 for the sample according to Example 26 as well as another example with 0 mol % Fe₂O₃ (Example 3 in Table 1 above). As can be seen, the addition of Fe₂O₃ lowers overall measured transmittance, especially in the infrared spectrum (at greater than or equal to 750 nm). The UV cutoff wavelength is also greater than 300 nm (approximately 320 nm), indicating greater UV absorption than the iron-free embodiment, and the transmittance is greater than or equal to 90% throughout the entire visible spectrum. Such results indicate the suitability of the glasses described herein for use in windshields, providing shielding from solar heating and UV rays, while still providing favorable transmittance in the visible spectrum. The composition in accordance with Example 26 has a relatively high transmittance throughout the visible spectrum, which provides beneficial clarity for use in a windshield, while still blocking UV and IR portions of sunlight.

A 3.3 mm thick sample having the composition according to Example 26 and a 2.1 mm thick sample having the composition according to Example 29 were prepared for optical testing. Visible light transmission (T_{VIS}) and total solar transmission (TTS) transmission measurements were taken for each sample. The results are provided in the Table 400 below.

TABLE 400

| | |
|---|---|
| Example 26 (3.3 mm) | Example 29 (2.1 mm) |

| | | |
|---|---|---|
| Fe | oxalate | oxalate |
| source | | |

| | | | | |
|---|---|---|---|---|
| Fe | 0.1 | wt % | 0.3 | wt % |
| level | | | | |
| UV | 320 | nm | 378 | nm |

| | | |
|---|---|---|
| cutoff | | |
| Tuv | 59.5 | 12.0 |
| Tvis | 91.6 | 88.5 |
| TTS | 90.8 | 87.0 |

As shown in the Table 400, the sample with 0.1 wt % Fe₂O₃, despite having a greater thickness, possessed a visible transmission value of over 90%, while the sample with greater Fe₂O₃ content did not. Depending on visible transmission requirements, the glass compositions described herein may be provided with a suitable amount of iron oxide.

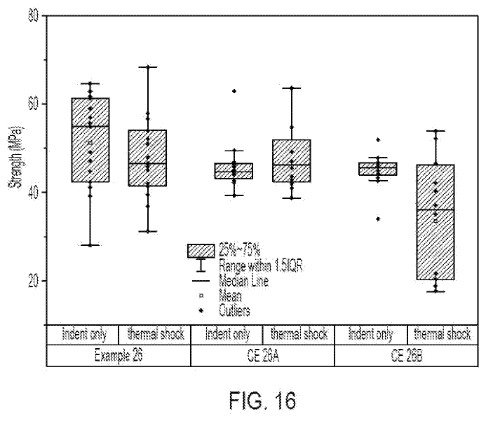

With reference to FIG. 16, samples having a 2 mm thickness and the compositions of Example 26 and Counter Examples 26a and 26b were subjected to flexural strength testing after indentation via a Vickers indenter both prior to and after inducing thermal shock. The flexural strength testing was conducted via ring-on-ring tests, which were generally performed according to the ASTM C-1499-03 standard test method for Monotonic Equibiaxial Flexural Strength of Advanced Ceramics at Ambient Temperatures. In particular, samples according to Example 26 and Counter Examples 26a and 26b described herein were indented with a Vickers indenter at 3 kgf as discussed above in relation to FIGS. 5A and 5B. Ring-on-ring testing was then conducted for some of the specimens immediately after indentation. After indentation, thermal shock was induced in some of the specimens by heating the specimens on a 125° C. hot plate for 10 minutes. After heating, a droplet of water (at 25° C. f 5° C.) was dropped onto the indent site while the specimens were still hot. Ring-on-ring testing was then conducted on the samples after cooling to determine the effects of thermal shock on flexural strength.

As shown in FIG. 16, the samples in accordance with Example 26 show comparable levels of retained strength after being subjected to thermal shock as the samples in accordance with Counter Example 26a. It is anticipated that the comparable results are the result of the ring-on-ring testing procedure. During testing, the rings were centered on the indent and contacted the glass on the surface opposite the indentation. Due to the alignment between the rings and the indent, it is believed that contained fracture behavior (the ring crack containing radially-extending cracks) exhibited by the glass in accordance with Example 26 had minimal effects on the retained strength measurements. Given the higher CTE of certain glasses of the present disclosure than conventional boro-float glasses, it is not surprising that the thermal shock resulting in a diminished flexural strength as compared to samples not subjected to thermal shock. However, despite having a higher LTCTE, the samples according to Example 26 had comparable levels of retained strength as those constructed according to Counter Example 26a. The samples according Example 26 had higher retained strength levels than those constructed according to Counter Example 26b, indicating that the glasses described herein provide favorable retained strength and thermal performance over certain existing glass compositions used in existing glass laminates.

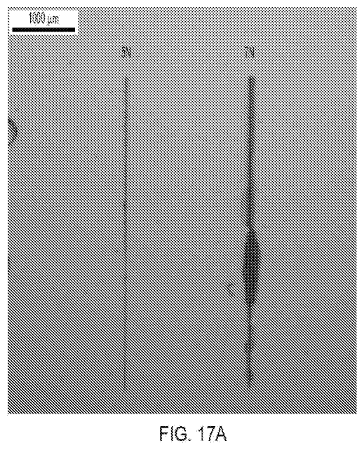

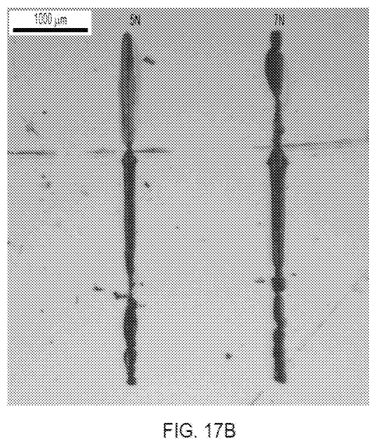

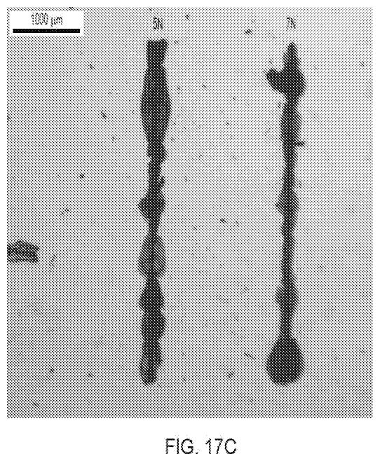

With reference to FIGS. 17A-17C, samples having compositions according to Example 26 and Counter Examples 26a and 26b were subjected to lateral Knoop scratch testing on surfaces thereof to determine the scratch resistance. A mechanical tester holding a Knoop diamond was used to scratch surfaces of the samples at about 23° C. at a relative humidity of about 50%. The scratch length on each of the samples was 5.0 mm, with the samples being scratched at a speed of 24 mm/min. FIG. 17A depicts an image of a sample having a composition according to Example 26 and scratched with loads of 5N and 7N. FIG. 17B depicts an image of a sample having a composition according to Counter Example 26a and scratched with loads of 5N and 7N. FIG. 17C depicts an image of a sample having a composition according to Counter Example 26b and scratched with loads of 5N and 7N. As shown, the samples constructed according to Example 26 demonstrated favorable scratch performance over the counter examples. When a load of 5N was used to scratch the samples, a lateral crack width of the scratch for those samples had a maximum value of 67.7 μm. Samples constructed according to Counter Examples 26a and 26b had maximum lateral crack widths of 337.44 μm and 485 μm, respectively. Such results indicate that glass compositions described herein may provide beneficial cratch resistance performance that is superior to certain glasses currently used in various applications (e.g., automotive glazings). In embodiments, glass articles comprising glass compositions according to the present disclosure may exhibit maximum lateral crack widths that are less than or equal to 80 μm (e.g., less than or equal to 75 μm, less than or equal to 70 μm) when scratched with a Knoop diamond at a scratch rate of 24 mm/min.

As described herein with respect to FIG. 3-4, the glass compositions described herein may find use in curved glass articles, such as curved glass laminates. For example, glasses in accordance with the present disclosure may be used as the first glass ply 310 depicted in FIGS. 3-4, while a glass having a different compostions (e.g., an annealed soda lime glass, an ion-exchanged aluminoborosilicate glass, etc.) may be used as the second glass ply 310. During fabrication of the curved glass laminate 400 (see FIG. 4), for example, the glass lies 310, 320 may be subjected to a co-sagging process, where the glass plies 310, 320, initially in a planar state, may be heated to a suitable sag temperature in order to be curved to a suitable depth of curvature. As used herein, “sag temperature” means the temperature at which the viscosity of the glass substrate is about 10¹¹ poises. The sag temperature is determined by fitting the Vogel-Fulcher-Tamman (VFT) equation: Log h=A+B/(T−C), where T is the temperature, A, B and C are fitting constants and h is the dynamic viscosity, to annealing point data measured using the bending beam viscosity (BBV) measurement, to softening point data measured by fiber elongation. In embodiments, the glass compositions used for the glass plies 310, 320 comprise sag temperatures that differ from one another by 5° C. or greater, about 10° C. or greater, about 15° C. or greater, about 20° C. or greater, about 25° C. or greater, about 30° C. or greater, or about 35° C. or greater.

In embodiments, the glasses described herein (such as those according to the Examples described herein) comprise a viscosity of 10¹¹ poises at a temperature that is greater than or equal to 590° C. and less than or equal to 630° C. Such viscosities are comparable to certain soda lime compositions used in glass laminates at the same temperatures. As a result, the glasses according to the present disclosure are suitable for co-sagging using existing methods and processes, and capable of forming laminates with the favorable optical distortion and shape matching performance described herein.

After being heated to a suitable sag temperature and sagged to a desired curved shape, the glass plies 310, 320 may be cooled at a suitable cooling rate. As a result of the cooling, the surfaces of the glass ply 310 (which may be formed of a glass composition according to the Examples described herein) may cool at a greater rate than a central region of the glass ply 310, resulting in a compressive stress extending from the surfaces of the glass ply 310 inward to a depth of compression and a tensile stress in a central region extending inward from the depth of compression. Such tensile and compressive stresses are “annealing stresses.” In embodiments, the depth of compression to which the compressive stress from the post-sagging cooling extends into the glass ply 310 is equal to 0.21 times the thickness 210 of the glass ply 310 (see FIG. 2). The magnitude of the post sagging cooling-induced tensile stress in such embodiments may be approximated by

$${σ}_{CT} = \frac{E * α * {t}^{2} * R}{24 K * ( 1 - v )} \qquad ( Equation 1 )$$

where E is the Young's modulus of the glass ply 310, a is the coefficient of thermal expansion of the glass in the temperature range of the cooling, t is the thickness of the glass ply 310, R is the cooling rate, K is the thermal diffisivity of the glass, and v is the Poission's ratio of the glass. The compressive stress integrated from the depth of compression to the surfaces of the glass ply 26 may be calculated as −2*σ_{CT}. Membrane stresses were calculated for glasses constructed according to Example 26 and Counter Examples 26a and 26b described herein. The results are contained in the Table 500 below.

TABLE 500

| | | | Example |
|---|---|---|---|
| | CE 26b | CE 26a | 26 |
| E (Gpa) | 72 | 62.8 | 62.7 |
| Poisson's ratio | 0.22 | 0.2 | 0.196 |
| CTE (ppm/C) | 8.8 | 3.25 | 4.5 |
| thermal diffusivity @ 600 C (cm²/s) | 0.004813 | 0.006026 | 0.00565 |
| cooling rate (° C./s) | 1.67 | 1.67 | 1.67 |
| glass thickness (mm) | 2.1 | 2.1 | 2.1 |
| CT (MPa) | 0.52 | 0.13 | 0.19 |
| CS (MPa) | −1.03 | −0.26 | −0.38 |
| CS ratio to Example 26 | 2.72 | 0.68 | 1 |
| glass thickness (mm) | 3.8 | 3.8 | 3.8 |
| CT (MPa) | 1.69 | 0.42 | 0.62 |
| CS (MPa) | −3.38 | −0.85 | −1.25 |
| CS ratio to Example 26 | 2.72 | 0.68 | 1 |

As shown, annealed central tension (denoted “CT” in the Table 500) and the magnitude of compressive stress (denoted “CS” in the Table 500) for Example 26 is between the values for Counter Example 26b (soda lime glass) and Counter Example 26a (an existing borosilicate glass). The CS and CT values were computed at thicknesses of 2.1 mm and 3.8 mm, 2.1 mm is a commonly-used thickness for outer plies in automotive glazings. As shown, at 2.1 mm thickness, the sample constructed in accordance with Example 26 comprised an annealed tensile stress of 0.19 MPa, greater than the 0.13 MPa achieved for an existing borosilicate glass and less than the 0.52 MPa achieved for the soda lime glass. At 3.8 mm thickness, the sample constructed in accordance with Example 26 comprised an annealed tensile stress of 0.62 MPa, greater than the 0.42 MPa achieved for an existing borosilicate glass and less than the 1.69 MPa achieved for the soda lime glass. Annealing stresses may be measured using SCALP device.

According to exemplary embodiments and in furtherance of the above disclosed information, further aspects of the example glass compositions described herein are now described.

In the following paragraphs, the term “tramp”, when used to describe a particular constituent component in a glass composition, refers to a constituent component that is not intentionally added to the glass composition and is present in an amount of less than 0.10 mol. %. Tramp components may be unintentionally added to the glass composition as an impurity in another constituent component and/or through migration of the tramp component into the composition during processing of the glass composition.

In the following paragraphs, the terms “free” and “substantially free” are used interchangeably herein to refer to an amount and/or an absence of a particular component in a glass composition that is not intentionally added to the glass composition. It is understood that the glass composition may contain traces of a particular constituent component as a contaminant or a tramp in an amount of less than 0.10 mol. %.

In the following paragraphs, the term “glass former” is used herein to refer to a component that, being solely present in a glass composition (i.e., without other components, except for tramps), is able to form a glass when cooling the melt at a rate of not greater than about 300° C./min.

In the following paragraphs, the term “modifier”, refers to the oxides of monovalent or divalent metals, i.e., R₂O or RO, where “R” stands for a cation. Modifiers can be added to a glass composition to change the atomic structure of the melt and the resulting glass. In some embodiments, the modifier may change the coordination numbers of cations present in the glass formers (e.g., boron in B₂O₃), which may result in forming a more polymerized atomic network and, as a result, may provide better glass formation.

In the following paragraphs, the term “rare earth metals” refers to the metals listed in the Lanthanide Series of the IUPAC Periodic Table, plus yttrium and scandium. As used herein, the term “rare earth metal oxides.” is used to refer to the oxides of rare earth metals in different redox states, such as “+3” for lanthanum in La₂O₃, “+4” for cerium in CeO₂, “+2” for europium in EuO, etc. In general, the redox states of rare earth metals in oxide glasses may vary and, in particular, the redox state may change during melting, based on the batch composition and/or the redox conditions in the furnace where the glass is melted and/or heat-treated (e.g., annealed). Unless otherwise specified, a rare earth metal oxide is referred to herein by its normalized formula in which the rare earth metal has the redox state “+3.” Accordingly, in the case in which a rare earth metal having a redox state other than “+3” is added to the glass composition batch, the glass compositions are recalculated by adding or removing some oxygen to maintain the stoichiometry. For example, when CeO₂ (with cerium in redox state “+4”) is used as a batch component, the resulting as-batched composition is recalculated assuming that two moles of CeO₂ is equivalent to one mole of Ce₂O₃, and the resulting as-batched composition is expressed in terms of Ce₂O₃. As used herein, the term “REₘOₙ” is used to refer to the total content of rare earth metal oxides in all redox states present, and the term “RE₂O₃” is used to refer to the total content of rare earth metal oxides in the “+3” redox state, also specified as “trivalent equivalent”.

In the mathematical formulas used in the following paragraphs, the term “min(A, B)” means the least of the values A and B, and the term “max(A, B)” means the greatest of the quantities A and B, where “A” and “B” may be any quantities (concentrations of components, values of properties, etc.). The term “abs(X)” means absolute value of a quantity X (without sign).

In the glass compositions described herein, SiO₂ may play a role of a major glass former. Without wishing to be bound by theory, it is believed that tetrahedra [SiO₄], as a part of the structural network of glass, are connected with other structural units that may be rotatable, such as, in particular, tetrahedra [AlO₄] and triangles [BO₃]. Such connections between tetrahedra and triangles may cause the anomalous fracture behavior described herein. Additionally, SiO₂ was found to increase the viscosity of the glass forming melts, increase the liquidus viscosity, reduce the thermal expansion coefficient and increase the Young's modulus, therefore improving mechanical properties. Then, at high content of silica, a glass may become more chemically durable. However, when the content of SiO₂ in a glass composition becomes too high, this may cause an unacceptably large high-temperature viscosity, which may cause some difficulties with melting, such as, for example, corrosion of the refractories in the glass melting tank. Also, at very high content of SiO₂, the structural network of glass may contain insufficient amounts of rotatable units, may cause the loss of the anomalous fracture behavior. Accordingly, in embodiments, the glass compositions described herein may contain, in addition to the other ranges of SiO₂ contents described herein, SiO₂ in an amount greater than or equal to 60.0 mol % and less than or equal to 96.0 mol %, greater than or equal to 60.0 mol % and less than or equal to 80.0 mol %, greater than or equal to 60.0 mol % and less than or equal to 77.5 mol %, greater than or equal to 72.0 mol % and less than or equal to 78.0 mol %, greater than or equal to 73.0 mol % and less than or equal to 77.0 mol %, greater than or equal to 73.4 mol % and less than or equal to 76.8 mol %, greater than or equal to 73.8 mol % and less than or equal to 76.4 mol %, greater than or equal to 74.62 mol % and less than or equal to 75.88 mol %, greater than or equal to 65.0 mol % and less than or equal to 75.9 mol %, greater than or equal to 72.0 mol % and less than or equal to 75.9 mol %, greater than or equal to 73.0 mol % and less than or equal to 96.0 mol %, greater than or equal to 74.6 mol % and less than or equal to 75.9 mol %.

In the glass compositions described herein, B₂O₃ may play a role of the network former together with SiO₂ and Al₂O₃. As a part of the structural network of glass, boron oxide may form either tetrahedra [BO₄] or triangles [BO₃], depending on the contents of other components. Without wishing to be bound by a particular theory, it is believed that the amount of tetrahedra [BO₄] increases when the content of modifiers (monovalent metal oxides R₂O and divalent metal oxides RO) exceeds the amount of alumina in a particular glass composition. In embodiments, both triangles [BO₃] and tetrahedra [BO₄] may play a significant role in the glass compositions described herein. Tetrahedra [BO₄] may increase the connectivity of structural network, which may make the network more rigid and increase the viscosity, especially at low temperatures, not causing undesirable precipitation of refractory minerals from the melt. Triangles [BO₃] may be rotatable structural units, which may provide the anomalous fracture behavior described herein. Accordingly, the glass compositions of the present disclosure include boron oxide. However, when the content of B₂O₃ becomes too high, this may reduce the liquidus viscosity, which may potentially cause precipitation of refractory minerals in the glass. Also, at high content of boron oxide, a glass composition may not be acceptably durable to alkalis and acids, or a glass forming melt may tend to liquid-liquid phase separation, which may make a glass opaque. In embodiments, the glass compositions described herein may contain, in addition to the other ranges of B₂O₃ contents described herein. B₂O₃ in an amount greater than or equal to 1.0 mol % and less than or equal to 25.0 mol %, greater than or equal to 5.0 mol % and less than or equal to 20.0 mol %, greater than or equal to 5.0 mol % and less than or equal to 17.0 mol %, greater than or equal to 10.5 mol % and less than or equal to 19.0 mol %, greater than or equal to 11.75 mol % and less than or equal to 17.75 mol %, greater than or equal to 12.07 mol % and less than or equal to 13.8 mol %.

In an investigation, it was empirically found that the addition of even small amounts of rare earth metal oxides to the glass compositions described herein may result in increased liquidus temperatures and precipitation of refractory minerals. It was also empirically found that addition of rare earth oxides may reduce the chemical durability of resultant glasses, especially to acids. For that reason, in some embodiments of the present disclosure, the content of rare earth metal oxides in the glass composition is limited, or a glass composition may preferably be free (or substantially free) of rare earth metal oxides.

Glass compositions of the present disclosure may also include lithium oxide (Li₂O). Lithium oxide may play a role of modifier, similar to other alkali metal oxides. However, it was empirically found that addition of Li₂O to the glass compositions of the present disclosure may result in increasing the liquidus temperature and reducing the liquidus viscosity. Also, glasses with Li₂O may have lower chemical durability comparing to the glasses with same amounts of other alkali metal oxides. Li₂O was also found to potentially cause reduction of the anomalous fracture behavior described herein. Without wishing to be bound by theory, it is believed that Li₂O additions may lead to higher packing density of cations, which may increase the density and reduce the anomalous fracture behavior. Accordingly, in embodiments, the content of Li₂O in the glass compositions described herein may be limited, or the glass composition may preferably be free (or substantially free) of Li₂O.

Glass compositions of the present disclosure may also include magnesia (MgO). In embodiments, magnesia may be added to the glass composition to increase the Young's modulus of the resultant glass and/or improve other mechanical properties. Magnesia may beneficially not increase the density and also not increase the thermal expansion coefficient of glass to the same extent as other glass modifiers. It was also found that adding a small amount of magnesia to the glass compositions of the present disclosure may improve the anomalous fracture behavior. However, when the content of MgO in a glass composition is too large, the glass forming melt may precipitate the refractory minerals, which may increase the liquidus temperature and/or result in appearance of crystalline defects in the glass articles. Accordingly, in embodiments, the glass compositions of the present disclosure may contain magnesia (MgO) in an amount from greater than or equal to 0.0 mol % to less than or equal to 5.0 mol % and all ranges and sub-ranges between the foregoing values. In embodiments, the glass compositions may contain MgO in an amount less than or equal to 5.0 mol %, less than or equal to 2.5 mol %, less than or equal to 2.0 mol %, less than or equal to 1.8 mol %, or less than or equal to 1.75 mol %. In embodiments, the glass composition may contain MgO in an amount greater than or equal to 0.0 mol % and less than or equal to 5.0 mol %, greater than or equal to 0.0 mol % and less than or equal to 2.0 mol %, greater than or equal to 0.0 mol % and less than or equal to 1.8 mol %, greater than or equal to 0.35 mol % and less than or equal to 1.75 mol %, greater than or equal to 0.68 mol % and less than or equal to 1.75 mol %, greater than or equal to 0.0 mol % and less than or equal to 1.75 mol %.

Glass compositions of the present disclosure may also include calcium oxide (CaO). Calcium oxide may be added in a glass composition to improve chemical durability and increase the Young's modulus, therefore improving mechanical properties. Also, alkaline earth oxides, such as CaO and MgO, tend to reduce liquidus temperature and increase liquidus viscosity. It was empirically found that adding a small amount of CaO may improve the anomalous fracture behavior. However, when the content of CaO is high, this may cause precipitation of refractory minerals, which may result in appearance of crystalline defects in glass articles. Also, adding high amount of CaO to the glass compositions with high content of B₂O₃ may sometimes cause liquid-liquid phase separation of the melt, resulting in loss of light transmittance. Accordingly, in embodiments, the glass composition may contain calcium oxide (CaO) in an amount from greater than or equal to 0.0 mol % to less than or equal to 5.0 mol % and all ranges and sub-ranges between the foregoing values. In some other embodiments, the glass composition may contain CaO in an amount less than or equal to 5.0 mol %, less than or equal to 2.5 mol %, less than or equal to 2.0 mol %, less than or equal to 1.9 mol %, less than or equal to 1.7 mol %, less than or equal to 1.5 mol %, or less than or equal to 1.0 mol %. In some more embodiments, the glass composition may contain CaO in an amount greater than or equal to 0.0 mol % and less than or equal to 2.0 mol %, greater than or equal to 0.0 mol % and less than or equal to 1.9 mol %, greater than or equal to 0.0 mol % and less than or equal to 1.7 mol %, greater than or equal to 0.0 mol % and less than or equal to 1.5 mol %, greater than or equal to 0.02 mol % and less than or equal to 1.02 mol %, greater than or equal to 0.0 mol % and less than or equal to 5.0 mol %, greater than or equal to 0.0 mol % and less than or equal to 1.0 mol %.

In embodiments, the glass compositions of the present disclosure may have a combined amount of CaO and MgO (CaO+MgO) that is less than or equal to 5.0 mol % or less than or equal to 2.5 mol %. In embodiments, CaO+MgO is greater than or equal to 0.0 mol % and less than or equal to 5.0 mol %, or greater than or equal to 0.0 mol % and less than or equal to 2.5 mol %.

Glass compositions of the present disclosure may also include zirconia (ZrO₂). Zirconia may be added in the glass compositions of the present disclosure to improve the mechanical properties and/or to increase the viscosity of the glass forming melts. However, it was empirically found that in some embodiments of the present disclosure, especially when the total content of alkali metal oxides (in mol %) does not exceed or only slightly exceeds the content of alumina (in mol %), adding zirconia to the glass compositions, sometimes even in a very small amount, may increase the liquidus temperature and/or cause precipitation of the refractory minerals from the glass forming melts. Accordingly, in some embodiments of the present disclosure, the content of zirconia in the glass composition is limited, or the glass composition may be substantially free of ZrO₂. In embodiments, the glass composition may contain zirconia (ZrO₂) in an amount from greater than or equal to 0.0 mol % to less than or equal to 5.0 mol % and all ranges and sub-ranges between the foregoing values. In some other embodiments, the glass composition may contain ZrO₂ in an amount less than or equal to 5.0 mol %, less than or equal to 2.5 mol %, less than or equal to 1.5 mol %, less than or equal to 1.35 mol %, less than or equal to 1.2 mol %, or less than or equal to 1.0 mol %. In some more embodiments, the glass composition may contain ZrO₂ in an amount greater than or equal to 0.0 mol % and less than or equal to 1.5 mol %, greater than or equal to 0.0 mol % and less than or equal to 1.35 mol %, greater than or equal to 0.0 mol % and less than or equal to 1.2 mol %, greater than or equal to 0.01 mol % and less than or equal to 1.01 mol %, greater than or equal to 0.0 mol % and less than or equal to 5.0 mol %, greater than or equal to 0.0 mol % and less than or equal to 1.0 mol %.

Glass compositions of the present disclosure may include barium oxide (BaO). Barium oxide may be unintentionally added in a glass composition as an impurity in other raw materials or intentionally added in favor of lower melting temperatures or higher chemical durability. It was empirically found that adding BaO to glass compositions of the present disclosure may result in increasing the liquidus temperature, which may cause crystallization of the glass forming melts when cooling and forming. Also, barium as a large cation may reduce the anomalous fracture behavior. Accordingly, in the glass compositions of the present disclosure, the content of BaO is limited, and the glass compositions may preferably be free of BaO. In embodiments, the glass composition may contain barium oxide (BaO) in an amount from greater than or equal to 0.0 mol % to less than or equal to 0.2 mol % and all ranges and sub-ranges between the foregoing values. In some other embodiments, the glass composition may contain BaO in an amount less than or equal to 0.2 mol % or less than or equal to 0.1 mol %. In some more embodiments, the glass composition may contain BaO in an amount greater than or equal to 0.0 mol % and less than or equal to 0.2 mol %, greater than or equal to 0.0 mol % and less than or equal to 0.1 mol %.

Glass compositions of the present disclosure may include potassium oxide (K₂O). Potassium oxide may be unintentionally added in a glass composition as an impurity in other raw materials, or intentionally added, for example, to preserve a glass-forming melt from liquid-liquid phase separation. Additions of K₂O may improve the chemical durability of glasses and/or reduce the liquidus temperature. Without wishing to be bound by theory, it is believed that K₂O transforms the structural units created by boron oxide from the triangles [BO₃] to the tetrahedra [BO₄], which may improve the balance between these structural units in the glass composition and, therefore, improve the anomalous fracture behavior. However, adding K₂O to the glass compositions of the present disclosure may reduce the Young's modulus of glass, which may reduce the mechanical properties of the glass articles. Also, adding high amounts of K₂O may unacceptably increase the thermal expansion coefficient of glass. Accordingly, in some embodiments of the present disclosure the content of K₂O in a glass composition is limited, or the glass composition may be substantially free of K₂O. In embodiments, the glass composition may contain potassium oxide (K₂O) in an amount from greater than or equal to 0.0 mol % to less than or equal to 10.0 mol % and all ranges and sub-ranges between the foregoing values. In embodiments, the glass composition may contain K₂O in an amount greater than or equal to 0.0 mol % and less than or equal to 3.0 mol %, greater than or equal to 0.3 mol % and less than or equal to 2.8 mol %, greater than or equal to 0.6 mol % and less than or equal to 2.5 mol %, greater than or equal to 0.92 mol % and less than or equal to 2.18 mol %, greater than or equal to 0.0 mol % and less than or equal to 10.0 mol %, greater than or equal to 0.3 mol % and less than or equal to 2.2 mol %, greater than or equal to 0.6 mol % and less than or equal to 10.0 mol %, greater than or equal to 0.6 mol % and less than or equal to 2.2 mol %, greater than or equal to 0.8 mol % and less than or equal to 2.2 mol %, greater than or equal to 0.9 mol % and less than or equal to 2.2 mol %, greater than or equal to 5.0 mol % and less than or equal to 7.0 mol %.

Glass compositions of the present disclosure may also include alumina (Al₂O₃). In the glass compositions of the present disclosure, alumina plays a role of a network former together with B₂O₃ and SiO₂. As a network former, alumina may increase the viscosity of glass-forming melts and increase the liquidus viscosity, and provide better protection from crystallization. Also, additions of alumina, even in a small amount, may preserve a melt from phase separation. Then, alumina may improve chemical durability of glass. Accordingly, the glass compositions of the present disclosure contain some amount of alumina. However, when added in a large amount, alumina may cause precipitation of refractory minerals from the melt, which may cause crystalline defects in the glass articles. Also, at high content of alumina the viscosity may become too high, which may cause corrosion of the refractories in the glass melting tank. Accordingly, in some embodiments of the present disclosure the content of alumina is limited. In embodiments, the glass composition may contain alumina (Al₂O₃) in an amount from greater than or equal to 0.3 mol % to less than or equal to 5.3 mol % and all ranges and sub-ranges between the foregoing values. In some embodiments, the glass composition may contain Al₂O₃ in an amount greater than or equal to 0.3 mol %, greater than or equal to 2.0 mol %, greater than or equal to 2.2 mol %, greater than or equal to 2.4 mol %, greater than or equal to 2.5 mol %, greater than or equal to 3.45 mol %, greater than or equal to 3.8 mol %, greater than or equal to 4.3 mol %, greater than or equal to 4.8 mol %, or greater than or equal to 5.0 mol %. In some other embodiments, the glass composition may contain Al₂O₃ in an amount less than or equal to 5.3 mol %, less than or equal to 5.0 mol %, less than or equal to 4.8 mol %, less than or equal to 4.3 mol %, less than or equal to 4.0 mol %, less than or equal to 3.9 mol %, less than or equal to 3.8 mol %, less than or equal to 3.65 mol %, less than or equal to 3.53 mol %, or less than or equal to 2.5 mol %. In some more embodiments, the glass composition may contain Al₂O₃ in an amount greater than or equal to 0.3 mol % and less than or equal to 5.3 mol %, greater than or equal to 2.0 mol % and less than or equal to 4.0 mol %, greater than or equal to 2.2 mol % and less than or equal to 3.9 mol %, greater than or equal to 2.4 mol % and less than or equal to 3.65 mol %, greater than or equal to 3.45 mol % and less than or equal to 3.53 mol %, greater than or equal to 0.3 mol % and less than or equal to 2.5 mol %, greater than or equal to 2.0 mol % and less than or equal to 5.3 mol %, greater than or equal to 2.0 mol % and less than or equal to 2.5 mol %, greater than or equal to 2.2 mol % and less than or equal to 2.5 mol %, greater than or equal to 2.4 mol % and less than or equal to 2.5 mol %, greater than or equal to 2.5 mol % and less than or equal to 5.3 mol %, greater than or equal to 3.8 mol % and less than or equal to 3.9 mol %.

Glass compositions of the present disclosure may also include sodium oxide (Na₂O). Sodium oxide may play a role of a modifier, transforming the structural units formed by aluminum and boron cations to a tetrahedral form ([AlO₄] and [BO₄]), which may result in better balance between the structural units that we assume rotatable and non-rotatable, which may result in an improved anomalous fracture behavior of glasses. Also, additions of Na₂O may improve the chemical durability of glass, reduce the liquidus temperature and increase the liquidus viscosity, therefore, better protecting the glass forming melt from crystallization. However, when being added in large amounts, Na₂O may unacceptably reduce the Young's modulus and, therefore, worsen the mechanical properties of the glass articles. Also, large amounts of Na₂O in a glass composition may cause inacceptable increasing the thermal expansion coefficient and, in some cases, reduce the chemical durability of glass. Accordingly, in some embodiments of the present disclosure, content of sodium oxide in the glass composition is limited, or the glass composition may be substantially free of Na₂O. In embodiments, the glass composition may contain sodium oxide (Na₂O) in an amount from greater than or equal to 0.0 mol % to less than or equal to 10.0 mol % and all ranges and sub-ranges between the foregoing values. In some embodiments, the glass composition may contain Na₂O in an amount greater than or equal to 0.0 mol %, greater than or equal to 2.0 mol %, greater than or equal to 2.5 mol %, greater than or equal to 2.9 mol %, greater than or equal to 3.4 mol %, greater than or equal to 4.55 mol %, greater than or equal to 5.0 mol %, greater than or equal to 7.0 mol %, greater than or equal to 8.0 mol %, or greater than or equal to 9.0 mol %. In some other embodiments, the glass composition may contain Na₂O in an amount less than or equal to 10.0 mol %, less than or equal to 9.7 mol %, less than or equal to 9.0 mol %, less than or equal to 8.0 mol %, less than or equal to 7.0 mol %, less than or equal to 6.0 mol %, less than or equal to 5.5 mol %, less than or equal to 5.45 mol %, less than or equal to 5.3 mol %, less than or equal to 5.2 mol %, or less than or equal to 5.0 mol %. In some more embodiments, the glass composition may contain Na₂O in an amount greater than or equal to 0.0 mol % and less than or equal to 5.2 mol %, greater than or equal to 2.0 mol % and less than or equal to 8.0 mol %, greater than or equal to 2.0 mol % and less than or equal to 6.0 mol %, greater than or equal to 2.5 mol % and less than or equal to 5.3 mol %, greater than or equal to 2.9 mol % and less than or equal to 5.5 mol %, greater than or equal to 3.4 mol % and less than or equal to 6.0 mol %, greater than or equal to 4.55 mol % and less than or equal to 5.45 mol %, greater than or equal to 0.0 mol % and less than or equal to 10.0 mol %, greater than or equal to 2.0 mol % and less than or equal to 5.0 mol %, greater than or equal to 2.5 mol % and less than or equal to 5.0 mol %, greater than or equal to 3.4 mol % and less than or equal to 5.0 mol %, greater than or equal to 4.55 mol % and less than or equal to 5.0 mol %.

Glass compositions of the present disclosure may include fluorine (F). Fluorine may be added in a small amount to the glass compositions of the present disclosure as an ingredient of a fining agent or as a component that reduces the liquidus temperature. However, adding fluorine in a glass composition may cause environmental concern. For that reason, in some embodiments of the present disclosure the content of fluorine is limited, and, preferably, the glass composition may be free of fluorine.

In embodiments, the glass compositions of the present disclosure may include a combined amount of iron, chromium, molybdenum, vanadium, copper, and cobalt (Fe+Cr+Mo+V+Cu+Co) that is less than or equal to 1.0 mol % or less than or equal to 0.5 mol %. In embodiments, Fe+Cr+Mo+V+Cu+Co is greater than or equal to 0.0 mol % and less than or equal to 1.0 mol %, or greater than or equal to 0.0 mol % and less than or equal to 0.5 mol %.

In embodiments, the glass compositions of the present disclosure may contain a combined amount of iron(II) and iron (III) oxides (FeO+Fe₂O₃) that is a less than or equal to 0.5 mol % or less than or equal to 0.25 mol %. In embodiments, FeO+Fe₂O₃ is greater than or equal to 0.0 mol % and less than or equal to 0.5 mol %, or greater than or equal to 0.0 mol % and less than or equal to 0.25 mol %.

In embodiments, the glass compositions of the present disclosure may have a combined amount of lanthanum oxide and yttrium(III) oxide La₂O₃+Y₂O₃ that is less than or equal to 1.0 mol % or less than or equal to 0.5 mol %. In embodiments, La₂O₃+Y₂O₃ is greater than or equal to 0.0 mol % and less than or equal to 1.0 mol %, or greater than or equal to 0.0 mol % and less than or equal to 0.5 mol %.

In embodiments, the glass compositions of the present disclosure may have a combined amount of sodium oxide and potassium oxide (Na₂O+K₂O) that is greater than or equal to 0.0 mol %, greater than or equal to 5.0 mol %, or greater than or equal to 6.11 mol %.

In embodiments, Na₂O+K₂O is less than or equal to 6.84 mol % or less than or equal to 5.0 mol %. In embodiments, Na₂O+K₂O is greater than or equal to 0.0 mol % and less than or equal to 6.84 mol %, or greater than or equal to 0.0 mol % and less than or equal to 5.0 mol %.

In embodiments, the glass compositions of the present disclosure may have a combined amount of sodium oxide and alumina (Na₂O+Al₂O₃) that is greater than or equal to 0.0 mol %, greater than or equal to 5.0 mol %, or greater than or equal to 7.7 mol %. In embodiments, Na₂O+Al₂O₃ is less than or equal to 9.7 mol %, less than or equal to 8.9 mol %, or less than or equal to 5.0 mol %. In embodiments, Na₂O+Al₂O₃ is greater than or equal to 0.0 mol % and less than or equal to 9.7 mol %, greater than or equal to 0.0 mol % and less than or equal to 8.9 mol %, or greater than or equal to 0.0 mol % and less than or equal to 5.0 mol %, greater than or equal to 5.0 mol % and less than or equal to 9.7 mol %, or greater than or equal to 5.0 mol % and less than or equal to 8.9 mol %, greater than or equal to 7.7 mol % and less than or equal to 9.7 mol %.

In embodiments, the glass compositions of the present disclosure may have a combined amount of sodium oxide, potassium oxide, magnesium oxide, calcium oxide, zinc oxide, alumina, boron oxide, and silica (Na₂O+K₂O+MgO+CaO+ZnO+Al₂O₃+B₂O₃+SiO₂) that is greater than or equal to 95.0 mol %.

In embodiments, the glass compositions of the present disclosure may have a value for a ratio (Na₂O+K₂O+MgO+CaO+SrO+BaO+ZnO)/(R₂O+RO) that is greater than or equal to 0.000, or greater than or equal to 0.95. The oxides of sodium and potassium, as well as alkaline earth metal oxides and zinc oxide, are the most common options for the modifiers (R₂O and RO), as they may not reduce the light transmittance of the resultant glass articles and are well soluble in glass melts of the present disclosure. Other monovalent and divalent metal oxides, such as, for example, MnO, NiO, CuO, Ag₂O, PbO, etc. may either be less soluble, or provide undesirable coloring, or cause ecology concern, or be more expensive.

In embodiments, the glass compositions of the present disclosure may have a value for a ratio Na₂O/Al₂O₃. In the case when Na₂O is added to a glass composition, it may be desirable to have it connected with the structural units formed by different network formers. When this occurs, the mobility of sodium ions may be decreased, which may cause some improvement of chemical durability of glass. Without wishing to be bound by theory, it is believed that such connections may occur when the content of Na₂O is greater than or equal to the content of Al₂O₃ in a glass composition. Accordingly, in some embodiments of the present disclosure, it may be desirable to have the ratio Na₂O/Al₂O₃ (in mole percent) greater than or equal to about 1.0. On the other hand, when the ratio Na₂O/Al₂O₃ becomes too high, anomalous fracture behavior described herein may be inhibited. Accordingly, in embodiments, Na₂O/Al₂O₃ is greater than or equal to 1.0 mol %, greater than or equal to 1.01 mol %, greater than or equal to 1.1 mol %, or greater than or equal to 1.5 mol %. In embodiments, Na₂O/Al₂O₃ is less than or equal to 1.67 mol %, less than or equal to 1.6 mol %, less than or equal to 1.5 mol %, or less than or equal to 1.35 mol %. In embodiments, Na₂O/Al₂O₃ is greater than or equal to 1.0 mol % and less than or equal to 1.35 mol %, greater than or equal to 1.01 mol % and less than or equal to 1.67 mol %, greater than or equal to 1.0 mol % and less than or equal to 1.67 mol %, greater than or equal to 1.0 mol % and less than or equal to 1.6 mol %, greater than or equal to 1.0 mol % and less than or equal to 1.5 mol %, greater than or equal to 1.01 mol % and less than or equal to 1.6 mol %, greater than or equal to 1.01 mol % and less than or equal to 1.5 mol %, or greater than or equal to 1.01 mol % and less than or equal to 1.35 mol %, greater than or equal to 1.1 mol % and less than or equal to 1.67 mol %, greater than or equal to 1.1 mol % and less than or equal to 1.6 mol %, greater than or equal to 1.1 mol % and less than or equal to 1.5 mol %, or greater than or equal to 1.1 mol % and less than or equal to 1.35 mol %.

In embodiments, the glass compositions of the present disclosure may include a parameter B₂O₃+3.5*Al₂O₃ within certain numerical ranges. It was empirically found that the anomalous fracture behavior described herein is preferably observed when the sum (B₂O₃+3.5*Al₂O₃) is approximately 25 mol %. Accordingly, in embodiments, B₂O₃+3.5*Al₂O₃ is greater than or equal to 20.3 mol %, greater than or equal to 24.2 mol %, or greater than or equal to 25 mol %. In embodiments, B₂O₃+3.5*Al₂O₃ is less than or equal to 27.5 mol %, less than or equal to 25.9 mol %, or less than or equal to 25 mol %. In embodiments, B₂O₃+3.5*Al₂O₃ greater than or equal to 20.3 mol % and less than or equal to 27.5 mol %, greater than or equal to 20.3 mol % and less than or equal to 25.9 mol %, or greater than or equal to 20.3 mol % and less than or equal to 25 mol %, greater than or equal to 24.2 mol % and less than or equal to 27.5 mol %, greater than or equal to 24.2 mol % and less than or equal to 25.9 mol %, or greater than or equal to 24.2 mol % and less than or equal to 25 mol %, greater than or equal to 25 mol % and less than or equal to 27.5 mol %, or greater than or equal to 25 mol % and less than or equal to 25.9 mol %.

In some embodiments, the glass compositions described herein may exhibit a decimal logarithm of liquidus viscosity (Log(eta_{liq}P)) that is greater than or equal to 5.5 to less than or equal to 8.0 and all ranges and sub-ranges between the foregoing values. In embodiments, Log(eta_{liq}P) is greater than or equal to 5.5, greater than or equal to 5.9, greater than or equal to 6.0, greater than or equal to 6.5, greater than or equal to 7.4, greater than or equal to 7.5, greater than or equal to 7.6, or greater than or equal to 7.8. In embodiments, Log(eta_{liq}P) less than or equal to 8.0, less than or equal to 7.8, less than or equal to 7.7, less than or equal to 7.6, less than or equal to 7.5, less than or equal to 7.4, less than or equal to 6.5, or less than or equal to 6.0. In embodiments, Log(eta_{liq}P) is greater than or equal to 5.5 and less than or equal to 8.0, greater than or equal to 5.9 and less than or equal to 7.7, greater than or equal to 5.5 and less than or equal to 6.0, greater than or equal to 5.9 and less than or equal to 6.0, greater than or equal to 6.0 and less than or equal to 8.0, greater than or equal to 6.0 and less than or equal to 6.5, greater than or equal to 7.4 and less than or equal to 8.0, greater than or equal to 7.4 and less than or equal to 7.5.

In embodiments, glass compositions according to the present disclosure may exhibit a modifier excess parameter M_{exc} that is calculated according to the following relation:

$${M}_{exc} = max ( 0 , ( {Al k}_{2} O + R O ) - ( {Al}_{2} {O}_{3} + {B}_{2} {O}_{3} ) ) , \qquad ( Equation 2 )$$

where Alk₂O is total sum of alkali metal oxides, RO is total sum of divalent metal oxides, and chemical formulas mean the amounts of corresponding components in the glass composition. M_{exc} represents the excess of modifiers R₂O and RO over the network former Al₂O₃ and B₂O₃. In the case when the total content of Al₂O₃+B₂O₃ exceeds the total content of R₂O+RO, the modifiers excess parameter is defined to be equal to zero. Without wishing to be bound by theory, it is believed that the value of M_{exc} correlates with the amount of the non-bridging oxygen atoms in the structural network of glass.

In embodiments, glass compositions according to the present disclosure may exhibit a total polyhedral parameter Pₜₒₜₐₗ that is calculated according to the following relation:

$${P}_{total} = {SiO}_{2} + 2 * {Al}_{2} {O}_{3} + 2 * {B}_{2} {O}_{3} , \qquad ( Equation 3 )$$

where chemical formulas mean the amounts of corresponding components in the glass composition. Pₜₒₜₐₗ may represent the total number of network forming cations Si₄⁺, Al₃⁺ and B₃⁺ in terms of gram-atoms per total 100 moles of oxides presented in a glass composition.

In embodiments, glass compositions according to the present disclosure may exhibit a boron excess parameter B_{exc} that is calculated according to the following relation:

$${B}_{exc} = max ( 0 , {B}_{2} {O}_{3} - max ( 0 , {R}_{2} O + R O - {Al}_{2} {O}_{3} ) ) , \qquad ( Equation 4 )$$

where R₂O is total sum of monovalent metal oxides, RO is total sum of divalent metal oxides, and chemical formulas mean the amounts of corresponding components in the glass composition. B_{exc} represents the excess of boron oxide, in terms of mole %, over the content of modifiers R₂O and RO (in mole %) after deduction of the content of alumina (in mole %) in a glass composition. In the case when the content of alumina is greater than or equal to the total content of R₂O and RO, the boron excess parameter is assumed being equal to the content of the boron oxide in the glass composition.

In embodiments, glass compositions according to the present disclosure may exhibit a silica excess parameter S_{exc} that is calculated according to the following relation:

$${Si}_{exc} = {SiO}_{2} - 6 * min ( {Al k}_{2} O , {Al}_{2} {O}_{3} ) - 2 * min ( {Al k}_{2} O + R O - {Al}_{2} {O}_{3} , {B}_{2} {O}_{3} ) , \qquad ( Equation 5 )$$

where Alk₂O is total sum of alkali metal oxides, RO is total sum of divalent metal oxides, and chemical formulas mean the amounts of corresponding components in the glass composition. S_{exc} approximates the content of silica that is assumed not to be connected with the structural polyhedra formed by aluminum and boron cations.

In embodiments, the parameters Pₜₒₜₐₗ, M_{exc}, B_{exc}, and S_{exc} of the glass compositions described herein may satisfy the following relation

$$( abs ( 2 * {M}_{exc} + 2 * min ( {B}_{2} {O}_{3} , {R}_{2} O + R O - {Al}_{2} {O}_{3} ) + 0.65 * {P}_{total} - 80 ) ) - ( 3.4 - 0.5 * ( abs ( {Si}_{exc} - max ( 24 + 2 * {B}_{exc} , 44 ) ) ) ) \leq 0.$$

In embodiments, the parameters Pₜₒₜₐₗ, M_{exc}, B_{exc}, and S_{exc} of the glass compositions described herein may satisfy the following relation

$$( abs ( 2 * {M}_{exc} + 2 * min ( {B}_{2} {O}_{3} , {R}_{2} O + R O - {Al}_{2} {O}_{3} ) + 0.65 * {P}_{total} - 80 ) ) - ( 2.8 - 0.5 * ( abs ( {Si}_{exc} - max ( 24 + 2 * {B}_{exc} , 44 ) ) ) ) \leq 0. .$$

In some embodiments, glasses including the compositions described herein may have a quantity 1-2*(Alk₂O+RO)/Pₜₒₜₐₗ that is greater than or equal to 0.83.

Glasses including the compositions described herein may also include a non-rotatable polyhedra parameter Pₙᵣ that is calculated as

$${P}_{nr} = 2 * max ( 0 , ( {Al k}_{2} O + R O ) - ( {Al}_{2} {O}_{3} + {B}_{2} {O}_{3} ) ) + 2 * min ( {B}_{2} {O}_{3} , {R}_{2} O + R O - {Al}_{2} {O}_{3} ) , \qquad ( Equation 6 )$$

where Alk₂O is total sum of alkali metal oxides, RO is total sum of divalent metal oxides, R₂O is total sum of monovalent metal oxides, and chemical formulas mean the amounts of corresponding components in the glass composition. Without wishing to be bound by theory, it is believed that Pₙᵣ represents an approximate number of network forming cations Si₄⁺, Al₃⁺ and B₃⁺ that cannot be rotated as described above, in terms of gram-atoms of non-rotatable network forming cations per total 100 moles of oxides presented in a glass composition.

Glasses including the compositions described herein may also include a network rotatability ratio Rₙᵣ is a quantity calculated by the following formula:

$${R}_{nr} = 1 - 2 * ( {Al k}_{2} O + R O ) / ( {SiO}_{2} + 2 * {Al}_{2} {O}_{3} + 2 * {B}_{2} {O}_{3} ) , \qquad ( Equation 7 )$$

where Alk₂O is total sum of alkali metal oxides, RO is total sum of divalent metal oxides, and chemical formulas mean the amounts of corresponding components in the glass composition. Applicants believe that Rₙᵣ may relate to fracture behavior of borosilicate glass compositions disclosed herein and characterize aspects of “rotatability” of the respective compositions. For compositions of the form xSiO2·yAl2O3·zB2O3·uR2O·vRO, where x, y, z, u, y can represent mol % or molar fraction of each type of oxide. If (u+v)≥y, Applicants believe the fracture behavior is related to a network rotatability ratio Rₙᵣ as determined by Equation 7. In instances when Rₙᵣ is between about 0.80 and about 0.93, Applicant have found that Vickers indenter tests produce radial and lateral cracks that are contained within a small (<1 mm in diameter) crack loop. A result is that sheets of glasses within this range may not crack to failure during Vickers indenter tests, but instead only form small round cracks that contain other cracks and prevent them from spreading.

In embodiments, glass compositions according to the present disclosure may include a network balance criterion C_{nb} that is calculated as

$${C}_{nb} = abs ( {SiO}_{2} - 6 * min ( {Al k}_{2} O , {Al}_{2} {O}_{3} ) - 2 * min ( {Al k}_{2} O + R O - {Al}_{2} {O}_{3} , {B}_{2} {O}_{3} ) - max ( 24 + 2 * max ( 0 , {B}_{2} {O}_{3} - max ( 0 , {R}_{2} O + R O - {Al}_{2} {O}_{3} ) ) , 44 ) ) , \qquad ( Equation 8 )$$

where Alk₂O is total sum of alkali metal oxides, RO is total sum of divalent metal oxides, R₂O is total sum of monovalent metal oxides, and chemical formulas mean the amounts of corresponding components in the glass composition. C_{nb} represents the relationship between the parameters Si_{exc} and B_{exc} described herein. When values for the Si_{exc} parameter are plotted as a function of the Be parameter for the example compositions described herein, the examples are grouped around the line y=24−x and y=44−3*x, where y corresponds to the parameter Si_{exc} and x corresponds to the parameter B_{exc}. The examples described herein are located around the highest values calculated by these equations, which can be expressed as follows:

$${Si}_{exc} = max ( 24 - {B}_{exc} , 44 - 4 * {B}_{exc} ) , \qquad ( Equation 9 )$$

Without wishing to be bound by theory, it is believed that the difference between Si_{exc} and the expression specified in the right part of Equation 9, max(24−B_{exc}, 44−4*B_{exc}), may characterize the balance between silicon and boron connectivity in the structural network. The absolute value of the said difference, after substituting the expressions for Si_{exc} and B_{exc} finally gives the expression for C_{nb}. In other words, the network balance criterion can be expressed in terms of Si_{exc} and B_{exc} as follows:

$${C}_{nb} = abs ( {Si}_{exc} - max ( 24 - {B}_{exc} , 44 - 4 * {B}_{exc} ) ) . \qquad ( Equation 10 )$$

The example compositions described herein that exhibit anomalous and intermediate fracture behavior are characterized by relatively small values of C_{nb}, such as, for example, less than or equal to 5.0, or less than or equal to 4.5, or less than or equal to 4.0, or less than or equal to 3.5, or less than or equal to 3.0, or less than or equal to 2.5, or even less than or equal to 2.0.

The term “fracture category” refers to the type of fracture behavior observed while performing the Vickers indenter test, being described in terms of three categories: “normal”, “anomalous” and “intermediate”. The said Vickers indenter tests may be used to characterize fracture behavior of glass, as discussed in Gross et al., Crack-resistant glass with high shear band density, Journal of Non-Crystalline Solids, 494 (2018) 13-20; and Gross, Deformation and cracking behavior of glasses indented with diamond tips of various sharpness, Journal of Non-Crystalline Solids, 358 (2012) 3445-3452, both of which are incorporated by reference herein. In some embodiments, when glass having the borosilicate glass composition of the first glass ply is formed as at least ten polished, flat samples (e.g., 100 samples) of 1 mm thickness with a major surface of at least 2×2 cm² area (e.g., 2 cm by 2 cm square), and tested using square-based, 136° four-sided, pyramidal Vickers indenter directed orthogonally into a center of the major surface at 25° C. in 50% relative humidity and the indenter is quasi-statically displaced at rate of 60 μm per second up to maximum 3 kg-force with indentation load held for 10 seconds (unless failure by fracture of the sample occurs first), more often than not (at least 51 times out of 100; at least 6 times out of 10) all cracks extending through the sample radially and/or laterally from beneath the indenter tip (i.e. the location where the indenter tip contacted the glass) are interrupted by a self-terminating crack loop (e.g., ring crack), whereby fracture of the samples from the Vickers indenter is limited to cracking within the loop. In this case, the fracture category is identified as “intermediate”. Essentially the indenter crushes and cracks the glass beneath the indenter. However, the crack loop forms and stops spread of cracking originating from the indenter contact beyond the crack loop. By contrast, lateral or radial cracks may otherwise form prior to and/or pass through such crack loops in other glasses (e.g., anomalous cracking) or crack loops may not form (e.g., normal cracking), and in either case the lateral or radial cracks would not be contained by the crack loop, and may propagate through the full glass article causing overall fracture through the article and failure thereof. This type of fracture behavior is identified as “normal”.

In embodiments, glass compositions according to the present disclosure may include a rotatability balance criterion C_{rb} is a quantity calculated as

$${C}_{rb} = abs ( 2 * max ( 0 , ( {Al k}_{2} O + R O ) - ( {Al}_{2} {O}_{3} + {B}_{2} {O}_{3} ) ) + 2 * min ( {B}_{2} {O}_{3} , {R}_{2} O + R O - {Al}_{2} {O}_{3} ) + 0.65 * ( {SiO}_{2} + 2 * {Al}_{2} {O}_{3} + 2 * {B}_{2} {O}_{3} ) - 80 ) , \qquad ( Equation 11 )$$

where Alk₂O is total sum of alkali metal oxides, RO is total sum of divalent metal oxides, R₂O is total sum of monovalent metal oxides, and chemical formulas mean the amounts of corresponding components in the glass composition. C_{rb} represents the relationship between the quantities Pₜₒₜₐₗ and Pₙᵣ described herein. When values of the Pₙᵣ parameter are plotted as a function of values of the Pₜₒₜₐₗ parameter for the Examples described herein, Pₙᵣ values for the Examples of present disclosure fall around the line y=80−0.65*x, where y corresponds to the parameter Pₙᵣ and x corresponds to the parameter Pₜₒₜₐₗ, which can be mathematically expressed as follows:

$${P}_{nr} = 80 - 0.65 * {P}_{total} , \qquad ( Equation 12 )$$

where Pₜₒₜₐₗ and Pₙᵣ refer to total polyhedra parameter and non-rotatable polyhedra parameter as described herein. Without wishing to be bound be theory, it is believed that the difference between Pₙᵣ and the expression specified in the right part of Equation 12, 80−0.65*Pₜₒₜₐₗ, may characterize the balance between the rotatable and non-rotatable structural polyhedra. The absolute value of the said difference, after substituting the expressions for Pₙᵣ and Pₜₒₜₐₗ, finally gives the expression for C_{nb}. In other words, the network balance criterion can be expressed in terms of Si_{exc} and B_{exc} as follows:

$${C}_{rb} = abs ( {P}_{nr} - ( 80 - 0.65 * {P}_{total} ) . \qquad ( Equation 13 )$$

Density at room temperature (referred to herein using the term “d_{RT}”) is a property of glass that can be predicted from the glass composition. A linear regression analysis of the Examples of the present disclosure as well as certain existing compositions was performed to generate an equation that can be used to predict the compositional dependence of the density for various glass compositions.

To select from among existing glass compositions, the criteria set forth in the Table 600 below were used to search the SciGlass Information System.

TABLE 600

| | |
|---|---|
| Property | d_{RT}, g/cm³ |

| Component limits | Min, mol % | Max, mol % |
|---|---|---|
| SiO₂ | 60 | 80 |
| Na₂O | 1 | 10 |
| Al₂O₃ | 0.3 | 10 |
| K₂O | 0 | 5 |
| Li₂O | 0 | 5 |
| BaO | 0 | 5 |
| Na₂O + K₂O | 5 | Not limited |
| B₂O₃ + 3.5 * Al₂O₃ | 15 | 30 |
| Other species | 0 | Not limited |

About 100 glass compositions were randomly selected from the search results and from the Exemplary Glasses from the embodiments presented herein. The linear regression analysis on the above-specified dataset was used to determine the formulas, with the exclusion of insignificant variables and outliers. The resulting formulas are presented in Table 700 below.

TABLE 700

| | | | | | Compo- | Stan- |
|---|---|---|---|---|---|---|
| | Abbre- | | Predicting | Regression | sition | dard |
| Property | viation | Unit | Parameter | Formula | Unit | error |
| Density at | d_{RT} | g/cm³ | P_{d} | Equation | Mol % | 0.024 |
| room | | | | 14 | | |
| temperature | | | | | | |

Another set of compositions satisfying the criteria in the Table 600 was used as a validation set to evaluate the ability of Equation 14 herein to interpolate within predefined P compositional limits, which corresponds to the standard deviations specified in the Table 700. An external dataset of prior art glass compositions, also randomly selected from the SciGlass Information System database, was used to evaluate the ability to predict the properties outside of the specified compositional limits with a reasonable accuracy. Multiple iterations of this process were performed in order to determine the best variant for each property, corresponding to the above-mentioned regression formulas specified in the Table 700.

The data for the compositions used in the linear regression modeling, including the training dataset, validation dataset and external dataset were obtained from the publically available SciGlass Information System database. Equation 14 below was obtained from the linear regression analysis and used to predict the density of the glasses:

$${P}_{d} = 2.487 - 0.0068998 * {B}_{2} {O}_{3} + 0.041371 * BaO + 0.13897 * {Bi}_{2} {O}_{3} + 0.011637 * CaO + 0.055366 * {Cs}_{2} O + 0.02542 * {Fe}_{2} {O}_{3} + 0.10294 * {Gd}_{2} {O}_{3} + 0.0051134 * {K}_{2} O + 0.079903 * {La}_{2} {O}_{3} + 0.0041594 * {Li}_{2} O + 0.0084582 * MgO + 0.01972 * MnO + 0.0064419 * {Na}_{2} O + 0.018282 * NiO + 0.065781 * PbO - 0.002953 * {SiO}_{2} + 0.027682 * SrO + 0.0055367 * {TiO}_{2} + 0.0068497 * {V}_{2} {O}_{5} + 0.048699 * {Y}_{2} {O}_{3} + 0.021527 * ZnO + 0.026527 * {ZrO}_{2} + 0.011033 * ( min ( {B}_{2} {O}_{3} , max ( 0 , {Al k}_{2} O + R O - {Al}_{2} {O}_{3} ) ) ) . \qquad ( Equation 14 )$$

In Equation 14, the density parameter P_{d} is a parameter that predicts the density at room temperature [g/cm³], calculated from the components of the glass composition expressed in mol %. In Equation 14, each component of the glass composition is listed in terms of its chemical formula, where the chemical formula refers to the concentration of the component expressed in mol %. For example, for purposes of Equation 14, B₂O₃ refers to the concentration of B₂O₃, expressed in mol %, in the glass composition. It is understood that not all components listed in Equation 14 are necessarily present in a particular glass composition and that Equation 14 are equally valid for glass compositions that contain less than all of the components listed in the formulas. It is further understood that Equation 14 are also valid for glass compositions within the scope and claims of the present disclosure that contain components in addition to the components listed in the formulas. If a component listed in Equation 14 is absent in a particular glass composition, the concentration of the component in the glass composition is 0 mol % and the contribution of the component to the value calculated from the formulas is zero. Equation 14 was used to generate predicted values for the density of the Examples described herein as well as glasses found in the prior art. The predicted values were plotted as a function of the measured densities at room temperature d_{RT}. Equation 14 was found to accurately predict the actual measured density, within an error of +/−0.024 g/cm³.

Applicant has found that, for certain glass compositions according to the Examples contained herein, the density parameter P_{d}, representing a predicted value of the density from the compositional components of each composition, satisfies a relation as a function of the ratio Na₂O/Al₂O₃. A first set of the Examples described herein were selected as satisfying the following criteria listed in the Table 800 below. In the Table 800, “Not limited” refers to a limitation that was not considered when selecting the compositions.

TABLE 800

| Quantity | Unit | Min | Max |
|---|---|---|---|
| SiO₂ | mol % | 60 | 77.5 |
| B₂O₃ | mol % | 5 | 17 |
| Na₂O | mol % | 2.5 | 5.3 |
| Al₂O₃ | mol % | 0.3 | 5.3 |
| K₂O | mol % | 0 | 3 |
| Li₂O | mol % | 0 | 0.2 |
| BaO | mol % | 0 | 0.2 |
| Na₂O + K₂O | mol % | 5 | Not limited |
| B₂O₃ + 3.5 * Al₂O₃ | mol % | 20.3 | 27.5 |

For the first set of examples, the density parameter P_{d} value was plotted as a function of the value of Na₂O/Al₂O₃ for each composition. It was found that the first set of examples satisfied the following relation:

$${P}_{d} - ( 2.58 - 0.2 * {Na}_{2} O / {Al}_{2} {O}_{3} ) < 0. . \qquad ( Equation 15 )$$

A subset of the first set of examples was found to satisfy the following relation:

$${P}_{d} - ( 2.54 - 0.2 * {Na}_{2} O / {Al}_{2} {O}_{3} ) < 0. . \qquad ( Equation 16 )$$

Certain existing glass compositions do not satisfy the relation defined by Equation 15 (and therefore also do not satisfy the relation defined by Equation 16). That is, the glass compositions according to the Examples described herein exhibit lower density parameter values (and lower measured d_{RT} values) than certain existing glass compositions having comparable Na₂O/Al₂O₃ ratios. As described herein, such lower densities may facilitate the glasses according to the present disclosure exhibiting the unique fracture behaviors described herein.

A second set of the Examples described herein were selected as satisfying the following criteria listed in the Table 900 below.

TABLE 900

| Composition | Amount (mol %) | |
|---|---|---|
| SiO₂ | 60.0 to 96.0 | mol % |
| B₂O₃ | 1.0 to 25.0 | mol % |
| Al₂O₃ | ≥0.3 | mol % |
| Sum of (Na₂O + Al₂O₃) | ≥9.7 | mol % |

In embodiments, the second set of Examples may also satisfy each of the following conditions: 1.01≤Na₂O/Al₂O₃ [mol %]≤1.67. B₂O₃+3.5*Al₂O₃ [mol %]≤27.5, C_{rb}−(3.4−0.5*C_{rb})<0.000, where C_{rb} is a rotatability balance criterion defined herein, and C_{rb} is a network balance criterion defined herein, or C_{rb}−(2.8−0.5*C_{nb})<0.000, and 1−2*(Alk₂O+RO)/Pₜₒₜₐₗ>0.83, where Pₜₒₜₐₗ is a total polyhedra parameter. It was found that certain existing compositions failed to satisfy the above conditions.

A third set of the Examples described herein were selected as satisfying the following criteria listed in the Table 1000 below.

TABLE 1000

| Composition | Amount (mol %) | |
|---|---|---|
| SiO₂ | 60.0 to 77.5 | mol % |
| B₂O₃ | 5.0 to 17.0 | mol % |
| Na₂O | 2.5 to 5.3 | mol % |
| Al₂O₃ | 0.3 to 5.3 | mol % |

The third set of Examples was found satisfy each of the following conditions: 20.3≤B₂O₃+3.5*Al₂O₃[mol %]≤27.5, d_{RT}−(2.58−0.2*(Na₂O/Al₂O₃))<0.00, d_{RT} is a density at room temperature, or, in some cases, d_{RT}−(2.54−0.2*(Na₂O/Al₂O₃))<0.000. It was found that certain existing compositions failed to satisfy the above conditions.

A fourth set of the Examples described herein were selected as satisfying the following criteria listed in the Table 1100 below.

TABLE 1100

| Quantity | Unit | Min | Max |
|---|---|---|---|
| SiO₂ | mol % | 60 | 80 |
| Al₂O₃ | mol % | 0.3 | Not limited |
| Li₂O | mol % | 0 | 0.3 |
| Na₂O + Al₂O₃ | mol % | Not limited | 9.7 |
| BaO | mol % | 0 | 0.1 |
| F | at % | 0 | 0.05 |
| REₘOₙ | mol % | 0 | 0.1 |
| Na₂O/Al₂O₃ | mol % | 1.01 | 1.67 |
| B₂O₃ + 3.5 * Al₂O₃ | mol % | Not limited | 27.5 |
| 1 − 2 * (Alk₂O + RO)/Pₜₒₜₐₗ | | 0.83 | Not limited |

For each of the Examples in the fourth set, the C_{nb} parameter was computed and plotted as a function of the C_{nb} parameter. It was determined that the C_{rb} and C_{nb} parameters for each of the Examples in the fourth set satisfy the relationship

$${C}_{rb} - ( 3.4 - 0.5 * {C}_{nb} ) < 0. . \qquad ( Equation 17 )$$

The glasses according to the present disclosure were found to be distinguished from certain existing compositions in that Equation 17 is satisfied.

For a subset of the Examples in the fourth set, values for the C_{rb} and C_{nb} parameters were found to also satisfy the relationship

$${C}_{rb} - ( 2.8 - 0.5 * {C}_{nb} ) < 0. . \qquad ( Equation 16 )$$

Such glasses were found to be further distinguished from certain existing compositions in that Equation 16 is satisfied.

Embodiments of the present disclosure may be further understood in view of the following aspects.

A first aspect of the present disclosure includes a borosilicate glass composition, comprising: at least 74 mol % SiO₂; at least 10 mol % B₂O₃; and Al₂O₃ in an amount such that sum of SiO₂, B₂O₃, and Al₂O₃ is at least 90 mol %; wherein the borosilicate glass composition comprises a liquidus viscosity of greater than 500 kP; and wherein the borosilicate glass composition comprises a temperature at which a viscosity of the borosilicate glass composition is 200 P of 1725° C. or less.

A second aspect of the present disclosure includes the borosilicate glass according to the first aspect, further comprising about 2 mol % to about 8 mol % Na₂O.

A third aspect of the present disclosure includes the borosilicate glass according to any of the first aspect through the second aspect, further comprising about 0.8 mol % to about 4 mol % K₂O.

A fourth aspect of the present disclosure includes the borosilicate glass according to any of the first aspect through the third aspect, wherein a total amount of Na₂O and K₂O is at least 4 mol %.

A fifth aspect of the present disclosure includes the borosilicate glass according to any of the first aspect through the fourth aspect, wherein a total amount of MgO and CaO is at most 5 mol %.

A sixth aspect of the present disclosure includes the borosilicate glass according to any of the first aspect through the fifth aspect, further comprising P₂O₅, wherein P₂O₅ is present in an amount up to 4 mol %.

A seventh aspect of the present disclosure includes the borosilicate glass according to any of the first aspect through the sixth aspect, further comprising about 0.05 mol % to about 0.25 mol % of SnO₂.

An eighth aspect of the present disclosure includes the borosilicate glass according to any of the first aspect through the seventh aspect, further comprising 0.05 mol % to 0.50 mol % of an iron compound.

A ninth aspect of the present disclosure includes the borosilicate glass according to any of the first aspect through the eighth aspect, wherein total solar transmittance as measured according to ISO 13837A is 90% or less.

A tenth aspect of the present disclosure includes the borosilicate glass according to any of the first aspect through the ninth aspect, wherein visible transmission as measured according to ISO 13837A is at least 73%.

An eleventh aspect of the present disclosure includes the borosilicate glass according to any of the first aspect through the tenth aspect, comprising a coefficient of thermal expansion of 5.6 ppm/° C. or less as measured over a temperature range of 0° C. to 300° C.

A twelfth aspect of the present disclosure includes the borosilicate glass according to any of the first aspect through the eleventh aspect, comprising a density of less than 2.4 g/cm³.

A thirteenth aspect of the present disclosure includes the borosilicate glass according to any of the first aspect through the twelfth aspect, comprising a strain point of about 480° C. to about 560° C.

A fourteenth aspect of the present disclosure includes the borosilicate glass according to any of the first aspect through the thirteenth aspect, comprising an anneal point of about 520° C. to about 590° C.

A fifteenth aspect of the present disclosure includes the borosilicate glass according to any of the first aspect through the fourteenth aspect, wherein the glass ply comprises the borosilicate glass composition according to any of the preceding claims.

A sixteenth aspect of the present disclosure includes the borosilicate glass according to any of the first aspect through the fifteenth aspect, wherein, when subjected to a quasi-static 2 kgf indentation load with a Vickers tip, the glass ply exhibits a ring crack and a plurality of radial cracks and wherein each radial crack of the plurality of radial cracks is bounded by the ring crack.

A seventeenth aspect of the present disclosure includes the borosilicate glass according to any of the first aspect through the sixteenth aspect, wherein the glass ply is formed via fusion draw and wherein a thickness between the first major surface and the second major surface is greater than 2 mm.

An eighteenth aspect of the present disclosure includes the borosilicate glass according to any of the first aspect through the seventeenth aspect, wherein the thickness is at least 3 mm.

A nineteenth aspect of the present disclosure includes a laminate, comprising: a first glass ply according to any of the first aspect through the eighteenth aspect, a second glass ply; and an interlayer bonding the first glass ply to the second glass ply.

A twentieth aspect of the present disclosure includes a laminate according to the nineteenth aspect, wherein the first glass ply is thicker than the second glass ply.

A twenty first aspect of the present disclosure includes a laminate according to any of the nineteenth aspect through the twentieth aspect, wherein the second glass ply is strengthened.

A twenty second aspect of the present disclosure includes a laminate according to any of the nineteenth aspect through the twenty first aspect, wherein the first glass ply and the second glass ply are pair-shaped, wherein the first glass ply comprises a first curvature depth of at least 2 mm, wherein the second glass ply comprises a second curvature depth of at least 2 mm, and wherein the first curvature depth is within 10% of the second curvature depth.

A twenty third aspect of the present disclosure includes a laminate according to any of the nineteenth aspect through the twenty second aspect, wherein the first glass ply is sagged and comprises a curvature depth of at least 2 mm and wherein the second glass ply is cold-formed into conformity with the first glass ply.

A twenty fourth aspect of the present disclosure includes a automotive glazing including the laminate according to any of the nineteenth aspect through the twenty fourth aspect.

A twenty fifth aspect of the present disclosure includes a vehicle, comprising: a body defining an interior of the vehicle and at least one opening: the automotive glazing according to claim 24 disposed in the at least one opening; wherein the second glass ply is arranged facing the interior of the vehicle and the first glass ply faces an exterior of the vehicle.

A twenty sixth aspect of the present disclosure includes a vehicle according to the twenty fifth aspect, wherein the automotive glazing is at least one of a sidelight, a windshield, a rear window, a window, or a sunroof.

A twenty seventh aspect of the present disclosure includes a method of forming a glass ply, the glass ply comprising a first major surface and a second major surface, the method comprising: overflowing a trough in an isopipe with at least two streams of a borosilicate glass composition comprising a liquidus viscosity of greater than 500 kP and a temperature at which a viscosity of the borosilicate glass composition is 200 P of 1725° C. or less, wherein the borosilicate glass composition comprises at least 74 mol % SiO₂ and at least 10 mol % of B₂O₃ and wherein a combined amount of SiO₂, B₂O₃, and Al₂O₃ is at least 90 mol %; fusing the at least two streams of the borosilicate glass composition at a root of the isopipe to form the glass ply having a thickness of at least 2 mm between the first major surface and the second major surface.

A twenty eighth aspect of the present disclosure includes the method according to the twenty seventh aspect, wherein the glass ply comprises a coefficient of thermal expansion of 5.6 ppm/° C. or less as measured over a temperature range of 0° C. to 300° C.

A twenty ninth aspect of the present disclosure includes the method according to any of the twenty seventh to the twenty eighth aspects, wherein the glass ply comprises a density of less than 2.4 g/cm³.

A thirtieth aspect of the present disclosure includes the method according to any of the twenty seventh to the twenty ninth aspects, wherein the borosilicate glass composition further comprises from about 2 mol % to about 8 mol % Na₂O.

A thirty first aspect of the present disclosure includes the method according to any of the twenty seventh to the thirtieth aspects, wherein the borosilicate glass composition further comprises from about 0.8 mol % to about 4 mol % K₂O.

A thirty second aspect of the present disclosure includes the method according to any of the twenty seventh to the thirtieth aspects, wherein a total amount of Na₂O and K₂O is at least 4 mol %.

A thirty third aspect of the present disclosure includes the method according to any of the twenty seventh to the twenty second aspects, wherein the borosilicate glass composition further comprises at least one of MgO or CaO, wherein a total amount of MgO and CaO is at most 5 mol %.

A thirty fourth aspect of the present disclosure includes the method according to any of the twenty seventh to the thirty third aspects, wherein the borosilicate glass composition further comprises about 0.05 mol % to about 0.25 mol % of SnO₂.

A thirty fifth aspect of the present disclosure includes the method according to any of the twenty seventh to the thirty fourth aspects, wherein the borosilicate glass composition further comprises 0.05 mol % to 0.50 mol % of an iron compound.

A thirty sixth aspect of the present disclosure includes the method according to any of the twenty seventh to the thirty fifth aspects, further comprising P₂O₅, wherein P₂O₅ is present in an amount up to 4 mol %.

A thirty seventh aspect of the present disclosure includes a glass ply, comprising: a first major surface and a second major surface opposite to the first major surface, wherein the glass ply comprises a borosilicate glass composition; and wherein, when subjected to a quasi-static 2 kgf indentation load with a Vickers tip, the glass ply exhibits a ring crack and a plurality of radial cracks and wherein each radial crack of the plurality of radial cracks is bounded by the ring crack.

A thirty eighth aspect of the present disclosure includes a glass ply according to the thirty seventh aspect, wherein the borosilicate glass composition comprises: at least 74 mol % SiO₂; at least 10 mol % B₂O₃; and Al₂O₃ in an amount such that sum of SiO₂, B₂O₃, and Al₂O₃ is at least 90 mol %.

A thirty ninth aspect of the present disclosure includes a glass ply according to the thirty eighth aspect, wherein the borosilicate glass composition comprises a liquidus viscosity of greater than 500 kP.

A fortieth aspect of the present disclosure includes a glass ply according to any of the thirty eighth through the thirty ninth aspects, wherein the borosilicate glass composition comprises a temperature at which a viscosity of the borosilicate glass composition is 200 P of 1725° C. or less.

A forty first aspect of the present disclosure includes a glass ply according to any of the thirty eighth through the forty first aspects, wherein the borosilicate glass composition comprises about 2 mol % to about 8 mol % Na₂O.

A forty second aspect of the present disclosure includes a glass ply according to any of the thirty eighth through the fortieth aspects, wherein the borosilicate glass composition comprises about 0.8 mol % to about 4 mol % K₂O.

A forty third aspect of the present disclosure includes a glass ply according to any of the thirty eighth through the forty second aspects, wherein the borosilicate composition comprises a total amount of Na₂O and K₂O that is at least 4 mol %.

A forty fourth aspect of the present disclosure includes a glass ply according to any of the thirty eighth through the forty third aspects, wherein the borosilicate glass composition comprises at least one of MgO or CaO, wherein a total amount of MgO and CaO is at most 5 mol %.

A forty fifth aspect of the present disclosure includes a glass ply according to any of the thirty eighth through the forty fourth aspects, wherein the borosilicate glass composition comprises P₂O₅ in an amount up to 4 mol %.

A forty sixth aspect of the present disclosure includes a glass ply according to any of the thirty eighth through the forty fifth aspects, wherein the borosilicate glass composition comprises about 0.05 mol % to about 0.25 mol % of SnO₂.

A forty seventh aspect of the present disclosure includes a glass ply according to any of the thirty eighth through the forty sixth aspects, wherein the borosilicate glass composition comprises 0.05 mol % to 0.50 mol % of an iron compound.

A forty eighth aspect of the present disclosure includes a glass ply according to any of the thirty eighth through the forty seventh aspects, wherein total solar transmittance through the glass ply as measured according to ISO 13837A is 90% or less.

A forty ninth aspect of the present disclosure includes a glass ply according to any of the thirty eighth through the forty eighth aspects, wherein visible transmission through the glass ply as measured according to ISO 13837A is at least 73%.

A fiftieth aspect of the present disclosure includes a glass ply according to any of the thirty eighth through the forty ninth aspects, wherein the first major surface exhibits an optical distortion of at most 200 millidiopters, as measured by an optical distortion detector using transmission optics according to ASTM 1561.

A fifty first aspect of the present disclosure includes a glass laminate, comprising: a first glass ply comprising a first major surface and a second major surface opposite to the first major surface, wherein the first glass ply comprises a borosilicate glass composition; a second glass ply comprising a third major surface and a fourth major surface opposite to the third major surface; and an interlayer bonding the second major surface of the first glass ply to the third major surface of the second glass ply; wherein the borosilicate glass composition comprises: at least 74 mol % SiO₂; at least 10 mol % B₂O₃; and Al₂O₃ in an amount such that sum of SiO₂, B₂O₃, and Al₂O₃ is at least 90 mol %.

A fifty second aspect of the present disclosure includes a glass laminate according to the fifty second aspect, wherein the first glass ply is thicker than the second glass ply.

A fifty third aspect of the present disclosure includes a glass laminate according to any of fifty first through the fifty second aspects, wherein the second glass ply is strengthened.

A fifty fourth aspect of the present disclosure includes a glass laminate according to any of fifty first through the fifty third aspects, wherein the second glass ply is chemically strengthened through an ion-exchange treatment.

A fifty fifth aspect of the present disclosure includes a glass laminate according to any of fifty first through the fifty fourth aspects, wherein the glass laminate is configured for use in a vehicle having a body defining an interior and an opening, wherein the glass laminate is configured to be positioned in the opening, and wherein the first glass ply is arranged facing an exterior of the vehicle and the second glass ply is arranged facing the interior of the vehicle.

A fifty sixth aspect of the present disclosure includes a glass laminate according to any of fifty first through the fifty fifth aspects, wherein the first glass ply has a first thickness between the first major surface and the second major surface of at least 2 mm and wherein the second glass ply has a second thickness between the third major surface and the fourth major surface of less than 2 mm.

A fifty seventh aspect of the present disclosure includes a glass laminate according to any of fifty first through the fifty sixth aspects, wherein the glass laminate comprises a total glass thickness equal to a sum of the first thickness and the second thickness and wherein a ratio of the first glass thickness to the total glass thickness is at least 0.7.

A fifty-eighth aspect of the present disclosure includes a glass laminate according to any of fifty first through the fifty seventh aspects, wherein the first glass thickness is at least 3 mm and the second glass thickness is 1.1 mm or less.

A fifty ninth aspect of the present disclosure includes a glass laminate according to any of fifty first through the fifty eighth aspects, wherein the first glass thickness is at least 3.3, mm and the second glass thickness is 0.7 mm or less.

A sixtieth aspect of the present disclosure includes a glass laminate according to any of fifty first through the fifty ninth aspects, wherein the second glass ply comprises a second glass composition.

A sixty first aspect of the present disclosure includes a glass laminate according to any of fifty first through the sixtieth aspects, wherein the second glass composition is different from the borosilicate glass composition.

A sixty second aspect of the present disclosure includes a glass laminate according to any of fifty first through the sixty first aspects, wherein the second glass composition is selected from the group consisting of a soda lime silicate glass composition, an aluminosilicate glass composition, an alkali aluminosilicate glass composition, an alkali containing borosilicate glass composition, an alkali aluminophosphosilicate glass composition, an alkali aluminoborosilicate glass composition, and combinations thereof.

A sixty third aspect of the present disclosure includes a glass laminate according to any of fifty first through the sixty second aspects, wherein visible transmission through the glass laminate as measured according to ISO 13837A is at least 73%.

A sixty fourth aspect of the present disclosure includes a glass laminate according to any of fifty first through the sixty second aspects, wherein total solar transmittance through the glass laminate as measured according to ISO 13837A is 90% or less.

A sixty fifth aspect of the present disclosure includes a glass laminate according to any of fifty first through the sixty fourth aspects, wherein the first major surface, the fourth major surface, or both the first major surface and the fourth major surface exhibit an optical distortion of at most 200 millidiopters, as measured by an optical distortion detector using transmission optics according to ASTM 1561.

A sixty sixth aspect of the present disclosure includes a glass laminate according to any of fifty first through the sixty fifth aspects, wherein the interlayer is selected from the group consisting of a polyvinyl butyral (PVB), an acoustic PVB (APVB), an ionomer, an ethylene-vinyl acetate (EVA), a thermoplastic polyurethane (TPU), a polyester (PE), a polyethylene terephthalate (PET), and combinations thereof.

A sixty seventh aspect of the present disclosure includes a glass laminate according to any of fifty first through the sixty second aspects, wherein the interlayer comprises a thickness in a range from about 0.5 mm to about 2.5 mm.

A sixty eighth aspect of the present disclosure includes a glass laminate according to any of fifty first through the sixty seventh aspects, wherein the interlayer comprises at least one functional layer or film.

A sixty ninth aspect of the present disclosure includes a glass laminate according to any of fifty first through the sixty eighth aspects, wherein the functional layer or film provides a function selected from the group consisting of ultraviolet absorption, infrared absorption, infrared reflection, acoustic dampening, tint, an antenna, adhesion promotion, an anti-glare treatment, an anti-reflective treatment, and combinations thereof.

A seventieth aspect of the present disclosure includes a glass laminate according to any of fifty first through the sixty ninth aspects, wherein the first glass ply and the second glass ply are pair-shaped, wherein the first glass ply comprises a first curvature depth of at least 2 mm, wherein the second glass ply comprises a second curvature depth of at least 2 mm, and wherein the first curvature depth is within 10% of the second curvature depth.

A seventy first aspect of the present disclosure includes a glass laminate according to any of fifty first through the seventieth aspects, wherein the first glass ply is sagged and comprises a curvature depth of at least 2 mm and wherein the second glass ply is cold-formed into conformity with the first glass ply.

A seventy second aspect of the present disclosure includes a system, comprising: a sensor, and a glass laminate, comprising: a first glass ply comprising a first major surface and a second major surface opposite to the first major surface, wherein the first glass ply comprises a borosilicate glass composition; a second glass ply comprising a third major surface and a fourth major surface opposite to the third major surface; and an interlayer bonding the second major surface of the first glass ply to the third major surface of the second glass ply; wherein the borosilicate glass composition comprises at least 74 mol % SiO₂, at least 10 mol % B₂O₃, and Al₂O₃ in an amount such that sum of SiO₂, B₂O₃, and Al₂O₃ is at least 90 mol %; wherein the sensor is configured to receive, transmit, or both receive and transmit signals through the glass laminate; wherein the signals comprise a peak wavelength in a range of 400 nm to 750 nm or a range of 1500 nm or greater.

A seventy third aspect of the present disclosure includes a system according to the seventy second aspect, wherein the sensor is a LIDAR.

A seventy fourth aspect of the present disclosure includes a system according to any of the seventy second through the seventy third aspects, wherein the glass laminate is a glazing for a vehicle.

A seventy fifth aspect of the present disclosure includes a system according to any of the seventy second through the seventy fourth aspects, wherein visible transmission through the glass laminate as measured according to ISO 13837A is at least 73%.

A seventy sixth aspect of the present disclosure includes a system according to any of the seventy second through the seventy fifth aspects, wherein total solar transmittance through the glass laminate as measured according to ISO 13837A is 90% or less.

A seventy seventh aspect of the present disclosure includes a system according to any of the seventy second through the seventy sixth aspect, wherein the first major surface, the fourth major surface, or both the first major surface and the fourth major surface exhibit an optical distortion of at most 200 millidiopters, as measured by an optical distortion detector using transmission optics according to ASTM 1561.

A seventy eighth aspect of the present disclosure includes a system according to any of the seventy second through the seventy seventh aspects, wherein the first glass ply is thicker than the second glass ply.

A seventy ninth aspect of the present disclosure includes a system according to any of the seventy second through the seventy eighth aspects, wherein the second glass ply is strengthened.

An eightieth aspect of the present disclosure includes a system according to any of the seventy second through the seventy ninth aspects, wherein the second glass ply is chemically strengthened through an ion-exchange treatment.

An eighty first aspect of the present disclosure includes a glass laminate, comprising: a first glass ply comprising a first major surface and a second major surface opposite to the first major surface, wherein the first glass ply comprises a fusion-formed borosilicate glass composition; a second glass ply comprising a third major surface and a fourth major surface opposite to the third major surface; and an interlayer bonding the second major surface of the first glass ply to the third major surface of the second glass ply; wherein transmission of ultraviolet light having a wavelength in a range of 300-380 nm through the glass laminate is 75% or less; wherein transmission of light in the visible spectrum through the glass laminate is 73% or more; and wherein total solar transmission through the glass laminate is 61% or less.

An eighty second aspect of the present disclosure includes a glass laminate according to the eighty first aspect, wherein the borosilicate glass composition comprises at least 74 mol % SiO₂, at least 10 mol % B₂O₃, and Al₂O₃ in an amount such that sum of SiO₂, B₂O₃, and Al₂O₃ is at least 90 mol %.

An eighty third aspect of the present disclosure includes a glass laminate according to any of the eighty first through the eighty second aspects, wherein the first glass ply is thicker than the second glass ply.

An eighty fourth aspect of the present disclosure includes a glass laminate according to any of the eighty first through the eighty third aspects, wherein the second glass ply is strengthened.

An eighty fifth aspect of the present disclosure includes a glass laminate according to any of the eighty first through the eighty fourth aspects, wherein the second glass ply is chemically strengthened through an ion-exchange treatment.

An eighty sixth aspect of the present disclosure includes a glass laminate according to any of the eighty first through the eighty fifth aspects, wherein the second glass ply comprises an ion-exchangeable frit applied to the third major surface, the fourth major surface, or both the third major surface and the fourth major surface.

An eighty seventh aspect of the present disclosure includes a glass laminate according to any of the eighty first through the eighty sixth aspects, wherein the first glass ply has a first thickness between the first major surface and the second major surface of at least 2 mm and wherein the second glass ply has a second thickness between the third major surface and the fourth major surface of less than 2 mm.

An eighty eighth aspect of the present disclosure includes a glass laminate according to any of the eighty first through the eighty seventh aspects, wherein the glass laminate comprises a total glass thickness equal to a sum of the first thickness and the second thickness and wherein a ratio of the first glass thickness to the total glass thickness is at least 0.7.

An eighty ninth aspect of the present disclosure includes a glass laminate according to any of the eighty first through the eighty eighth aspects, wherein the first glass thickness is at least 3 mm and the second glass thickness is 1.1 mm or less.

A ninetieth aspect of the present disclosure includes a glass laminate according to any of the eighty first through the eighty ninth aspects, wherein the first glass thickness is at least 3.3, mm and the second glass thickness is 0.7 mm or less.

A ninety first aspect of the present disclosure includes a glass laminate according to any of the eighty first through the ninetieth aspects, wherein the second glass ply comprises a second glass composition.

A ninety second aspect of the present disclosure includes a glass laminate according to any of the eighty first through the ninety first aspects, wherein the second glass composition is different from the borosilicate glass composition.

A ninety third aspect of the present disclosure includes a glass laminate according to any of the eighty first through the ninety second aspects, wherein the second glass composition is selected from the group consisting of an aluminosilicate glass composition, an alkali aluminosilicate glass composition, an alkali containing borosilicate glass composition, an alkali aluminophosphosilicate glass composition, an alkali aluminoborosilicate glass composition, and combinations thereof.

A ninety fourth aspect of the present disclosure includes a glass laminate according to any of the eighty first through the ninety third aspects, wherein the interlayer is selected from the group consisting of a polyvinyl butyral (PVB), an acoustic PVB (APVB), an ionomer, an ethylene-vinyl acetate (EVA), a thermoplastic polyurethane (TPU), a polyester (PE), a polyethylene terephthalate (PET), and combinations thereof.

A ninety fifth aspect of the present disclosure includes a glass laminate according to any of the eighty first through the ninety third aspects, wherein the interlayer comprises a thickness in a range from about 0.5 mm to about 2.5 mm.

A ninety sixth aspect of the present disclosure includes a glass laminate according to any of the eighty first through the ninety fifth aspects, wherein the interlayer comprises at least one functional layer or film.

A ninety seventh aspect of the present disclosure includes a glass laminate according to any of the eighty first through the ninety sixth aspects, wherein the functional layer or film provides a function selected from the group consisting of ultraviolet absorption, infrared absorption, infrared reflection, acoustic dampening, tint, an antenna, adhesion promotion, an anti-glare treatment, an anti-reflective treatment, and combinations thereof.

A ninety eighth aspect of the present disclosure includes a glass laminate according to any of the eighty first through the ninety seventh aspects, wherein the first glass ply and the second glass ply are pair-shaped, wherein the first glass ply comprises a first curvature depth of at least 2 mm, wherein the second glass ply comprises a second curvature depth of at least 2 mm, and wherein the first curvature depth is within 10% of the second curvature depth.

A ninety ninth aspect of the present disclosure includes a glass laminate according to any of the eighty first through the ninety eighth aspects, wherein the first glass ply comprises a first temperature at which a viscosity of the first glass ply is 10¹¹ Poise, the second glass ply comprises a second temperature at which a viscosity of the second glass ply is 10¹ Poise, and the first temperature is different from the second temperature.

A hundredth aspect of the present disclosure includes a glass laminate according to any of the eighty first through the ninety ninth aspects, wherein the first glass ply is thicker than the second glass ply and wherein the second temperature is greater than the first temperature.

A hundred first aspect of the present disclosure includes a glass laminate according to any of the eighty first through hundredth aspects, wherein the first glass ply is sagged and comprises a curvature depth of at least 2 mm and wherein the second glass ply is cold-formed into conformity with the first glass ply.

A hundred second aspect of the present disclosure includes a glass laminate according to any of the eighty first through hundred first aspects, wherein the second glass ply comprises a pigment coating on the third major surface.

A hundred third aspect of the present disclosure includes a glass laminate according to any of the eighty first through hundred second aspects, wherein the first glass ply or the second glass ply comprises a coating.

A hundred fourth aspect of the present disclosure includes a glass laminate according to any of the eighty first through hundred third aspects, wherein the coating comprises an infrared-reflective coating having at least one layer of a metal and optionally at least layer of a dielectric.

A hundred fifth aspect of the present disclosure includes a glass composition, comprising: SiO₂ in an amount in a range from about 72 mol % to about 80 mol %; Al₂O₃ in an amount in a range from about 2.5 mol % to about 5 mol %, and B₂O₃ in an amount in a range from about 11.5 mol % to about 14.5 mol %; wherein the glass composition comprises a liquidus viscosity of greater than 500 kP; and wherein the glass composition comprises a temperature at which a viscosity of the borosilicate glass composition is 200 P of 1725° C. or less.

A hundred sixth aspect of the present disclosure includes the glass composition according to the hundred fifth aspect, further comprising Na₂O in an amount in a range from about 4 mol % to about 8 mol %.

A hundred seventh aspect of the present disclosure includes the glass composition according to any of the hundred fifth through hundred sixth aspects, wherein the amount of Na₂O is in the range from about 4.5 mol % to about 8 mol %.

A hundred eighth aspect of the present disclosure includes the glass composition according to any of the hundred fifth through hundred seventh aspects, further comprising K₂O in an amount in a range from about 0.5 mol % to about 3 mol %.

A hundred ninth aspect of the present disclosure includes the glass composition according to any of the hundred fifth through hundred eighth aspects, further comprising MgO in an amount in a range from about 0.5 to about 2.5 mol %.

A hundred tenth aspect of the present disclosure includes the glass composition according to any of the hundred fifth through the hundred ninth aspects, further comprising up to about 4 mol % CaO.

A hundred eleventh aspect of the present disclosure includes the glass composition according to any of the hundred fifth through the hundred tenth aspects, wherein the amount of SiO₂ is at least 74 mol %.

A hundred twelfth aspect of the present disclosure includes a glass composition comprising: 74 mol % to 80 mol % of SiO₂; 2.5 mol % to 5 mol % of Al₂O₃; 11.5 mol % to 14.5 mol % B₂O₃; 4.5 mol % to 8 mol % Na₂O; 0.5 mol % to 3 mol % K₂O; 0.5 mol % to 2.5 mol % MgO; and 0 mol % to 4 mol % CaO.

A hundred thirteenth aspect of the present disclosure includes a glass composition according to the hundred twelfth aspect, wherein a combined amount of Na₂O and K₂O is at least 5.5 mol %.

A hundred fourteenth aspect of the present disclosure includes a glass composition according to any of the hundred twelfth through the hundred thirteenth aspects, wherein a combined amount of MaO and CaO is at least 1.5 mol %.

A hundred fifteenth aspect of the present disclosure includes a glass composition according to any of the hundred twelfth through the hundred fourteenth aspects, wherein a combined amount of Na₂O, K₂O, MaO, and CaO is at least 7 mol %.

A hundred sixteenth aspect of the present disclosure includes a glass composition according to any of the hundred twelfth through the hundred fourteenth aspects, wherein a combined amount of Na₂O and K₂O is at least 8 mol %.

A hundred seventeenth aspect of the present disclosure includes a glass composition according to any of the hundred twelfth through the hundred sixteenth aspects, comprising a total amount of Fe₂O₃ and FeO of 0.03 mol % to 0.5 mol %.

A hundred eighteenth aspect of the present disclosure includes an article comprising: a first glass ply comprising a first major surface and a second major surface opposite to the first major surface, wherein the first glass ply comprises a borosilicate glass composition; a second glass ply comprising a third major surface and a fourth major surface opposite to the third major surface; and an interlayer bonding the second major surface of the first glass ply to the third major surface of the second glass ply; wherein: (A) the borosilicate glass composition of the first glass ply comprises: (i) SiO₂, B₂O₃, and, optionally, Al₂O₃ and/or P₂O₃; and (ii) one or more alkali metal oxides and, optionally, one or more alkaline earth metal oxides and/or ZnO; wherein the concentrations in mole percent on an oxide basis of SiO₂, B₂O₃, the one or more alkali metal oxides, and, when included in the composition, Al₂O₃, P₂O₅, and the one or more alkaline earth metal oxides and/or ZnO satisfy the relationships: SiO₂≥72; B₂O₃≥10; (R₂O+R′O+P₂O₅)≥Al₂O₃; and 0.80≤(1−[(2R₂O+2R′O+2P₂O₅)/(SiO₂+2Al₂O₃+2B₂O₃)])≤0.93; where R₂O is the sum of the concentrations of the one or more alkali metal oxides and, when included in the borosilicate glass composition. R′O is the sum of the concentrations of the one or more alkaline earth metal oxides and/or ZnO; (B) when glass having the borosilicate glass composition of the first glass ply is Vickers indent tested using a quasi-static 2 kg-force indentation load and a 136° Vickers indenter, the glass exhibits a plurality of radial cracks and a ring crack which limits spread of the radial cracks, and (C) when the article is installed in a vehicle, the first glass ply is outboard of the second glass ply.

A hundred nineteenth aspect of the present disclosure includes an article according to the hundred eighteenth aspect, wherein the first glass ply is thicker than the second glass ply, and wherein the second glass ply is chemically strengthened through an ion-exchange treatment.

A hundred twentieth aspect of the present disclosure includes an article according to any of the hundred eighteenth through the hundred nineteenth aspects, wherein the first glass ply has a first thickness between the first major surface and the second major surface of at least 2 mm, and wherein the second glass ply has a second thickness between the third major surface and the fourth major surface of less than 2 mm.

A hundred twenty first aspect of the present disclosure includes an article according to any of the hundred eighteenth through the hundred twentieth aspects, wherein ratio of the first thickness to the sum of the first and second thicknesses is at least 0.7.

A hundred twenty second aspect of the present disclosure includes an article according to any of the hundred eighteenth through the hundred twenty first aspects, wherein the first thickness is at least 3.3 mm and the second thickness is 0.7 mm or less.

A hundred twenty third aspect of the present disclosure includes an article according to any of the hundred eighteenth through the hundred twenty second aspects, wherein the second glass ply comprises a second glass composition that is different from the borosilicate glass composition of the first glass ply, and wherein the second glass composition is selected from the group consisting of a soda lime silicate glass composition, an aluminosilicate glass composition, an alkali aluminosilicate glass composition, an alkali containing borosilicate glass composition, an alkali aluminophosphosilicate glass composition, and an alkali aluminoborosilicate glass composition.

A hundred twenty fourth aspect of the present disclosure includes an article according to any of the hundred eighteenth through the hundred twenty third aspects, wherein visible transmission through the article as measured according to ISO 13837A is at least 73%, and wherein total solar transmittance through the article as measured according to ISO 13837A is 90% or less.

A hundred twenty fifth aspect of the present disclosure includes an article according to any of the hundred eighteenth through the hundred twenty fourth aspects, wherein the first major surface, the fourth major surface, or both the first major surface and the fourth major surface exhibit an optical distortion of at most 200 millidiopters, as measured by an optical distortion detector using transmission optics according to ASTM 1561.

A hundred twenty sixth aspect of the present disclosure includes an article according to any of the hundred eighteenth through the hundred twenty fifth aspects, wherein the interlayer is selected from the group consisting of a polyvinyl butyral (PVB), an acoustic PVB (APVB), an ionomer, an ethylene-vinyl acetate (EVA), a thermoplastic polyurethane (TPU), a polyester (PE), a polyethylene terephthalate (PET), and combinations thereof; wherein the interlayer has a thickness in a range from 0.5 mm to 2.5 mm; wherein the interlayer comprises at least one functional layer or film, and wherein the functional layer or film provides a function selected from the group consisting of ultraviolet absorption, infrared absorption, infrared reflection, acoustic dampening, tint, an antenna, adhesion promotion, an anti-glare treatment, an anti-reflective treatment, and combinations thereof.

A hundred twenty seventh aspect of the present disclosure includes an article according to any of the hundred eighteenth through the hundred twenty sixth aspects, wherein the first glass ply and the second glass ply are pair-shaped, wherein the first glass ply comprises a first curvature depth of at least 2 mm, wherein the second glass ply comprises a second curvature depth of at least 2 mm, and wherein the first curvature depth is within 10% of the second curvature depth.

A hundred twenty eighth aspect of the present disclosure includes an article according to any of the hundred eighteenth through the hundred twenty seventh aspects, wherein the first glass ply is sagged and comprises a curvature depth of at least 2 mm and wherein the second glass ply is cold-formed into conformity with the first glass ply.

A hundred twenty ninth aspect of the present disclosure includes an article according to any of the hundred eighteenth through the hundred twenty eighth aspects, wherein the first glass ply is made by a downdraw process, wherein the downdraw process is a fusion downdraw process, wherein glass having the borosilicate glass composition of the first glass ply has a liquidus viscosity which is greater than or equal to 500 kilopoise, and wherein glass having the borosilicate glass composition of the first glass ply has a 200-poise temperature less than or equal to 1725° C.

A hundred thirtieth aspect of the present disclosure includes an article comprising: an outer ply comprising a borosilicate glass and having thickness of at least 200 μm and no more than 1 cm, wherein in terms of constituent oxides, composition of the borosilicate glass comprises: SiO₂, B₂O₃, Al₂O₃, one or more alkali metal oxides, and one or more divalent cation oxides of the group consisting of MgO, CaO, SrO, BaO, and ZnO, wherein concentrations in mole percent on an oxide basis of SiO₂, B₂O₃, the one or more alkali metal oxides, Al₂O₃, and the one or more alkaline earth metal oxides, satisfy the relationships: (R₂O+R′O)≥Al₂O₃, 0.80<(1−[(2R₂O+2R′O)/(SiO₂+2Al₂O₃+2B₂O₃)])<0.93, where R₂O is the sum of the concentrations of the one or more alkali metal oxides and R′O is the sum of the concentrations of the one or more alkaline earth metal oxides; an inner ply comprising a second glass that is different from the composition of the borosilicate glass of the outer ply, wherein the inner ply reinforces the outer ply, stiffening the outer ply to bending forces applied thereto, and wherein composition of the second glass is selected from the group consisting of a soda lime silicate glass composition, an aluminosilicate glass composition, an alkali aluminosilicate glass composition, an alkali containing borosilicate glass composition, an alkali aluminophosphosilicate glass composition, and an alkali aluminoborosilicate glass composition; an interlayer coupling the inner and outer plies, wherein the interlayer is polymeric and dampens transmission of cracks from the outer ply to the inner ply.

A hundred thirty first aspect of the present disclosure includes an article according to the hundred thirtieth aspect, wherein when glass having the composition of the borosilicate glass of the outer ply is formed as 100 polished, flat samples of 1 mm thickness with a major surface of 2×2 cm² area, and tested using square-based, 136° four-sided, pyramidal Vickers indenter directed orthogonally into a center of the major surface at 25° C. in 50% relative humidity and the indenter is quasi-statically displaced at rate of 60 μm per second to maximum 3 kg-force with indentation load held for 10 seconds, more often than not all cracks extending through the samples radially and/or laterally from the indenter are contained within a crack loop.

A hundred thirty second aspect of the present disclosure includes an article according to any of the hundred thirtieth through the hundred thirty first aspects, wherein when rapidly cooled from 25° C. to 1° C. by placement of the samples into cold water, more often than not cracks extending through the samples radially and/or laterally do not propagate beyond the crack loop.

A hundred thirty third aspect of the present disclosure includes an article according to any of the hundred thirtieth through the hundred thirty second aspects, wherein most of the crack loops of the samples are circular and have radii less than 1 mm.

A hundred thirty fourth aspect of the present disclosure includes an article comprising a first glass ply comprising a first major surface and a second major surface opposite to the first major surface, wherein the first glass ply comprises a borosilicate glass and wherein in terms of constituent oxides, composition of the borosilicate glass comprises: SiO₂, B₂O₃, Al₂O₃, one or more alkali metal oxides, and one or more divalent cation oxides of the group consisting of MgO, CaO, SrO, BaO, and ZnO, wherein concentrations in mole percent on an oxide basis of SiO₂, B₂O₃, the one or more alkali metal oxides. Al₂O₃, and the one or more divalent cation oxides, satisfy the relationships: (R₂O+R′O)≥Al₂O₃, 0.80<(1−[(2R₂O+2R′O)/(SiO₂+2Al₂O₃+2B₂O₃)])<0.93, where R₂O is the sum of the concentrations of the one or more alkali metal oxides and R′O is the sum of the concentrations of the one or more divalent cation oxides; a second glass ply comprising a third major surface and a fourth major surface opposite to the third major surface, and an interlayer bonding the second major surface of the first glass ply to the third major surface of the second glass ply; wherein transmission of ultraviolet light having a wavelength in a range of 300-380 nm through the article is 75% or less; wherein transmission of light in the visible spectrum through the article is 73% or more; and wherein total solar transmission through the article is 61% or less.

A hundred thirty fifth aspect of the present disclosure includes an article according to the hundred thirty fourth aspect, wherein the borosilicate glass composition comprises at least 74 mol % SiO₂, at least 10 mol % B₂O₃, and Al₂O₃ in an amount such that sum of SiO₂, B₂O₃, and Al₂O₃ is at least 90 mol %.

A hundred thirty sixth aspect of the present disclosure includes an article comprising: borosilicate glass, wherein in terms of constituent oxides, composition of the borosilicate glass comprises: SiO₂, B₂O₃, Al₂O₃, one or more alkali metal oxides, and one or more divalent cation oxides of the group consisting of MgO, CaO, SrO, BaO, and ZnO, wherein concentrations in mole percent on an oxide basis of SiO₂, B₂O₃, the one or more alkali metal oxides, Al₂O₃, and the one or more divalent cation oxides, satisfy the relationships: (R₂O+R′O)≥Al₂O₃, 0.80<(1−[(2R₂O+2R′O)/(SiO₂+2Al₂O₃+2B₂O₃)])<0.93, where R₂O is the sum of the concentrations of the one or more alkali metal oxides and R′O is the sum of the concentrations of the one or more divalent cation oxides; a crack loop formed in the borosilicate glass, wherein the article is free of radial or lateral cracks intersecting the crack loop and extending outward beyond the crack loop.

A hundred thirty seventh aspect of the present disclosure includes an article according to the hundred thirty sixth aspect, wherein the crack loop has a circular perimeter.

A hundred thirty eighth aspect of the present disclosure includes an article according to any of the hundred thirty sixth through the hundred thirty seventh aspects, wherein the circular perimeter has a diameter of less than 1 mm.

A hundred thirty ninth aspect of the present disclosure includes an article according to any of the hundred thirty sixth through the hundred thirty eighth aspects, wherein the borosilicate glass has thickness of at least 200 μm and no more than 1 cm.

A hundred fortieth aspect of the present disclosure includes an article according to any of the hundred thirty sixth through the hundred thirty ninth aspects, wherein the borosilicate glass has a low-temperature coefficient of thermal expansion greater than 3.25 ppm/° C. and less than 8.7 ppm/° C.

A hundred forty first aspect of the present disclosure includes an article according to any of the thirtieth through the hundred twenty ninth aspects, wherein the thickness is greater than or equal to 2.0 mm.

A hundred forty second aspect of the present disclosure includes an article according to any of the thirtieth through the hundred twenty ninth aspects, wherein the composition of the borosilicate glass comprises greater than or equal to 4 mol % and less than or equal to 6 mol % Na₂O.

A hundred forty third aspect of the present disclosure includes an article according to any of the thirtieth through the hundred twenty ninth aspects, wherein the composition of the borosilicate glass comprises: greater than or equal to 3 mol % and less than or equal to 5 mol % Al₂O₃; and greater than or equal to 12 mol % and less than or equal to 16 mol % B₂O₃.

A hundred forty fourth aspect of the present disclosure includes an article according to any of the thirtieth through the hundred twenty ninth aspects, wherein at least one of: the composition of the borosilicate glass comprises greater than or equal to 0.03 mol % and less than or equal to 0.5 mol % Fe₂O₃, and the thickness is less than or equal to 3.3 mm and the outer ply has a transmittance that is greater than or equal to 90% and less than or equal to 92.5% throughout the visible spectrum.

A hundred forty fifth aspect of the present disclosure includes an article according to any of the thirtieth through the hundred twenty ninth aspects, wherein the outer glass ply consists of the borosilicate glass.

A hundred forty sixth aspect of the present disclosure includes a borosilicate glass composition comprising: greater than or equal to 60 mol % and less than or equal to 96.0 mol % SiO₂; greater than or equal to 1.0 mol % and less than or equal to 25.0 mol % B₂O₃, greater than or equal to 0.3 mol % Al₂O₃; greater than or equal to 0.0 mol % and less than or equal to 0.3 mol % Li₂O; a non-zero amount of Na₂O; and one or more divalent metal oxides RO, wherein: the compositional amounts of each component in mol %, represented by the molecular formula of each component, satisfy the relation B₂O₃+3.5*Al₂O₃≤27.5 mol %, and at least one of: (A) the compositional amounts of each component satisfy both of the following conditions: (i) C_{rb}−(3.4−0.5*C_{nb})<0.000; and (ii) 1−2*(Alk₂O+RO)/Pₜₒₜₐₗ>0.83, wherein: (a) C_{rb} is a value of a rotatability balance parameter, calculated from the composition in terms of mol % of the components according to the following formula: C_{rb}=abs(2*max(0, (Alk₂O+RO)−(Al₂O₃+B₂O₃))+2*min(B₂O₃, R₂O+RO−Al₂O₃)+0.65*(SiO₂+2*Al₂O₃+2*B₂O₃)−80), (b) C_{nb} is a value of a network balance parameter, calculated from the composition in terms of mol % of the components according to the following formula: C_{nb}=abs(SiO₂−6*min(Alk₂O, Al₂O₃)−2*min(Alk₂O+RO−Al₂O₃, B₂O₃)−max(24+2*max(0, B₂O₃−max(0, R₂O+RO−Al₂O₃)),44)), (c) Alk₂O represents one or more alkali metal oxides, if present in the composition, (d) P_{d} is a value of a total polyhedra parameter, calculated from the glass composition in terms of mol % of the components according to the following formula: Pₜₒₜₐₗ=SiO₂+2*Al₂O₃+2*B₂O₃, and (B) the compositional amounts of each component satisfy the following condition: P_{d}−(2.58−0.2*(Na₂O/Al₂O₃))<0.000, wherein P_{d} is a value of a density parameter, calculated from the glass composition in terms of mol % of the components according to the following formula: P_{d}=2.487−0.0068998*B₂O₃+0.041371*BaO+0.13897*B2O₃+0.011637*CaO+0.055366*Cs₂O+0.025420*Fe₂O₃+0.10294*Gd₂O₃+0.0051134*K₂O+0.079903*La₂O₃+0.0041594*Li₂O+0.0084582*MgO+0.019720*MnO+0.0064419*Na₂O+0.018282*NiO+0.065781*PbO−0.002953*SiO₂+0.027682*SrO+0.0055367*TiO₂+0.0068497*V₂O₅+0.048699*Y₂O₃+0.021527*ZnO+0.026527*ZrO₂+0.011033*(min(B₂O₃, max(0, Alk₂O+RO−Al₂O₃))).

A hundred forty seventh aspect of the present disclosure includes a borosilicate glass composition according to the hundred forty sixth aspect, wherein: the compositional amounts of each component satisfy both of the following conditions: (i) C_{rb}−(3.4−0.5*C_{nb})<0.000; and (ii) 1−2*(Alk₂O+RO)/Pₜₒₜₐₗ>0.83, the composition comprises a combined amount of Na₂O and Al₂O₃ that is less than or equal to 9.7 mol %, the composition is substantially free of BaO, fluorine, and rare earth oxides.

A hundred forty eighth aspect of the present disclosure includes a borosilicate glass composition according to any of the hundred forty sixth to the hundred forty seventh aspects, wherein: the composition comprises: greater than or equal to 60.0 mol % and less than or equal to 78 mol % SiO₂, greater than or equal to 5.0 mol % and less than or equal to 17.0 mol % B₂O₃, greater than or equal to 2.5 mol % and less than or equal to 5.3 mol % Na₂O, greater than or equal to 0.3 mol % and less than or equal to 5.3 mol % Al₂O₃, greater than or equal to 0.0 mol % and less than or equal to 3.0 mol % K₂O, greater than or equal to 0.0 mol % and less than or equal to 1.5 mol % CaO, greater than or equal to 0.0 mol % and less than or equal to 0.2 mol % Li₂O, greater than or equal to 5.0 mol % Na₂O+K₂O, and the compositional amounts of each components satisfy the condition: 20.3≤B₂O₃+3.5*Al₂O₃≤27.5.

A hundred forty ninth aspect of the present disclosure includes a borosilicate glass composition according to any of the hundred forty sixth to the hundred forty eighth aspects, wherein the composition comprises: greater than or equal to 0.0 mol % and less than or equal to 5.0 mol % MgO; greater than or equal to 0.0 mol % and less than or equal to 4.0 mol % P₂O₅, greater than or equal to 0 mol % and less than or equal to 0.25 mol % SnO₂, a combined amount of (Na₂O+K₂O+MgO+CaO+ZnO+Al₂O₃+B₂O₃+SiO₂) that is greater than or equal to 95.0 mol %, a combined amount of (CaO+MgO) that is greater than or equal to 0.0 mol % and less than or equal to 5.0 mol %, and a combined amount of (FeO+Fe₂₃O) that is greater than or equal to 0.0 mol % and less than or equal to 0.5 mol %, and wherein the compositional amounts of each component of the composition satisfy both the conditions: (C) (Na₂O+K₂O+MgO+CaO+SrO+BaO+ZnO)/(R₂O+RO)<0.95, and (D) 1.01≤Na₂O/Al₂O₃<1.35.

A hundred fiftieth aspect of the present disclosure includes a borosilicate glass composition according to any of the hundred forty sixth to the hundred forty ninth aspects, wherein the composition comprises: greater than or equal to 72.0 mol % and less than or equal to 78.0 mol % SiO₂, greater than or equal to 5.0 mol % and less than or equal to 20.0 mol % B₂O₃, greater than or equal to 2.0 mol % and less than or equal to 8.0 mol % Na₂O, greater than or equal to 2.0 mol % and less than or equal to 4.0 mol % Al₂O₃, greater than or equal to 0.0 mol % and less than or equal to 3.0 mol % K₂O, greater than or equal to 0.0 mol % and less than or equal to 2.0 mol % CaO, greater than or equal to 0.0 mol % and less than or equal to 2.0 mol % MgO, and greater than or equal to 0.0 mol % and less than or equal to 0.2 mol % SnO₂.

A hundred fifty first aspect of the present disclosure includes a borosilicate glass composition according to any of the hundred forty sixth to the hundred fiftieth aspects, wherein the composition comprises: greater than or equal to 0.0 mol % and less than or equal to 0.5 mol % MnO₂, greater than or equal to 0.0 mol % and less than or equal to 0.5 mol % MnO, greater than or equal to 0.0 mol % and less than or equal to 0.5 mol % TiO₂, and a combined amount of (Fe+Cr+Mo+V+Cu+Co) that is greater than or equal to 0.0 mol % and less than or equal to 1.0 mol %, wherein the composition is: substantially free of Li₂O, and substantially free of PbO.

A hundred fifty second aspect of the present disclosure includes a borosilicate glass composition according to any of the hundred forty sixth to the hundred fifty first aspects, wherein the compositional amounts of each component of the composition satisfy the conditions: (E) 0.0≤2*M_{exc}+2*min(B₂O₃, R₂O+RO−Al₂O₃)+0.65*Pₜₒₜₐₗ−80≤3.0, wherein: M_{exc} is a value of modifiers excess parameter, calculated from the glass composition in terms of mol % of the components according to the following formula: M_{exc}=max(0, (Alk₂O+RO)−(Al₂O₃+B₂O₃)), and (F) 0.0≤abs(Si_{exc}−3*((B₂O₃+Al₂O₃)−(Alk₂O+RO))−max(24−B_{exc}, 44−3*B_{exc}))≤3.0, wherein: (i) Si_{exc} is a value of a silica excess parameter, calculated from the glass composition in terms of mol % of the components according to the following formula: Si_{exc}=SiO₂−6*min(Alk₂O, Al2O3O₃)−2*min(Alk₂O+RO−Al2O3O₃, B₂O₃), and (ii) B_{exc} is a value of a boron excess parameter, calculated from the glass composition in terms of mol % of the components according to the following formula: B_{exc}=max (0, B₂O₃−max(0, R₂O+RO−Al₂O₃)).

A hundred fifty third aspect of the present disclosure includes a borosilicate glass composition according to any of the hundred forty sixth to the hundred fifty second aspects, wherein the compositional amounts of each component satisfy the condition: P_{d}−(2.58−0.2*(Na₂O/Al2O3O₃))<0.000.

A hundred fifty fourth aspect of the present disclosure includes a borosilicate glass composition according to any of the hundred forty sixth to the hundred fifty third aspects, wherein the composition comprises: greater than or equal to 60.0 mol % and less than or equal to 77.5 mol % SiO₂, greater than or equal to 5.0 mol % and less than or equal to 17.0 mol % B₂O₃, greater than or equal to 2.5 mol % and less than or equal to 5.3 mol % Na₂O, greater than or equal to 0.3 mol % and less than or equal to 5.3 mol % Al₂O₃, greater than or equal to 0.0 mol % and less than or equal to 3.0 mol % K₂O, greater than or equal to 0.0 mol % and less than or equal to 0.2 mol % Li₂O, greater than or equal to 0.0 mol % and less than or equal to 0.2 mol % BaO, and a combined amount of (Na₂O+K₂O) that is greater than or equal to 5.0 mol %.

A hundred fifty fifth aspect of the present disclosure includes a borosilicate glass composition according to any of the hundred forty sixth to the hundred fifty fourth aspects, wherein the composition comprises: greater than or equal to 5.0 mol % and less than or equal to 5.2 mol % Na₂O, greater than or equal to 0.3 mol % MgO, and greater than or equal to 0.0 mol % and less than or equal to 0.3 mol % TiO₂, wherein the composition is substantially free of fluorine.

A hundred fifty sixth aspect of the present disclosure includes a borosilicate glass composition according to any of the hundred forty sixth to the hundred fifty fifth aspects, wherein the compositional amounts of each component satisfy the condition: 1−2*(Alk₂O+RO)/Pₜₒₜₐₗ>0.83.

A hundred fifty seventh aspect of the present disclosure includes a borosilicate glass composition according to any of the hundred forty sixth to the hundred fifty sixth aspects, wherein the compositional amounts of each component satisfy the conditions: (G) 77≤(2*M_{exc}+2*min(B₂O₃, R₂O+RO−Al₂O₃))+0.65*Pₜₒₜₐₗ≤82, wherein: M_{exc} is a value of modifiers excess parameter, calculated from the glass composition in terms of mol % of the components according to the following formula: M_{exc}=max(0, (Alk₂O+RO)−(Al₂O₃+B₂O₃)), and (H) 0.84≤1−2*(Alk₂O+RO)/Pₜₒₜₐₗ≤0.90.

A hundred fifty eighth aspect of the present disclosure includes a borosilicate glass composition according to any of the hundred forty sixth to the hundred fifty seventh aspects, wherein the composition comprises: greater than or equal to 0.0 mol % and less than or equal to 4.0 mol % P₂O₅, greater than or equal to 0 mol % and less than or equal to 0.25 mol % SnO₂, a combined amount of (Na₂O+K₂O+MgO+CaO+ZnO+Al₂O₃+B₂O₃+SiO₂) that is greater than or equal to 95.0 mol %, a combined amount of (CaO+MgO) that is greater than or equal to 0.0 mol % and less than or equal to 5.0 mol %, and a combined amount of (FeO+Fe₂O₃) that is greater than or equal to 0.0 mol % and less than or equal to 0.5 mol %, and wherein the compositional amounts of each component of the composition satisfy both the conditions: (I) (Na₂O+K₂O+MgO+CaO+SrO+BaO+ZnO)/(R₂O+RO)≤0.95, and (J) 1.01≤Na₂O/Al₂O₃≤1.35.

A hundred fifty ninth aspect of the present disclosure includes a borosilicate glass composition according to any of the hundred forty sixth to the hundred fifty eighth aspects, wherein the composition comprises: greater than or equal to 72.0 mol % and less than or equal to 77.5 mol % SiO₂, greater than or equal to 2.0 mol % and less than or equal to 4.0 mol % Al₂O₃, greater than or equal to 0.0 mol % and less than or equal to 2.0 mol % CaO, greater than or equal to 0.0 mol % and less than or equal to 2.0 mol % MgO, and greater than or equal to 0.0 mol % and less than or equal to 0.2 mol % SnO₂.

A hundred sixtieth aspect of the present disclosure includes a borosilicate glass composition according to any of the hundred forty sixth to the hundred fifty ninth aspects, wherein the composition comprises: greater than or equal to 0.0 mol % and less than or equal to 0.5 mol % MnO₂, greater than or equal to 0.0 mol % and less than or equal to 0.5 mol % MnO, greater than or equal to 0.0 mol % and less than or equal to 0.5 mol % TiO₂, a combined amount (Fe+Cr+Mo+V+Cu+Co) that is greater than or equal to 0.0 mol % and less than or equal to 1.0 mol %, and a combined amount (La₂O₃+Y₂O₃) that is greater than or equal to 0.0 mol % and less than or equal to 1.0 mol %.

A hundred sixty first aspect of the present disclosure includes a borosilicate glass composition according to any of the hundred forty sixth to the hundred sixtieth aspects, wherein the composition is substantially free of fluorine, BaO, LiO₂, and PbO.

A hundred sixty second aspect of the present disclosure includes a borosilicate glass composition according to any of the hundred forty sixth to the hundred sixty first aspects, wherein the amounts of each component of the compositions satisfy the conditions: (K) 0.0≤2*M_{exc}+2*min(B₂O₃, R₂O+RO−Al₂O₃)+0.65*Pₜₒₜₐₗ−80≤3.0, wherein: M_{exc} is a value of modifiers excess parameter, calculated from the glass composition in terms of mol % of the components according to the following formula: M_{exc}=max(0, (Alk₂O+RO)−(Al₂O₃+B₂O₃)), and (L) 0.0≤abs(Si_{exc}−3*((B₂O₃+Al₂O₃)−(Alk₂O+RO))−max(24−B_{exc}, 44−3*B_{exc}))≤3.0, wherein: (i) Si_{exc} is a value of a silica excess parameter, calculated from the glass composition in terms of mol % of the components according to the following formula: Si_{exc}=SiO₂−6*min(Alk₂O, Al2O3O₃)−2*min(Alk₂O+RO−Al2O3O₃, B₂O₃), and (ii) B_{exc} is a value of a boron excess parameter, calculated from the glass composition in terms of mol % of the components according to the following formula: B_{exc}=max (0, B₂O₃−max(0, R₂O+RO−Al₂O₃)).

A hundred sixty third aspect of the present disclosure includes a borosilicate glass composition according to any of the hundred forty sixth to the hundred sixty second aspects, wherein the composition comprises: greater than or equal to 11 mol % and less than or equal to 16 mol % B₂O₃, greater than or equal to 2 mol % and less than or equal to 6 mol % Al₂O₃, and a total amount of Na₂O, K₂O, MgO, and CaO that is greater than or equal to 7.0 mol %.

A hundred sixty fourth aspect of the present disclosure includes a borosilicate glass composition according to any of the hundred forty sixth to the hundred sixty third aspects, wherein the composition comprises greater than or equal to 4 mol % and less than or equal to 6 mol % Na₂O.

A hundred sixty fifth aspect of the present disclosure includes a borosilicate glass composition according to any of the hundred forty sixth to the hundred sixty fourth aspects, wherein the composition of the borosilicate glass comprises: greater than or equal to 3 mol % and less than or equal to 5 mol % Al₂O₃; and greater than or equal to 12 mol % and less than or equal to 16 mol % B₂O₃.

A hundred sixty sixth aspect of the present disclosure includes a glass article comprising a borosilicate glass composition according to any of the hundred forty sixth to hundred sixty fifth aspects.

A hundred sixty seventh aspect of the present disclosure includes a glass article according to the hundred sixty sixth aspect, wherein the glass article comprises a density measured at 20° C. that is less than 2.5 g/cm³.

A hundred sixty eighth aspect of the present disclosure includes a glass article according to the hundred sixty seventh aspect, wherein the density measured at 20° C. is less than 2.3 g/cm³.

A hundred ninth aspect of the present disclosure includes a glass article according to any of the hundred sixty seventh to the hundred sixty eighth aspects, wherein when glass having the borosilicate composition is formed as 100 polished, flat samples of 1 mm thickness with a major surface of 2×2 cm² area, and tested using square-based, 136° four-sided, pyramidal Vickers indenter directed orthogonally into a center of the major surface at 25° C. in 50% relative humidity and the indenter is quasi-statically displaced at rate of 60 μm per second to maximum 3 kg-force with indentation load held for 10 seconds, more often than not all cracks extending through the samples radially and/or laterally from the indenter are contained within a crack loop.

A hundred seventieth includes a glass article according to the hundred sixty ninth aspect, wherein most of the crack loops of the samples are circular and have radii less than 1 mm.

Construction and arrangements of the compositions, assemblies, and structures, as shown in the various exemplary embodiments, are illustrative only. Although only a few embodiments have been described in detail in this disclosure, many modifications are possible (e.g., variations in sizes, dimensions, structures, shapes, and proportions of the various elements, values of parameters, mounting arrangements, use of materials, colors, orientations) without materially departing from the novel teachings and advantages of the subject matter described herein. Materials, such as the glazing disclosed herein, may be used for glazing in architectural applications (e.g., windows, partitions) or may be otherwise used, such as in packaging (e.g., containers). The order or sequence of any process, logical algorithm, or method steps may be varied or re-sequenced according to alternative embodiments. Other substitutions, modifications, changes and omissions may also be made in the design, operating conditions and arrangement of the various exemplary embodiments without departing from the scope of the present inventive technology.

The borosilicate compositions (and/or borofusion compositions) described herein are suitable and advantageous for utilization in solar applications, in particular, in solar panels and/or solar modules, as described herein.

A series of experiments was completed in comparing borosilicate glasses described herein against the sodalime glass incumbent typically utilized in the solar industry, as cover glass for solar panels and solar modules. It was determined that the borosilicate compositions described herein enable a tailored, advantaged design when incorporated into a first substrate (front) and/or second substrate (back) of a solar module or panel, including but not limited to: (1) enhanced degradation resistance to subsurface cracks when scratched; (2) scratch and weathering resistance; (3) lower density/10% weight savings (providing a lighter overall module or panel, when compared to the same thickness of sodalime glass; (4) higher transmission rates over the spectrum (e.g. 300-800) with particular advantages/improvements observed at certain wavelengths; (5) consistent transmission over a duration of service in installed/field position; and (6) improved abrasion resistance; (7) lower probability of subsurface damage as compared to sodalime glass, among other advantages (processability, CTE match/tailoring with interlayer/encapsulants, lower CTE than SLG).

FIG. 18 provides a schematic cut-away side view of an embodiment of a solar panel 10 having one or more substrates from the borosilicate compositions set forth herein, in conjunction with various aspects of the present disclosure.

Referring to FIG. 18, the solar cell 40 is retained between two substrates, a first substrate 32 and a second substrate 42. An encapsulant 38 (e.g., first encapsulant) is configured between the solar cell 40 and the second surface 36 of the first substrate 32. An encapsulant 48 (e.g., a second encapsulant or an integral layer/monolith with the encapsulant 38) is configured between the first surface 44 of the second substrate and the solar 40. In this configuration, the solar cell 40 is attached to the first substrate 32 and second substrate 42

The solar cell 40 is configured with a functional material 50, which converts photons into electrons (the functional part of the solar cell). The solar cell 40 is configured from functional material 50, electrode/electrode layers, transparent oxide layers, and/or additives or interlayers to configure the solar cell 40. This layup, along with the edge seal 22, provides an embodiment of a solar module 12. The solar panel 10 of FIG. 18 incorporates a frame 20 (e.g., in perimetrical configuration around the outer edge of the solar module 12 (e.g., at least partially overlapping with the edge seal 22 of the solar module 12). The flame optionally includes a gasket, which is configured between the frame 20 body and an outer edge of the solar module 12. Optionally, a coating (e.g., anti-reflective coating) is applied to the first surface 34 of the first substrate 32 (and/or the second surface 45 of the second substrate 42 (not shown)).

The solar cell 40 is configured with electrical leads that connect the solar cell to the electrical wiring and/or junction box, such that the solar cell is in electrical communication with the j-box and can transmit electrons in the form of electricity/electrical current out of the solar cell 40.

In some embodiment, the leads and electrical wires/contacts are configured within the frame 20 edge, between the edge seal 22 and the frame/gasket assembly.

In some embodiments, the leads and electrical wires are configured to extend through at least a portion of the second substrate (e.g., through a hole or discontinuous edge portion) such that the electrical wiring is directed through a major surface portion of the second substrate and out of the solar panel into the junction box 24.

As shown, the first substrate can be configured as the major surface facing the sun/photon capture. The solar panel 10 or module 12 can also be configured in a bifacial configuration, such that photon capture is configured through the first substrate 32 and the second substrate 42.

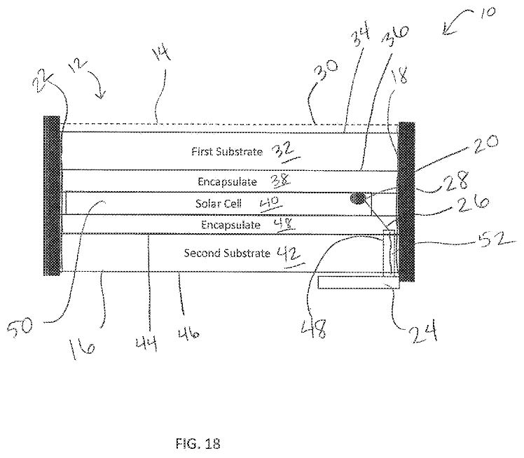

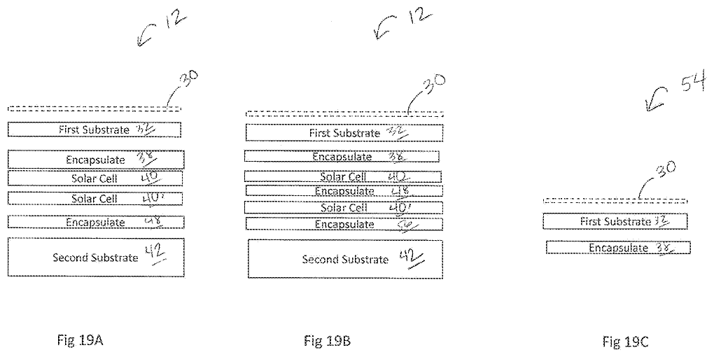

FIG. 19A-C provide various schematic embodiments of expanded cut away side views of aspects of incorporating the embodied borosilicate compositions of the present disclosure into variously configured layups within embodied solar modules (FIGS. 19A and 19B) and as a retrofit cover, configured to attach to a surface of a solar panel (FIG. 19C), in accordance with one or more embodiments of the present disclosure.

FIG. 19A provides an illustrative example of a solar module 12 having an embodied borosilicate composition incorporated therein as a first substrate or a second substrate, in conjunction with one or more aspects of the present disclosure.

As FIG. 19A-C incorporate reference numbers and configurations utilized in FIG. 18, so too are those reference numbers and relative descriptions applicable to FIGS. 19A-C.

Referring to FIG. 19A, two solar cells are shown, solar cells 40 and 40′. The solar cells are tailored adjacent to each other, and may be printed, adhered, configured, deposited, layered, or the like, in order to configure a tandem solar module, where one solar cell 40 (first solar cell) is configured at least partially over the top of another solar cell 40′ (second solar cell).

FIG. 19B provides an illustrative example of a solar module 12 having an embodied borosilicate composition incorporated therein as a first substrate or a second substrate, in conjunction with one or more aspects of the present disclosure. Also, FIG. 19B includes two solar cells: solar cell 40 and 40′. In contrast with FIG. 19A, the tandem configuration illustrated in FIG. 19B incorporates an intervening encapsulate layer 48 between the solar cells. In this configuration, the solar module 12 utilizes three encapsulates, 38, 48, and 56 in the layup configuration of FIG. 19B.

With reference to FIG. 19C, an illustrative example of a retrofit cover 54 for a solar module 12 (or solar panel 10) is depicted, in accordance with one or more aspects of the present disclosure. As shown in FIG. 19C, the first substrate in the cover includes an embodied borosilicate composition, in conjunction with one or more aspects of the present disclosure. Moreover, the encapsulate is tailored to: (1) provide protective surface cover to the first substrate; (2) provide structural rigidity and/or cushioning support to the first substrate during shipping, transport, and in the field; and/or (3) provide a surface configured to adhere to a surface of an existing solar panel in-field. As a non-limiting embodiment, the encapsulant may be configured as a sealant, glue, adhesive, room temperature curing polymer, UV curing polymer, an adhesive, an optically clear adhesive, and/or combinations thereof. In some embodiments, by incorporating the retrofit cover onto the surface of a solar panel (e.g., installed), the upper-most surface of the solar panel can be tailored for one or more advantages of the embodied borosilicate compositions of the present invention, as set forth herein.

In some embodiments, an anti-reflective coating is applied to the first surface of the first substrate in order to reduce the reflection on the surface of the glass coating, thereby increasing efficiency of the solar panel. In some embodiments, the AR coating is configured to get more photons into the solar cell.

Examples: Comparative Analysis of Borosilicate Glass Embodiments vs. sodalime glass comparative example.

In order to better-quantify whether one or more borosilicate glass compositions of the present disclosure are advantageous when utilized in a solar module application, a series of analytical and experimental measurements were completed, in which a borosilicate glass composition was evaluated against sodalime glass along various parameters, as set forth in the paragraphs that follow.

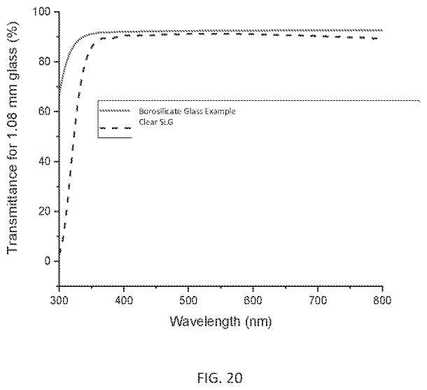

FIG. 20 provides the transmittance data for iron free-borosilicate glass and clear sodalime glass, plotted as the transmittance percent by wavelength, from 300 nm to 800 nm. Each glass sample was configured at the same thickness 1.08 mm. As shown in FIG. 20, the iron-free borofusion has a higher transmittance than clear SLG at all wavelengths. Moreover, there is a stark contrast in the transmission of borosilicate glass between 300 nm and 400 nm, as compared with sodalime glass, with approximately 4% transmission of SLG vs. 67% transmission for borosilicate at 300 nm; 82% transmission for sodalime glass vs. 92% transmission for borosilicate at 350 nm; and a measured improvement of between approximately 3-7% improvement at wavelengths ranging from 400-800 nm, as shown in FIG. 20. Without being bound by any particular mechanism or theory, by incorporating one or more embodiments of borosilicate glass described herein into a solar module or solar panel, the functional material in the panel would receive more photons at all wavelengths assessed versus the sodalime glass. With a measured improvement over sodalime glass in transmission, choices While FIG. 20 illustrates a comparative example of a borosilicate glass composition embodiment vs. SLG, this measured improvement is believed to be embodied in all borosilicate glass compositions detailed herein which are iron-free.

Table 1200. Table 1200) provides a listing of mechanical properties, thermal properties, and optical properties of a borosilicate glass (borofusion) of the present disclosure compared to sodalime glass.

| | Illustrative | |
|---|---|---|
| | borosilicate | SLG |
| | glass | comparative |
| | example | example |
| Mechanical properties | | |
| Fracture toughness by | 0.760 ± 0.017 | 0.730 ± 0.017 |
| DCB* (MPa · m^{0.5}) | | |
| Vickers hardness | 523 ± 6 | 542 (Tin) − |
| (kgf/mm²) (200 g load) | | 584 (air) |
| E-Modulus (GPa) | 62.7 | 72.9 |
| Poisson's ratio | 0.196 | 0.22 |
| Thermal properties | | |
| Density (g/cm³) | 2.266 | 2.507 |
| CTE (0-300° C.) (×10⁻⁷/° C.) | 45.2 ± 0.5 | 90 |
| Softening Point (° C.) | 777 | 719 |
| (10^{7.6} Poise) | | |
| Pair sagging temperature | 608 ± 3 | 599 |
| (° C.) (10¹¹ Poise) | | |
| Anneal Point (° C.) (10¹³ | 540 | 553 |
| Poise) | | |
| Strain Point (° C.) (10^{14.5} | 494 | 509 |
| Poise) | | |
| Optical properties | | |
| Refractive index (589.3 | 1.4820 | 1.5214 |
| nm) | | |
| Stress Optical | 38.39 | 27.2 |
| Coefficient | | |
| (nm/cm/Mpa) | | |

As referenced above,
*DCB means double cantilever beam.

As depicted in Table 1200, regarding mechanical properties, the borosilicate glass composition embodiment provides roughly comparable properties. Regarding thermal properties, the density of the borosilicate glass composition embodiment is roughly 10% less than the SLG comparative example and the CTE of the borosilicate glass composition embodiment is roughly half of the sodalime glass comparative example, with the remaining thermal properties being roughly comparable to each other. The optical properties referenced in Table 1200, refractive index and stress optical coefficient, are also roughly comparable to each other.

The properties in Table 1200 illustrate that the borosilicate glass composition has a lower density (i.e., lighter weight at same dimensional size) and lower CTE than the sodalime glass. Without being bound by any particular mechanism or theory, the borosilicate glass compositions described herein provide at least one advantage, including, but not limited to: a lightweight, drop-in replacement alternative to sodalime glass in a solar panel and solar module applications, tailoring of frame and/or support railings/gantry in line with panel weight reduction, among other items. Moreover, given the formability of the borosilicate glass and low CTE, it is believed that a solar module and/or solar panel incorporating borosilicate glass (e.g., as a substrate or superstrate) will have improved processability and lower thicknesses than corresponding sodalime glass comparative example, providing at least one advantage including, but not limited to: improved yields in manufacturing, improved lamination yields, and/or increased duration.

FIG. 21 provides a series of SEM images at 20,000× magnification of the surfaces of two glass samples, (1) a sodalime glass (top row) compared to (2) the borosilicate glass composition embodiment detailed above (bottom row), over three conditions: initial state before weathering (initial state); after weathering, and after weathering and washing. The starting glass samples, ‘not weathered’ were in the as-made condition without any intentionally introduced damage and both samples were configured with a cross-sectional thickness approximately the same (SLG at 2.1 mm cross-sectional thickness, borosilicate glass at 2.2 mm cross-sectional thickness).

The samples both underwent weathering, after which they were observed for surface roughness (center images in ‘after weathering column’). Weathering on the samples included holding the samples at a steady 85 degrees Celsius at 85% relative humidity for a duration of 14 days.

After weathering, as shown in FIG. 21, the sodalime glass showed a significantly increased surface roughness as visually observable and in stark contrast with the surface roughness of the borosilicate glass embodiment. The borosilicate glass embodiment appears in approximately the same condition/surface roughness in the ‘not weathered state’ as in the ‘after weathering state’. Without being bound by any particular mechanism or theory, it is believed that the sodalime glass undergoes a surface reaction during weathering, such that a weathering byproduct (e.g., sodium carbonate) is deposited at along the surface, such that the degradation of glass and deposition of byproduct at the surface results in a stark increase in surface roughness. While scale

Subsequent to weathering, the samples both underwent a wash cycle in a commercially available washer configured with ultrasonic capabilities, after which they were then again observed for surface roughness (right-hand images in ‘after weathering+wash’ column). Each glass sample was washed according to the following wash process steps: rinsing with de-ionized (DI) water; cleaning with 4% semi clean detergent at an ultrasonic frequency of 40 kHz; rinsing with DI water; rinsing with DI water at an ultrasonic frequency of 40 kHZ; rinsing with DI water while slowly pulling the sample from the ultrasonic environment; and air drying the sample. Each step of the washing process was completed at elevated temperature (a temperature of 160 degrees Farenheight) and each step lasted a duration of 720 seconds.

After weathering and washing, the surface roughness of the sodalime glass sample still exhibits significant surface roughness as compared to ‘not weathered’ image but appears in a smoother surface roughness than the ‘after weathering’ image. Without being bound by any particular mechanism or theory, it is believed that the washing process may enable more uniform degradation of the surface of the sodalime glass, such that the weathering byproduct (e.g., sodium carbonate) is distributed in a more uniform manner than after the initial weathering only state (as illustrated by the visual improvement of the after weathering+wash) compared to the ‘after weathering’ only images. In both states, after weathering and after weathering and washing, the sodalime glass degraded to increase surface roughness, as illustrated by the SEM images in FIG. 21.

After weathering and washing, the surface roughness of the borosilicate glass composition embodiment appears in an unchanged condition as compared to the ‘not weathered’ and ‘after weathering’ images. Comparing the two ‘after weathering+wash’ SEM images, the sodalime glass sample has significantly more surface roughness that's visually observable as compared to the borosilicate glass composition embodiment. Thus, the borosilicate glass composition embodiment illustrates improved weathering as compared to the sodalime glass composition.

Overall, the sodalime glass sample showed a significant amount of degradation/weathering as compared to borosilicate glass composition embodiment. It is believed that the weathering and/or weathering and washing process are a proxy to evaluate durability of the substrate in an installed state (e.g., as a superstrate or as a substrate in a solar module or solar panel). Without being bound by any particular mechanism or theory, at least one, or both of, the degradation artifacts that occurred on the surface of the sodalime glass are believed to be deleterious to the transmission of the substrate in a solar application. For example, increased surface roughness (e.g., in a non-tailored manner, by weathering and washing) imparts scattering in the substrate, thus reducing transmission of photons through the glass substrate and into the functional material in the solar module or solar panel.

Similarly, the surface degradation of the sodalime glass which resulted in weathering byproduct (e.g. sodium carbonate) creates a non-transmissive surface covering in all or part of the surface of the sodalime glass substrate, thus contributing to deleterious effects when in a solar application (e.g. reduced transmission, increased absorption of photons into the non-transparent material, increased haze, and scattering, to name a few), which result in lower transmission and thus, lower efficiency of the functional material embodied in the solar module or solar panel.

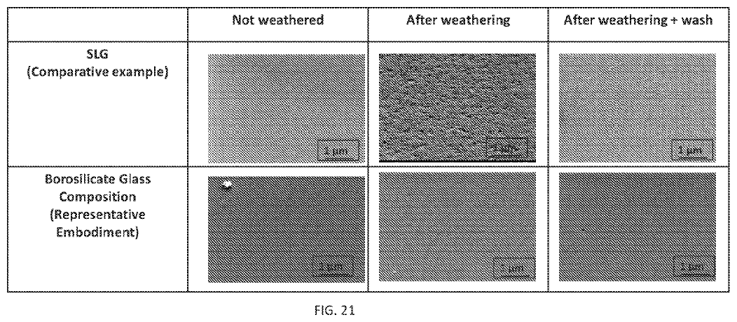

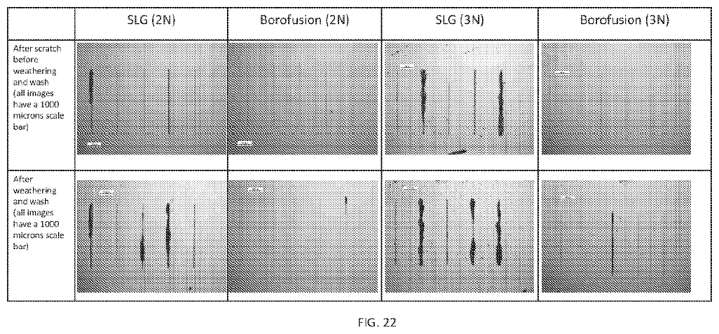

Referring to FIG. 22, two samples each of a borosilicate glass composition embodiment and a sodalime glass underwent the same weathering and wash process cycled described with respect to FIG. 21, though here, scratch damage evolution after weathering was evaluated as a proxy for durability in installation as a substrate in a solar application (solar panel or solar module). As indicated in FIG. 22, each sample received either a series of scratches at either 2N and 3N in accordance with a Knoop Scratch test (with an ‘after scratch, before weathering and wash’ in the top row), followed by weathering, then washing, (with the final images were taken of each sample, depicted in the ‘after weathering and wash’ in the bottom row). As shown in FIG. 22, the Knoop Scratch did impart some damage to the sodalime glass that was visually detectable before weathering and washing, and the Knoop Scratches did not impart any visible surface damage to the borosilicate glass composition embodiments that were visually detectable before weathering and washing.

The weathering and washing steps exposed the subsurface damages on each type of glass (imparted by the Knoop Scratches), where the subsurface damage was not visually detectable in any of the four samples before the weathering and wash steps. Through the weathering and wash cycle, the subsurface damage is exposed and is visually detectable/observable, as shown in FIG. 22. As shown in the bottom row, the sodalime glass had significantly more subsurface damage at both 2N and 3N as compared to either of the borosilicate glass compositions.

As set out above, and without being bound by any particular mechanism or theory, the resulting subsurface damage by scratching imparts significant initiation sites for degradation in the sodalime glass samples, while having very little impact in the borosilicate glass composition. With respect to an application in solar, any surface or subsurface damage is believed to impart a reduced transmission through the substrate into the functional material in the solar panel/solar module, creating a deleterious impact on the efficiency and/or long-term durability of the solar panel once one or more scratches are imparted on the surface of the substrate.

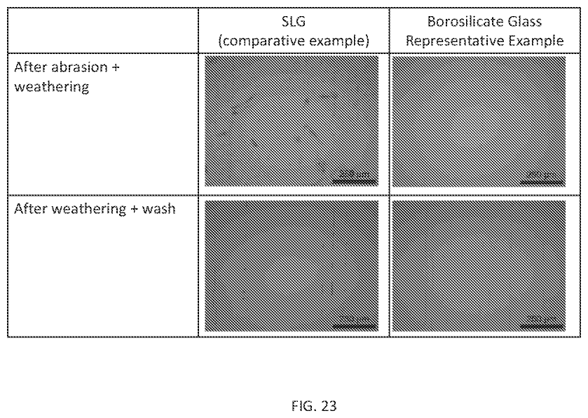

As depicted in FIG. 23, images from a microscope under 100× magnification, which depict spots and scratch damage on samples resulting from a proxy analysis from the automotive field. This evaluation was utilized as a mode of evaluating whether and how a repeated rubbing abrasion, combined with weathering and wash processing, would impact surface quality/degradation in a substrate for solar applications, where such impact to surface quality/degradation would be deleterious to transmission.

One of each type (sodalime glass and borofusion glass at 0.1 wt % Fe2O₃, with each at 3.3, mm cross-sectional thickness) underwent a linear abrasion test as set forth herein, followed by weathering, then washing process (where weathering and washing process are the same as set out with respect to FIGS. 21 and 22, above).

The linear abrasion process utilized a windshield wiper abrasion with a Taber 5750 Linear abrader, having a 250 g load, set for 60 cycles/min, and a duration of 500 cycles, where the process was configured to dispense AZ dust/water solution every ˜50 cycles to wash the glass. It is noted, the iron in the borosilicate glass composition is believed to have no impact on weathering performance and the composition evaluated is believed to perform in substantially the same way as if an iron free composition set forth herein was evaluated.

As shown in FIG. 23, after abrasion and weathering, the comparative example has significant areas of spots and lines/scratch damages readily visually observable, while the corresponding borosilicate glass composition has very faint, barely visible, visually observable lines. The spots and areas large areas of discoloration in the sodalime glass are believed to be caused by weathering byproducts (as set forth above), which can be washed away (as also set forth above). After weathering and wash, the weathering byproduct appears to have been significantly removed from the sodalime glass, leaving striations/line marks on the glass which are easily detected through visual observation. In contrast, after weathering, the borosilicate glass composition embodiment has more pronounced striations/line marks as compared to before washing, but even after washing, the line marks/scratches in the borosilicate glass composition embodiment are far less pronounced than in the sodalime glass comparative example. Here to, through this evaluation, the borosilicate glass has improved performance over sodalime glass.

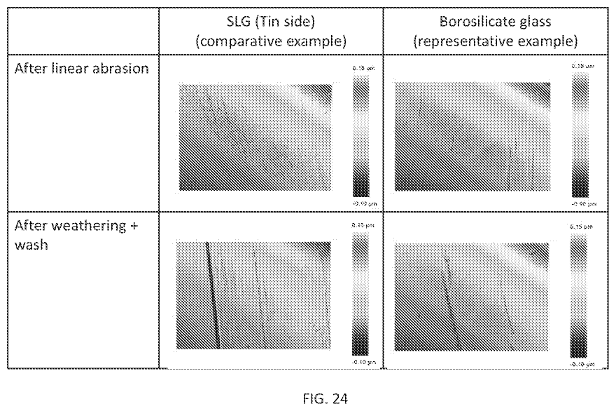

Referring to FIG. 24, confocal microscopy images of the samples described in FIG. 23 are provided, except that the confocal microscopy images were taken after abrasion (top row) then after weathering and wash process (bottom row). The confocal microscopy provides a qualifying analysis on scratch presence and general depth, and also quantifying analysis of the depth of surface damage/scratch penetration (with reference to the corresponding scale at the right-hand side of each image, with a lower limit of a depth of 0.1 microns (i.e. −0.10 micrometers, as shown in FIG. 24)). Each image is 117 microns by 88 microns in size. As depicted in FIG. 24, the sodalime glass shows more surface roughness and depth of linear abrasion than the borosilicate glass composition embodiment.

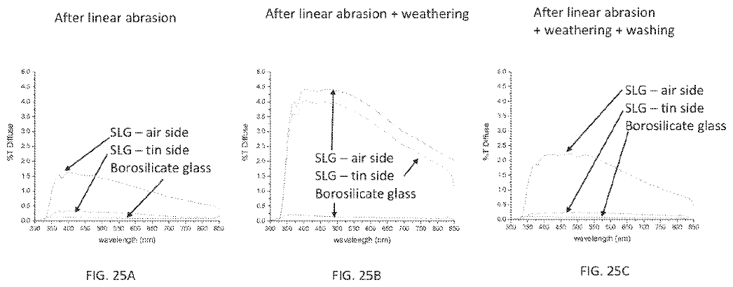

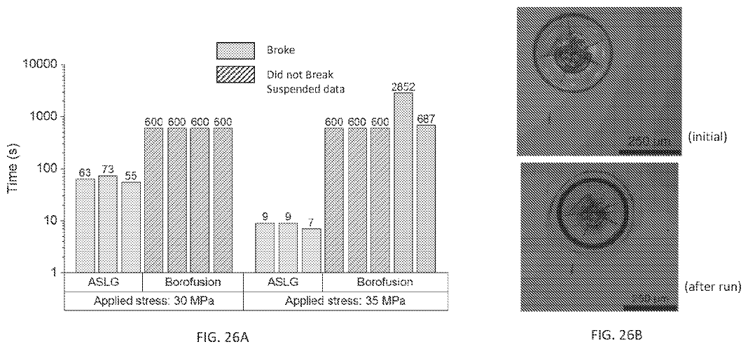

FIG. 25A through 25C provides three separate plots of % transmission diffusion over the visible spectrum (nm) and illustrative support for borosilicate glass maintaining transmission after linear abrasion (FIG. 25A), linear abrasion followed by weathering (FIG. 25B), and linear abrasion followed by weathering, then followed by washing (FIG. 25C). Weathering and washing are the same processes set out above, in regard to the discussion for FIG. 21. Linear abrasion is the same process as set out in the discussion in regard to FIG. 23 (above).

Since the sodalime glass is manufactured such that it has two different major surfaces (tin-facing or ‘tin side’ and air-facing or ‘air-side’), diffusion measurements against both two comparative samples of sodalime glass, having linear abrasion/weathering/washing on opposite sides, was taken for comparative purposes against the borosilicate glass composition embodiment.

Referring to all of FIGS. 25A, 25B, and 25C, the borosilicate glass has a lower % transmission diffusion (haze) in all conditions are compared to either side of the sodalime glass. While the SLG tin-side shows less haze than the air-side (illustrating improved abrasion resistance), both provide SLG sides show a significant amount of haze after abrasion and weathering, as compared to the borosilicate glass. This is believed to be due to the surface degradation in sodalime glass per the aforementioned formation of weathering byproducts (sodium carbonate) during weathering. FIG. 25C illustrates that both the tin and air facing sides of the sodalime glass are able to have their respective percent transmission diffusions reduced with the washing process, the air-side is unable to recover to a ‘before weathering condition’ (as in FIG. 25A). It is noted, while the washing process brings the tin side closer to its ‘before weathering condition’, the washing cycle is only a temporary, marginal improvement to a field-installed solar module containing sodalime glass, because in installation, the sodalime glass will continue to weather and degrade, forming haze-inducing weathering byproducts which will in turn bring reduce the transmission once again.

Referring to Table 1300 below, Haze was calculated for each sample after each step and is shown below.

TABLE 1300
% Haze = (Y_{diffuse}/Yₜₒₜₐₗ)* 100 @ illuminate D65 10°

| | As- | | | Linear |
|---|---|---|---|---|
| | made | | Linear | abrasion + |
| | (not | Linear | abrasion + | weathered + |
| | abraded) | abrasion | weathered | washed |
| SLG (air side abraded) | 0.02 | 1.54 | 4.93 | 2.44 |
| (comparative example) | | | | |
| SLG (Tin side abraded) | 0.07 | 0.31 | 4.34 | 0.26 |
| (Comparative example) | | | | |
| Borosilicate glass | 0.01 | 0.09 | 0.14 | 0.07 |
| (representative example) | | | | |

Next, a chemical durability test was completed, in order to illustrate in a comparative manner, the impact of the substrate vs. a comparative substrate under acidic, neutral (control) and basic conditions. The chemical durability was measured by immersing the glass samples to 5 mass % water solutions of HCl at 95° C. for 24 hours and 5 mass % NaOH at 95° C. for 6 hours. Before immersing the samples, the samples were rinsed under distilled water (16 M resistance) for 5 minutes while squeezing the Tygon tubing to make a shower-like rinse; ultrasonicated (50/60 Hz frequency) in 60° C. to 65° C. 4% Semi clean Detergent bath for one minute; again, rinsed under 16 M distilled water for 5 minutes while squeezing the Tygon tubing to make a shower-like rinse; followed by a final rinse in a cascading 18 M distilled water bath for 5 minutes. The samples were then transferred onto glass racks on stainless steel trays and dried in a 110° C. oven for an hour, and placed in a desiccator until used.

HCl tests were done in Pyrex tubes in hot water bath; NaOH was done in platinum tubes, same bath type. After the treatment, the samples were flood-rinsed in 16 and 18 M distilled water, dried in a 110° C. oven for about 30 minutes, and weighed to determine the loss of mass.

The sodalime glass was found to not undergo significant degradation in the basic chemical durability test. Without being bound by any particular mechanism or theory, it is believed that the sodalime glass formed a byproduct in soda-lime, which acted as a sort of surface protection to the surface of the sodalime glass, preventing further degradation. The NaOH byproduct is believed to be CaSiO4, which is formed in NaOH bath as NaOH reacted with soda-lime, releasing some Ca2+(from the glass) to the basic solution and forming Ca(OH)2. The calcium hydroxide in turn is chemically available to react with silica in the sodalime glass to form CaSiO4 which has very low solubility in the basic solution, therefore it can deposit on the glass surface and form a “protection” layer, but also increasing haze through the substrate/reducing transmission through the substrate. The weight change and optical results are illustrated in Table 1400 below, with the test media outlined in each row header.

TABLE 1400
Weight Change and Optical Results:

| | | Wt. | | | |
|---|---|---|---|---|---|
| | | Change | Standard | % T at | |
| | Sample | Mean | Deviation | 450 nm | % Haze |
| Test Media | Description | mg/cm² | mg/cm² | Avg. | Average |
| Acid durability | Borosilicate | 0.01 | 0.00 | 93.85 | 0.00 |
| test: | glass | | | | |
| 5% w/w HCl, 95 | Soda Lime | 0.011 | 0.00 | 91.90 | 0.00 |
| deg. C., 24 hr. | | | | | |
| Neutral pH | Borosilicate | 0.02 | 0.00 | 93.28 | 0.00 |
| (control) test: | glass | | | | |
| 18 megohm, DI | Soda Lime | 0.64 | 0.07 | 91.98 | 0.02 |
| H2O. 135 deg. | | | | | |
| C., 24 hrs. | | | | | |
| Basic durability | Borosilicate | 3.09 | 0.03 | 91.99 | 0.00 |
| test: | glass | | | | |
| 5% w/w NaOH. | Soda Lime | 0.79 | 0.01 | 91.60 | 10.22 |
| 95 deg. C., 6 hrs. | | | | | |

The borosilicate glass exhibited the highest weight loss after the basic chemical durability test, though even with this weight loss, there was no haze detected.

FIG. 26 A illustrates the crack behavior under subcritical stress, utilizing a Ring-on-Ring test with 3 kgf Vickers indented glass under subcritical crack growth stress for two sets of samples at different applied stresses (30 MPa and 35 MPa). As illustrated in FIG. 26A, under 30 MPa of applied stress, the loaded stress generated from the Ring-on-Ring broke the sodalime glass in about one minute (all three samples), while in stark contrast, the borosilicate samples (4 total) evaluated under the same conditions did not break after 10 minutes (end of run). At a higher stress (35 MPa,) the three sodalime glass samples each broke in under 10 seconds, while the borosilicate glass samples surpassed the end of runtime (10 minutes). To better-understand the capabilities of the borosilicate glass, two samples had to continued evaluation even after the run time (10 minutes) had concluded, with one sample braking almost a minute and a half past the test duration time, with the other sample breaking over 37 minutes after the test run time was over (over 47 minutes total).

FIG. 26B shows two representative images of a sample of borofusion glass evaluated in the test described with FIG. 26A, where the image on the top shows the initial break in the borofusion sample, and the image on the bottom shows the crack progression on the same sample of borofusion glass, after a duration of 10 minutes run time, holding at 35 MPa. As shown in FIG. 26B, some radial cracks grew larger after the holding at pressure under the Ring-on-Ring test, but the radial cracks did not extend into the ring cracks.

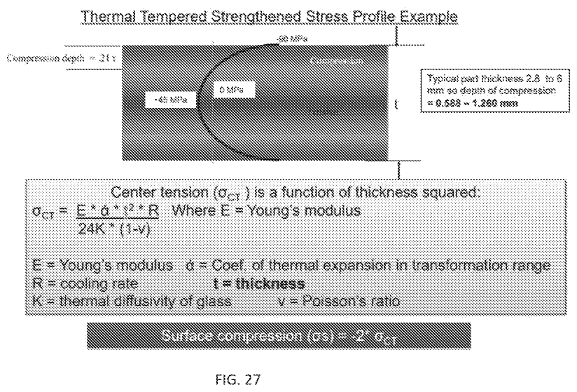

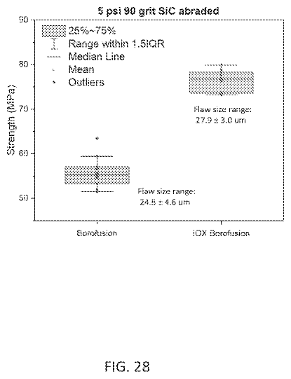

FIGS. 27 and 28 provide illustrative support that one or more borosilicate glass compositions of the present disclosure can be strengthened through at least one of thermal tempering (FIG. 27) or ion exchange (FIG. 28).

Referring to FIG. 27, an illustrative example is depicted, showing the compressive stress from thermal tempering mapped along a cross-sectional cut-away side view of a borofusion glass, in accordance with one or more embodiments of the present disclosure. As illustrated by the formula accompanying the cross-section, thermally strengthened glass has as depth of layer of 21% of its thickness & magnitude of stress is driven by thickness squared.

When the center tension is calculated for sodalime glass and borosilicate glass, it provides a relative sense on the tempering stress impacted form borofusion and SLG. As shown in Table 1500 below, when the same conditions are utilized to temper both glasses, SLG responds with a higher compressive stress than the borofusion glass (2.7 times higher).

The variables utilized in the stress profile example are below in Table 1500:

| | SLG | Borofusion |
|---|---|---|
| E (Gpa) | 72 | 62.7 |
| Poisson's ratio | 0.22 | 0.196 |
| CTE (ppm/C) | 8.8 | 4.5 |
| thermal diffusivity @ 600 C | 0.004813 | 0.00565 |
| (cm²/s) | | |
| cooling rate (° C./s) | 100 | 100 |
| glass thickness (mm) | 2.1 | 2.1 |
| CT (MPa) | 31 | 11.4 |
| CS (MPa) | −62 | −22.8 |
| CS ratio to Borofusion | 2.72 | 1 |
| glass thickness (mm) | 3.8 | 3.8 |
| CT (MPa) | 101.5 | 37.8 |
| CS (MPa) | −203.1 | −74.7 |
| CS ratio Borofusion | 2.72 | 1 |

As shown in FIG. 28, one or more borosilicate glass compositions of the present invention can be chemically strengthened by ion-exchange. As shown in FIG. 28, the strength (MPa) is shown for a borofusion glass composition, and an ion exchanged borofusion glass composition. The ion exchanged sample retained its strength even after 5 psi of 90 grit SiC abrasion on 0.6 mm glass. The ion exchange results from 100% KNO3 at 360 deg. C is shown below in Table 1600, with the Vickers indentation threshold in the Table that follows 1700).

TABLE 1600
Ion Exchange results from: 100% KNO₃, 380° C.

| Time | CS | DOL |
|---|---|---|
| (hour) | (MPa) | (μm) |
| 4 | 283 | 7 |
| 6 | 276 | 8 |
| 9 | 272 | 10 |
| 16 | 262 | 12.5 |
| 24 | 254 | 15 |

TABLE 1700
Vickers Indentation Threshold

| Time | CS | DOL |
|---|---|---|
| (hour) | (MPa) | (μm) |
| 4 | 283 | 7 |
| 6 | 276 | 8 |
| 9 | 272 | 10 |
| 16 | 262 | 12.5 |
| 24 | 254 | 15 |

In some embodiments, the solar module is a frameless module. When the solar module is a frameless module, an edge seal is configured perimetrically around the solar stack to protect the electrical and functional materials components from environmental impact (e.g., water, oxygen, dust, humidity).

In some embodiments, the solar module is configured with a frame. In some embodiments, the solar module includes an edge seal configured around the perimetrical edge of the solar stack.

In some embodiments, the frame cooperates with a gasket to provide sealing engagement around the perimetrical edge of the solar module and/or to provide compressive retention of the stack components.

In some embodiments, a fit or a metal is utilized between the first substrate and the second substrate, where the frit is laser bonded to create an edge seal.

In some embodiments, the encapsulate is an interlayer which is laminated with the first substrate, second substrate, and solar cell to form a solar module.

In some embodiments, the encapsulate is an EVA, polyolefin, or the like material. In some embodiments, the encapsulate is a polymer configured to protect the solar cell from water egress and/or provide a modulus of elasticity to prevent cracking of the first and/or second substrate. In some embodiments, the encapsulant attributes (thickness, modulus of elasticity) are tailored based on the glass strength, to design a solar panel that withstands impact and load forces required in service.

In some embodiments, the first surface of the first substrate is configured with a textured coating. The textured coating is configured to promote photons to be directed through the first glass substrate and into the solar cell. In one or more embodiments as set forth herein, the texture for the front coating can be tailored for efficiency improvement.

In some embodiments, the coating on the back glass can be configured to provide an index match to the second encapsulant such that improved adhesion is provided.

In some embodiments, the borosilicate compositions described herein provide crack arresting features upon receiving a crack initiating force, such that the crack is reduced, prevented, and/or eliminated from propagating and damaging the solar panel.

In some embodiments, the solar panel passes a hail impact test of 2-4 J.

In some embodiments, the solar panel passes a load test sufficient to withstand snow loads, wind updraft and downdraft, and other environmental evaluations for solar panels and/or solar installations.

In some embodiments, the solar panel is tailored with the appropriate design features and materials to enable continued performance through upwinds, downwinds, excessive temperatures, and/or deflections caused by the aforementioned environmental conditions.

In some embodiments, the stack is 3 to 4 mm thick.

In some embodiments, the stack is symmetrical.

In some embodiments, the stack is asymmetrical.

In some embodiments the solar panel or solar module described in FIGS. 18 and 19A-C is configured with additional substrates on the first surface or second surface (with accompanying encapsulants) to further protect the solar module.

In some embodiments, the first substrate and second substrate are configured to promote at least one of the following attributes: protect the solar cell from impact, flaws and bending, minimize optical loss, manage surface attributes, among other items.

In some embodiments, the solar panel is configured as bifacial (captures photons from the back/second substrate of the solar module).

In some embodiments, the solar panel is a tandem design (with multiple solar cells stacked in a panel).

In some embodiments, the glass compressive stresses are tailored (e.g., configured in compression) to reduce, prevent, and/or eliminate crack and/or flaw migration.

In some embodiments, the solar cell is selected from: silicon, semiconductor compounds, and emerging market material categories. In some embodiments, silicon solar cell includes a crystalline (e.g., single crystalline or multi-crystalline) or amorphous (hydrogenated amorphous silicon) solar cell. In some embodiments, semiconductor compounds include chalcogenides (e.g., cadmium telluride, copper zinc tin sulphide, copper indium gallium diselenide) or compounds of Group III-V (e.g., gallium indium phosphorus, gallium arsenide, to name a few). In some embodiments, the solar materials are emerging market material categories including dye sensitized solar cells, colloidal quantum dot, perovskite, or organic materials)

In one or more embodiments described herein, the solar module and/or solar panel is configured to pass: IEC-type testing for dynamic loading, static loading, and/or thermal cycling.

In one or more embodiments as described herein, the solar module and/or solar panel is configured to pass at least one of: IEC 61216 Module Quality Tests (MQT) for UV preconditioning (MQT 10), thermal cycling (MQT 11), humidity-freeze (MQT 12), damp heat (MQT 13), potential induced degradation (MQT 21), and perovskite stability testing covering thermal, irradiance, electrical, and environmental protocols (PACT protocol as described by IEC as of the date of this application), and/or combinations thereof. In some embodiments, the solar module and/or solar panel is configured to pass: IEC 61216 Module Quality Tests (MQT) for UV preconditioning (MQT 10), thermal cycling (MQT 11), humidity-freeze (MQT 12), damp heat (MQT 13), potential induced degradation (MQT 21), and perovskite stability testing covering thermal, irradiance, electrical, and environmental protocols (PACT protocol as described by IEC as of the date of this application).

### REFERENCE NUMBERS

Solar panel 10
Solar module 12
First surface 14
Second surface 16
Edge 18
Frame 20
Edge seal 22
J-box 24
Electrical connection 26
Electrical leads 28
Coating (e.g., AR coating/anti-reflective coating) 30
First substrate 32
First surface of first substrate 34
Second surface of first substrate 36
First encapsulate (interlayer) 38
Solar cell 40, 40′
Second encapsulate 48
Second substrate 42
First side of second substrate 44
Second side of second substrate 46
Hole for leads 48
Functional material 50
Electrodes 52
Retrofit cover 54
Third encapsulate 56

1. A solar module, comprising:
a. at least one solar cell having a functional material positioned in electrical communication with an electrical wiring component, wherein the functional material of the solar cell is configured to capture photons and convert them to electrons,
b. a first substrate configured of a transparent material;
c. a second substrate, configured in spaced relation from the first substrate, such that the functional material is configured between the first substrate and the second substrate and
d. an encapsulant configured between the first substrate and the solar cell and the second substate and the solar cell, further configured to retain the solar cell in place between the first substrate and the second substrate;
e. wherein at least one of the first substrate and the second substrate is a borosilicate glass composition, comprising:
at least 75 mol % SiO₂;
at least 10 mol % B₂O₃; and
Al₂O₃ in an amount such that sum of SiO₂, B₂O₃, and Al₂O₃ is at least 90 mol %.

2. The solar module of claim 1, wherein the borosilicate glass composition further comprises: a liquidus viscosity of at least 200 kP to not greater than 500 kP.

3. The solar module of claim 1, wherein the borosilicate glass composition further comprises: a liquidus viscosity of greater than 500 kP.

4. The solar module of claim 1, wherein the borosilicate glass composition comprises a viscosity 200 P of 1725° C. or less.

5. The solar module of claim 1, wherein the first substrate is the borosilicate glass composition, and the second substrate is a sodalime glass.

6. The solar module of claim 1, wherein the first substrate is the borosilicate glass composition, and the second substrate is a flexible glass ribbon.

7. The solar module of claim 1, wherein the first substrate is sodalime glass.

8. The solar module of claim 1, wherein both the first substrate and second substrate are the borosilicate glass composition.

9. The solar module of claim 1, wherein the first substrate and second substrate have the same thicknesses.

10. The solar module of claim 1, wherein the first substrate and second substrate have the different thicknesses.

11. The solar module of claim 1, wherein the first substrate is thicker than the second substrate.

12. (canceled)

13. (canceled)

14. (canceled)

15. (canceled)

16. (canceled)

17. (canceled)

18. (canceled)

19. The solar module of claim 1, further configured as a solar panel.

20. The solar module of claim 1, further comprising an anti-reflective coating on a first surface of the first substrate.

21. (canceled)

22. The solar module of claim 1, the borosilicate glass composition further comprising about 2 mol % to about 8 mol % Na₂O.

23. The solar module of claim 1, the borosilicate glass composition further comprising about 1 mol % to about 4 mol % K₂O.

24. The solar module of claim 1, the borosilicate glass composition, wherein a total amount of Na₂O and K₂O is at least 4 mol %.

25. The solar module of claim 1, the borosilicate glass composition further comprising at least one of MgO or CaO, wherein a total amount of MgO and CaO is at most 5 mol %.

26. The solar module of claim 1, the borosilicate glass composition further comprising wherein a total amount of Na₂O, K₂O, MgO, and CaO is at least 7 mol %.

27. The solar module of claim 1, the borosilicate glass composition further comprising P₂O₅, wherein P₂O₅ is present in an amount up to 4 mol %.

28. The solar module of claim 1, the borosilicate glass composition further comprising about 0.05 mol % to about 0.25 mol % of SnO₂.

29. The solar module of claim 1, the borosilicate glass composition further comprising further comprising 0.05 mol % to 0.50 mol % Fe₂O₃.

30. (canceled)

31. (canceled)

32. (canceled)

33. A substrate in a solar module, comprising:
an outer ply comprising a borosilicate glass and having thickness of at least 200 μm and no more than 1 cm, wherein in terms of constituent oxides, composition of the borosilicate glass comprises: SiO₂, B₂O₃, Al₂O₃, one or more alkali metal oxides, one or more divalent cation oxides of the group consisting of MgO, CaO, SrO, BaO, and ZnO, wherein concentrations in mole percent on an oxide basis of SiO₂, B₂O₃,
greater than or equal to 11 mol % and less than or equal to 16 mol % B₂O₃,
greater than or equal to 2 mol % and less than or equal to 6 mol % Al₂O₃, and
a total amount of Na₂O, K₂O, MgO, and CaO that is greater than or equal to 7.0 mol %,
wherein the one or more alkali metal oxides, Al₂O₃, and the one or more alkaline earth metal oxides, satisfy the relationships:
$$( {R}_{2} O + {R}^{′} O ) \geq {Al}_{2} {O}_{3}$$
$$0.8 < ( 1 - [ ( 2 {R}_{2} O + 2 {R}^{′} O ) / ( {SiO}_{2} + 2 {Al}_{2} {O}_{3} + 2 {B}_{2} {O}_{3} ) ] ) < 0.93 ,$$
where R₂O is the sum of the concentrations of the one or more alkali metal oxides and R′O is the sum of the concentrations of the one or more alkaline earth metal oxides;
an inner ply comprising a second glass that is different from the composition of the borosilicate glass of the outer ply, wherein the inner ply reinforces the outer ply, stiffening the outer ply to bending forces applied thereto, and wherein composition of the second glass is selected from the group consisting of a soda lime silicate glass composition, an aluminosilicate glass composition, an alkali aluminosilicate glass composition, an alkali containing borosilicate glass composition, an alkali aluminophosphosilicate glass composition, and an alkali aluminoborosilicate glass composition;
an interlayer coupling the inner and outer plies, wherein the interlayer is polymeric and dampens transmission of cracks from the outer ply to the inner ply.

34. The substrate of claim 33, wherein when glass having the composition of the borosilicate glass of the outer ply is formed as 100 polished, flat samples of 1 mm thickness with a major surface of 2×2 cm² area, and tested using square-based, 136° four-sided, pyramidal Vickers indenter directed orthogonally into a center of the major surface at 25° C. in 50% relative humidity and the indenter is quasi-statically displaced at rate of 60 μm per second to maximum 3 kg-force with indentation load held for 10 seconds, more often than not all cracks extending through the samples radially and/or laterally from the indenter are contained within a crack loop.

35. (canceled)

36. (canceled)

37. The substrate of claim 33, wherein the borosilicate glass of the outer ply comprises at least 74 mol % SiO₂ and at least 10 mol % B₂O₃; and wherein the borosilicate glass of the outer ply comprises a sum of SiO₂, B₂O₃, and Al₂O₃ is at least 90 mol %.

38. The substrate of claim 33, wherein the outer ply is thicker than the inner ply, and wherein the second glass of the inner ply is chemically strengthened through an ion-exchange treatment.

39. The substrate of claim 33, wherein the thickness of the outer ply is a first thickness, wherein the first thickness is at least 2 mm, and wherein the inner ply has a second thickness of less than 2 mm.

40. The substrate of claim 33, wherein a ratio of the first thickness to the sum of the first and second thicknesses is at least 0.7.

41. The substrate of claim 33, wherein the first thickness is at least 3.3 mm, and the second thickness is 0.7 mm or less.

42. The substrate of claim 33, wherein visible transmission through the article, as measured according to ISO 13837A, is at least 73%; and wherein total solar transmittance through the article, as measured according to ISO 13837A, is 90% or less.

43. The substrate of claim 33, wherein a major surface of the outer ply furthest from the inner ply and a major surface of the inner ply further from the outer ply both exhibit an optical distortion of at most 200 millidiopters as measured by an optical distortion detector using transmission optics according to ASTM 1561.

44. (canceled)

45. The substrate of claim 33, wherein the outer ply and the inner ply are pair-shaped, wherein the outer ply comprises a first curvature depth of at least 2 mm, wherein the inner ply comprises a second curvature depth of at least 2 mm, and wherein the first curvature depth is within 10% of the second curvature depth.

46. The substrate of claim 33, wherein the outer ply comprises a curvature depth of at least 2 mm, and wherein the inner ply has stress from being cold-formed into conformity with the outer ply.

47. (canceled)

48. (canceled)

49. (canceled)

50. (canceled)

51. The substrate of claim 33, wherein the composition of the borosilicate glass comprises greater than or equal to 4 mol % and less than or equal to 6 mol % Na₂O.

52. The substrate of claim 33, wherein the composition of the borosilicate glass comprises:
greater than or equal to 3 mol % and less than or equal to 5 mol % Al₂O₃; and
greater than or equal to 12 mol % and less than or equal to 16 mol % B₂O₃.

53. The substrate of claim 33, wherein at least one of:
the composition of the borosilicate glass comprises greater than or equal to 0.03 mol % and less than or equal to 0.5 mol % Fe₂O₃, and
the thickness is less than or equal to 3.3 mm and the outer ply has a transmittance that is greater than or equal to 90% and less than or equal to 92.5% throughout the visible spectrum.

54. The substrate of claim 33, wherein the outer glass ply consists of the borosilicate glass.
